(19) United States
(12) Patent Application Publication
(10) Pub. No.: US 2022/0181557 A1
(43) Pub. Date: Jun. 9, 2022

(54) ORGANIC ELECTROLUMINESCENCE DEVICE AND POLYCYCLIC COMPOUND FOR ORGANIC ELECTROLUMINESCENCE DEVICE

(71) Applicant: Samsung Display Co., Ltd., Yongin-si (KR)

(72) Inventors: MINJUNG JUNG, Hongcheon-gun (KR); SERAN KIM, Suwon-si (KR); TAEIL KIM, Hwaseong-si (KR); SUN YOUNG PAK, Suwon-si (KR); JUNHA PARK, Gwacheon-si (KR); JANG YEOL BAEK, Yongin-si (KR); KYOUNG SUNWOO, Hwaseong-si (KR); MUN-KI SIM, Seoul (KR); CHANSEOK OH, Seoul (KR)

(21) Appl. No.: 17/445,164

(22) Filed: Aug. 16, 2021

(30) Foreign Application Priority Data
Dec. 4, 2020 (KR) 10-2020-0168911

(51) Int. Cl. H01L 51/00

(52) U.S. Cl. CPC H01L 51/0071; H01L 51/5016; H01L 51/0061

(57) ABSTRACT

An organic electroluminescence device includes a first electrode, a hole transport region disposed on the first electrode, an emission layer disposed on the hole transport region, and an electron transport region disposed on the emission layer, where the emission layer includes a polycyclic compound represented by Formula 1 to thereby exhibit high luminous efficiency:

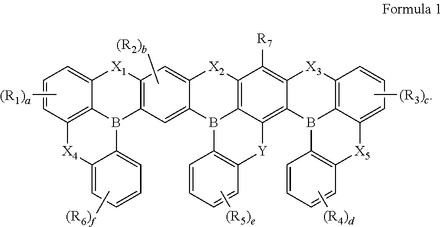

### CROSS-REFERENCE TO RELATED APPLICATION

This application claims priority to and the benefit of Korean Patent Application No. 10-2020-0168911, filed on Dec. 4, 2020, the entire content of which is hereby incorporated by reference.

### BACKGROUND

One or more aspects of embodiments of the present disclosure relate to an organic electroluminescence device and a polycyclic compound used therein, and for example, to a polycyclic compound used as a light-emitting material and an organic electroluminescence device including the same.

Recently, organic electroluminescence displays are being developed as image displays. Different from a liquid crystal display, the organic electroluminescence display is so-called a self-luminescent display in which holes and electrons respectively injected from a first electrode and a second electrode recombine in an emission layer, and a light-emitting material including an organic compound in the emission layer emits light to attain display.

In the application of an organic electroluminescence device to a display apparatus, it is desirable to utilize an organic electroluminescence device with low driving voltage, high luminous efficiency and/or long lifetime (e.g., lifespan), and development of materials for an organic electroluminescence device stably attaining such requirements is continuously desired.

In particular, in recent years, to achieve a high efficiency organic electroluminescence device, materials capable of phosphorescence utilizing triplet state energy, delayed fluorescence utilizing triplet-triplet annihilation (TTA) (in which singlet excitons are generated via collision between triplet excitons), and/or thermally activated delayed fluorescence (TADF) are continually being developed.

### SUMMARY

One or more aspects of embodiments of the present disclosure are directed toward an organic electroluminescence device and a polycyclic compound for the organic electroluminescence device, and for example, an organic electroluminescence device with high efficiency and a polycyclic compound included in an emission layer of the organic electroluminescence device.

One or more embodiments of the present disclosure provide an organic electroluminescence device including a first electrode, a hole transport region disposed on the first electrode, an emission layer disposed on the hole transport region, an electron transport region disposed on the emission layer, and a second electrode disposed on the electron transport region, wherein the first electrode and the second electrode each independently include at least one selected from silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/calcium (Ca), LiF/aluminum (Al), molybdenum (Mo), titanium (Ti), tungsten (W), indium (In), tin (Sn), and zinc (Zn), a compound of two or more thereof, a mixture of two or more thereof, or an oxide thereof, and the emission layer includes a polycyclic compound represented by Formula 1:

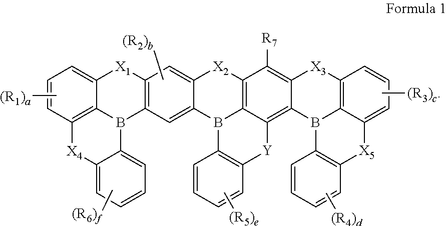

In Formula 1, X₁ to X₅ may each independently be O, NAr₁, S, or Se, Y may be O, S, or Se, Ar₁ may be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, R₁ to R₇ may each independently be a hydrogen atom, a deuterium atom, a halogen atom, a cyano group, a substituted or unsubstituted alkyl group having 1 to 30 carbon atoms, a substituted or unsubstituted amine group, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, “a” and “c” may each independently be an integer of 0 to 3, “b” may be an integer of 0 to 2, and “d” to “f” may each independently be an integer of 0 to 4.

In an embodiment, the emission layer may be to emit delayed fluorescence.

In an embodiment, the emission layer may be a delayed fluorescent emission layer including a host and a dopant, and the dopant may include a polycyclic compound represented by Formula 1.

In an embodiment, the emission layer may be a thermally activated delayed fluorescent emission layer to emit blue light.

In an embodiment, the sum of “a” and “c” may be an integer of 1 or more, and at least one of R₁ or R₃ may be a substituted amine group.

In an embodiment, Formula 1 may be represented by Formula 2-1 or Formula 2-2:

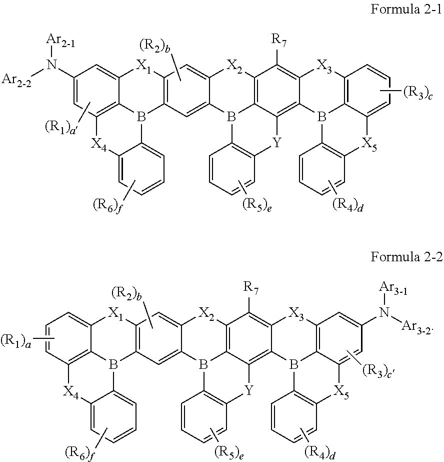

In Formula 2-1 and Formula 2-2, Ar₂₋₁, Ar₂₋₂, Ar₃₋₁, and Ar₃₋₂ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, a′ and c′ may each independently be an integer of 0 to 2, and X₁ to X₅, Y, R₁ to R₇, and “a” to “f” may each independently be the same as defined in Formula 1.

Formula 1 above may be represented by Formula 3:

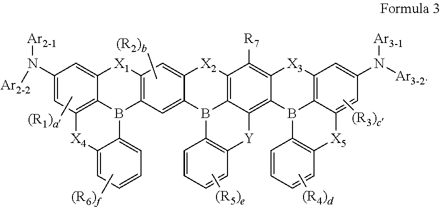

In Formula 3 above, Ar₂₋₁, Ar₂₋₂, Ar₃₋₁, and Ar₃₋₂ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, a′ and c′ may each independently be an integer of 0 to 2, and X₁ to X₅, Y, R₁ to R₇, “b”, and “d” to “f” may each independently be the same as defined in Formula 1.

In an embodiment, Ar₂₋₁, Ar₂₋₂, Ar₃₋₁, and Ar₃₋₂ may each independently be a substituted or unsubstituted ring-forming aryl group having 6 to 18 carbon atoms.

In an embodiment, Formula 1 may be represented by any one among Formula 4-1 to Formula 4-4.

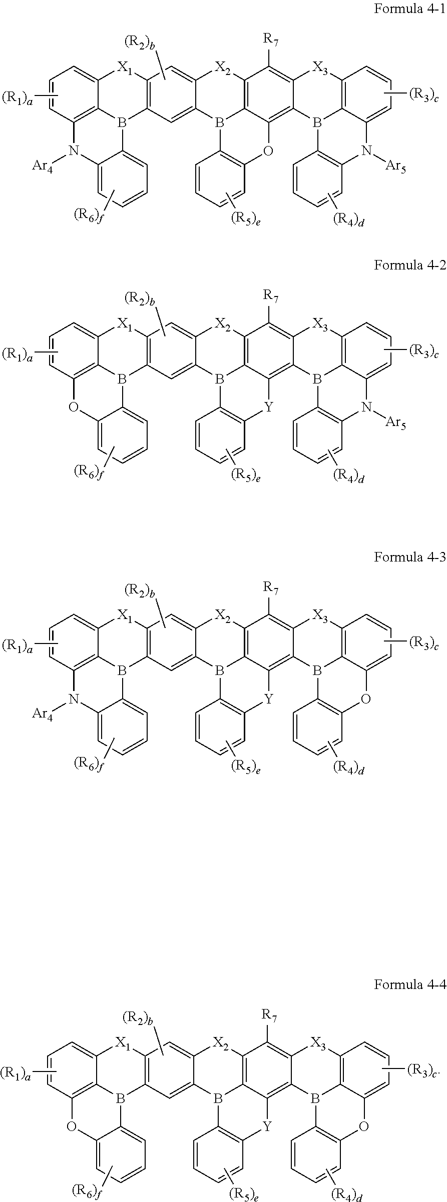

In Formula 4-1 to Formula 4-4, Ar₄ and Ar₅ may each independently be a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms, and X₁ to X₃, Y, R₁ to R₇, and “a” to “f” may each independently be the same as defined in Formula 1.

In an embodiment, Formula 1 may be represented by any one among Formula 5-1 to Formula 5-3.

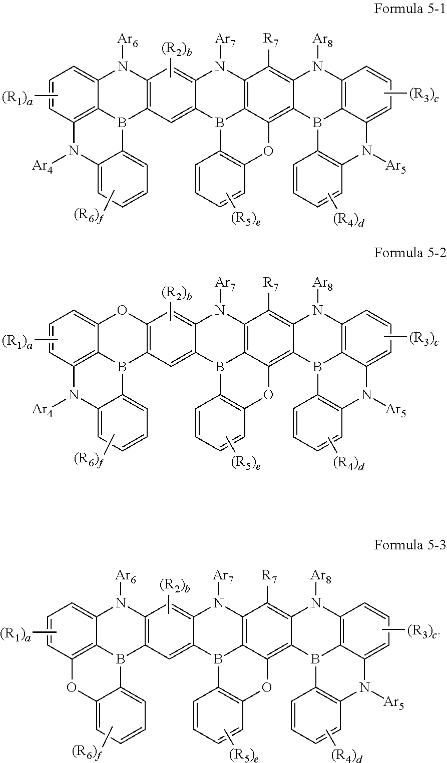

In Formula 5-1 to Formula 5-3, Ar₄ to Ar₅ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, and Y, R₁ to R₇, “a” to “f” may each independently be the same as defined in Formula 1.

In an embodiment, Ar₄ to Ar₈ may each independently be represented by any one among Formula 6-1 to Formula 6-3.

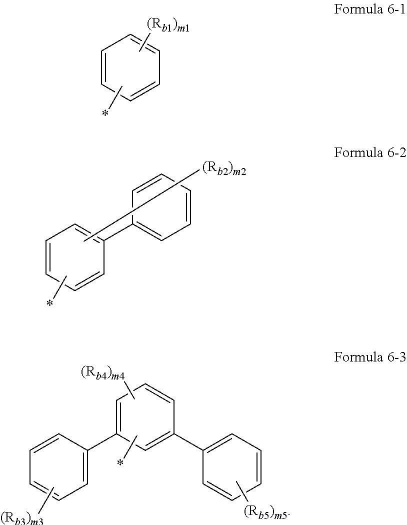

In Formula 6-1 to Formula 6-3, R_{b1} to R_{b5} may each independently be a hydrogen atom, a deuterium atom, a halogen atom, a cyano group, a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, m1, m3, and m5 may each independently be an integer of 0 to 5, m2 may be an integer of 0 to 9, and m4 may be an integer of 0 to 3.

In an embodiment, the polycyclic compound represented by Formula 1 may be any one among the compounds represented in Compound Group 1.

One or more embodiments of the present disclosure provide the polycyclic compound represented by Formula 1.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view illustrating a display apparatus according to an embodiment of the present disclosure;

FIG. 2 is a cross-sectional view illustrating a display apparatus according to an embodiment of the present disclosure;

FIG. 3 is a cross-sectional view schematically illustrating an organic electroluminescence device according to an embodiment of the present disclosure;

FIG. 4 is a cross-sectional view schematically illustrating an organic electroluminescence device according to an embodiment of the present disclosure;

FIG. 5 is a cross-sectional view schematically illustrating an organic electroluminescence device according to an embodiment of the present disclosure;

FIG. 6 is a cross-sectional view schematically illustrating an organic electroluminescence device according to an embodiment of the present disclosure;

FIG. 7 is a cross-sectional view illustrating a display apparatus according to an embodiment of the present disclosure; and

FIG. 8 is a cross-sectional view illustrating a display apparatus according to an embodiment of the present disclosure.

### DETAILED DESCRIPTION

The present disclosure may be modified in many alternative forms, and thus selected embodiments will be illustrated in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numerals may be used to refer to like components, and duplicative descriptions thereof may not be provided. In the accompanying drawings, dimensions of structures may be exaggerated for clarity of the present disclosure. It will be understood that, although the terms “first,” “second,” etc. may be used herein to describe various elements, these components should not be limited by these terms. These terms are only used to distinguish one element from another. For example, a first element may be referred to as a second element, and similarly, a second element may be referred to as a first element without departing from the scope of the present disclosure. The singular forms include the plural forms as well, unless the context clearly indicates otherwise.

In this application, it will be further understood that the terms “comprise,” “include” or “have” etc., when used in this specification, specify the presence of a feature, a fixed number, a step, an operation, an element, a component, or a combination thereof disclosed in the specification, but do not exclude the possibility of presence or addition of one or more other features, fixed numbers, steps, operations, elements, components, or combination thereof.

In this application, when a part such as a layer, a film, a region, a plate is referred to as being “on” or “above” another part, it may be “directly on” the other part, or an intervening part may also be present. In contrast, when a part such as a layer, a film, a region, a plate is referred to as being “under” or “below” another part, it may be “directly under” the other part, or an intervening part may also be present. When an element is referred to as being “directly on,” “directly above,” “directly under,” or “directly below” another element, there are no intervening elements present. In addition, in this application, when a part is referred to as being disposed “on” another part, it may be disposed on the other part or under the other part as well.

As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively. As used herein, expressions such as “at least one of,” “one of,” and “selected from,” when preceding a list of elements, modify the entire list of elements and do not modify the individual elements of the list.

As used herein, the term “and/or” includes any and all combinations of one or more of the associated listed items. Further, the use of “may” when describing embodiments of the present disclosure refers to “one or more embodiments of the present disclosure”. Hereinafter, embodiments of the present disclosure will be explained with reference to the drawings.

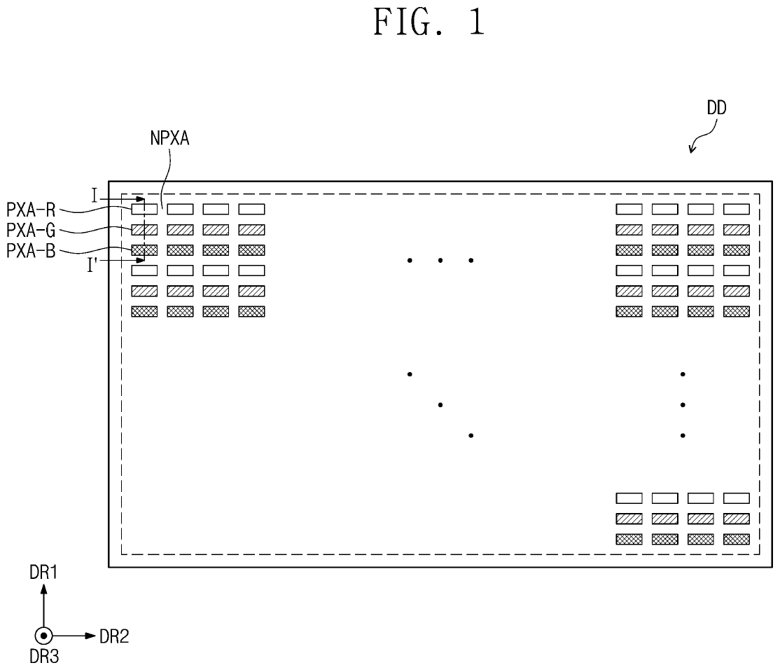

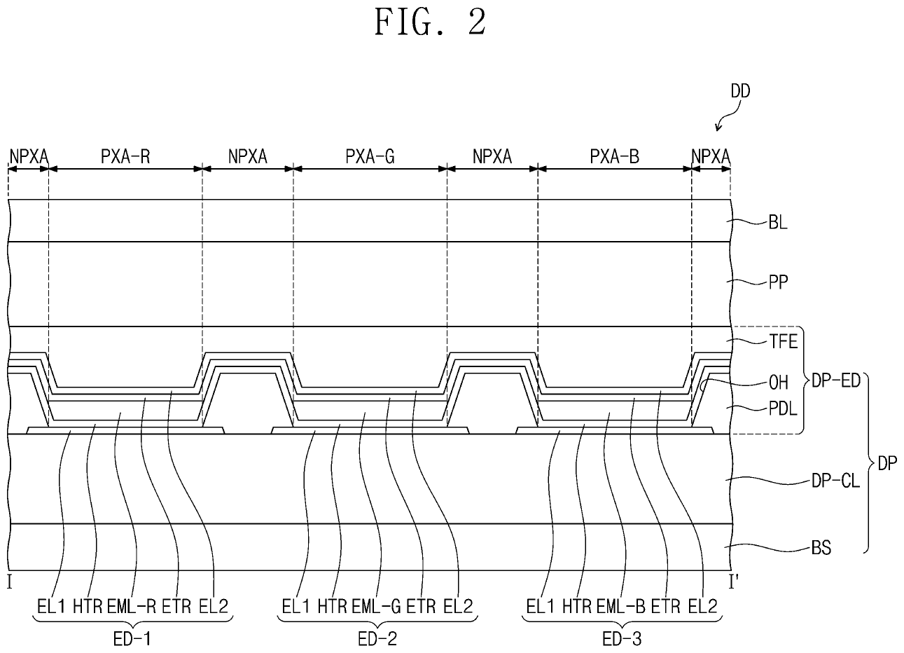

FIG. 1 is a plan view illustrating an embodiment of a display apparatus DD. FIG. 2 is a cross-sectional view of a display apparatus DD according to an embodiment. FIG. 2 is a cross-sectional view illustrating a portion taken along line I-I′ in FIG. 1.

The electronic apparatus DD may include a display panel DP and an optical layer PP disposed on the display panel DP. The display panel DP includes organic electroluminescence devices ED-1, ED-2, and ED-3. The display apparatus DD may include a plurality of organic electroluminescence devices ED-1, ED-2, and ED-3. The optical layer PP may be disposed on the display panel DP and may control or reduce reflection of external light on the display panel DP. The optical layer PP may include, for example, a polarization layer or a color filter layer. In some embodiments, the optical layer PP may be omitted in the display apparatus DD.

A base substrate BL may be disposed on the optical layer PP. The base substrate BL may be a member providing a base surface on which the optical layer PP is disposed. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In some embodiments, the base substrate BL may be omitted.

The display apparatus DD according to an embodiment may further include a filling layer. The filling layer may be disposed between the display device layer DP-ED and the base substrate BL. The filling layer may be an organic material layer. The filling layer may include at least one of acrylic-based resins, silicon-based resins, or epoxy-based resins.

The display panel DP may include a base layer BS, a circuit layer DP-CL provided on the base layer BS, and a display device layer DP-ED. The display device layer DP-ED may include a pixel-defining film PDL, organic electroluminescence devices ED-1, ED-2, and ED-3 disposed between the pixel-defining film PDL, and an encapsulating layer TFE disposed on the organic electroluminescence devices ED-1, ED-2, and ED-3.

The base layer BS may provide a base surface on which the display device layer DP-ED is disposed. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors. The transistors may include a control electrode, an input electrode, and an output electrode, respectively. For example, the circuit layer DP-CL may include a switching transistor and a driving transistor for driving the organic electroluminescence devices ED-1, ED-2, and ED-3 of the display device layer DP-ED.

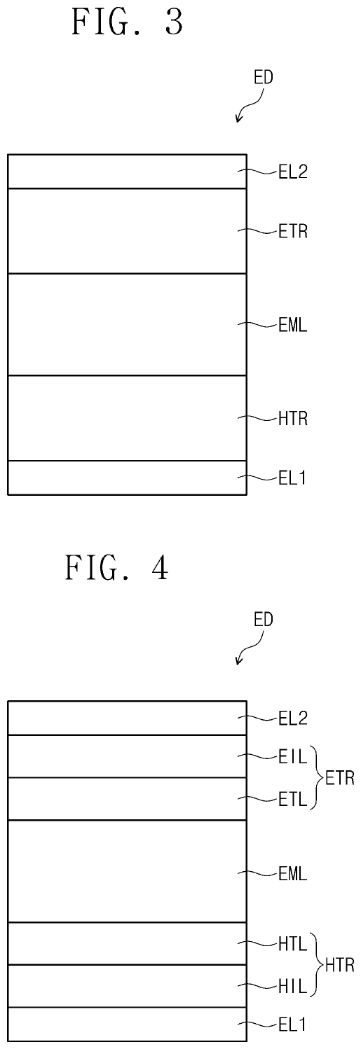

Each of the organic electroluminescence devices ED-1, ED-2, and ED-3 may have a structure of an organic electroluminescence device ED of an embodiment according to FIGS. 3 to 6 (described below). Each of the organic electroluminescence devices ED-1, ED-2, and ED-3 may include a first electrode EL1, a hole transport region HTR, emission layers EML-R, EML-G, and EML-B, an electron transport region ETR, and a second electrode EL2.

In FIG. 2, the emission layers EML-R, EML-G, and EML-B of the organic electroluminescence devices ED-1, ED-2, and ED-3 are disposed in an opening OH defined in the pixel-defining film PDL, and the hole transport region HTR, the electron transport region ETR, and the second electrode EL2 are provided as common layers in all of the organic electroluminescence devices ED-1, ED-2, and ED-3. However, embodiments of the present disclosure are not limited thereto. In some embodiments, the hole transport region HTR and the electron transport region ETR may be patterned and provided in (e.g., only in) the opening OH defined in the pixel-defining film PDL. For example, in an embodiment, the hole transport region HTR, the emission layers EML-R, EML-G, and EML-B, and the electron transport region ETR, etc. of the organic electroluminescence devices ED-1, ED-2, and ED-3 may be patterned and provided by an inkjet printing method.

The encapsulating layer TFE may cover the organic electroluminescence devices ED-1, ED-2, and ED-3. The encapsulating layer TFE may seal the display device layer DP-ED. The encapsulating layer TFE may be a thin film encapsulating layer. The encapsulating layer TFE may be a single layer or a plurality of layers being stacked. The encapsulating layer TFE includes at least one insulating layer. The encapsulating layer TFE according to an embodiment may include at least one inorganic film (hereinafter, an encapsulating inorganic film). In some embodiments, the encapsulating layer TFE according to an embodiment may include at least one organic film (hereinafter, an encapsulating organic film) and at least one encapsulating inorganic film.

The encapsulating inorganic film protects the display device layer DP-ED from moisture/oxygen, and the encapsulating organic film protects the display device layer DP-ED from foreign materials (such as dust particles). The encapsulating inorganic film may include silicon nitride, silicon oxy nitride, silicon oxide, titanium oxide, aluminum oxide, and/or the like, but embodiments of the present disclosure are not particularly limited thereto. The encapsulating organic film may include an acrylic-based compound, an epoxy-based compound, and/or the like. The encapsulating organic film may include a photopolymerizable organic material, but embodiments of the present disclosure are not particularly limited thereto.

The encapsulating layer TFE may be disposed on the second electrode EL2 and may be disposed while filling the opening OH.

Referring to FIGS. 1 and 2, the display apparatus DD may include a non-light emitting region NPXA and light-emitting regions PXA-R, PXA-G, and PXA-B. The light-emitting regions PXA-R, PXA-G, and PXA-B may be regions in which light generated from the organic electroluminescence devices ED-1, ED-2, and ED-3 is emitted, respectively. The light-emitting regions PXA-R, PXA-G, and PXA-B may be spaced apart from each other on a plane (e.g., the plane defined by the first direction axis DR1 and the second direction axis DR2, e.g., in a plan view).

Each of the light-emitting regions PXA-R, PXA-G, and PXA-B may be separated (e.g., from each other) by the pixel-defining film PDL. The non-light emitting region NPXA may be a region interposed between the neighboring light-emitting regions PXA-R, PXA-B, and PXA-G, and may be a region corresponding to the pixel-defining film PDL. In this description, each of the light-emitting regions PXA-R, PXA-G, and PXA-B may correspond to a pixel. The pixel-defining film PDL may separate the organic electroluminescence devices ED-1, ED-2 and ED-3. The emission layers EML-R, EML-G and EML-B of the organic electroluminescence devices ED-1, ED-2 and ED-3 may be disposed in the opening OH defined in the pixel-defining film PDL and separated from one another.

The light-emitting regions PXA-R, PXA-G, and PXA-B may be classified into a plurality of groups according to the color of light generated from the organic electroluminescence devices ED-1, ED-2, and ED-3. In the display apparatus DD according to an embodiment illustrated in FIGS. 1 and 2, three light-emitting regions PXA-R, PXA-G, and PXA-B respectively emitting red light, green light, and blue light are illustrated as an example. For example, the display apparatus DD according to an embodiment may include a red light-emitting region PXA-R, a green light-emitting region PXA-G, and a blue light-emitting region PXA-B, which are distinguished from each other.

In the display apparatus DD according to an embodiment, a plurality of organic electroluminescence devices ED-1, ED-2, and ED-3 may be to emit light having different wavelength regions. For example, in an embodiment, the display apparatus DD may include a first organic electroluminescence device ED-1 emitting red light, a second organic electroluminescence device ED-2 emitting green light, and a third organic electroluminescence device ED-3 emitting blue light. For example, the red light-emitting region PXA-R, the green light-emitting region PXA-G, and the blue light-emitting region PXA-B of the display apparatus DD may correspond to the first organic electroluminescence device ED-1, the second organic electroluminescence device ED-2, and the third organic electroluminescence device ED-3, respectively.

However, embodiments of the present disclosure are not limited thereto, and the first to third organic electroluminescence devices ED-1, ED-2, and ED-3 may be to emit light of the same wavelength region, or at least one thereof may be to emit light of a different wavelength region. For example, all of the first to third organic electroluminescence devices ED-1, ED-2, and ED-3 may be to emit blue light.

The light-emitting regions PXA-R, PXA-G, and PXA-B in the display apparatus DD according to an embodiment may be arranged in a stripe shape. Referring to FIG. 1, a plurality of red light-emitting regions PXA-R may be arranged with each other along a second direction axis DR2, a plurality of green light-emitting regions PXA-G may be arranged with each other along the second direction axis DR2, and a plurality of blue light-emitting regions PXA-B may be arranged with each other along the second direction axis DR2. In addition, a red light-emitting region PXA-R, a green light-emitting region PXA-G, and a blue light-emitting region PXA-B may be arranged by turns (e.g., alternatingly arranged) with each other along a first direction axis DR1.

FIGS. 1 and 2 illustrate that all the light-emitting regions PXA-R, PXA-G, and PXA-B have similar areas, but embodiments of the present disclosure are not limited thereto. The areas of the light-emitting regions PXA-R, PXA-G, and PXA-B may be different from each other depending on the wavelength region of the emitted light. The areas of the light-emitting regions PXA-R, PXA-G, and PXA-B may refer to areas as viewed on a plane defined by the first direction axis DR1 and the second direction axis DR2.

The arrangement of the light-emitting regions PXA-R, PXA-G, and PXA-B is not limited to the configuration illustrated in FIG. 1, and the red light-emitting region PXA-R, the green light-emitting region PXA-G, and the blue light-emitting region PXA-B may be provided in various suitable combinations (arrangement orders) depending on the properties of display quality required for the display apparatus DD. For example, the light-emitting regions PXA-R, PXA-G, and PXA-B may be arranged in a PENTILE® configuration or a diamond configuration.

The areas of the light-emitting regions PXA-R, PXA-G, and PXA-B may be different from each other. For example, in an embodiment, the area of the green light-emitting region PXA-G may be smaller than the area of the blue light-emitting region PXA-B, but embodiments of the present disclosure are not limited thereto.

Hereinafter, FIGS. 3 to 6 are cross-sectional views schematically illustrating an organic electroluminescence device according to an embodiment. The organic electroluminescence device ED according to an embodiment may include a first electrode EL1, a hole transport region HTR, an emission layer EML, an electron transport region ETR, and a second electrode EL2, which are sequentially stacked.

The organic electroluminescence device ED according to an embodiment include a polycyclic compound according to an embodiment (to be described below) in the emission layer EML disposed between the first electrode EL1 and the second electrode EL2. However, embodiments of the present disclosure are not limited thereto, and an organic electroluminescence device ED according to an embodiment may include the polycyclic compound in a hole transport region HTR or in an electron transport region ETR (which are among a plurality of functional layers disposed between the first electrode EL1 and the second electrode EL2 in addition to the emission layer EML), or in a capping layer CPL disposed on the second electrode EL2.

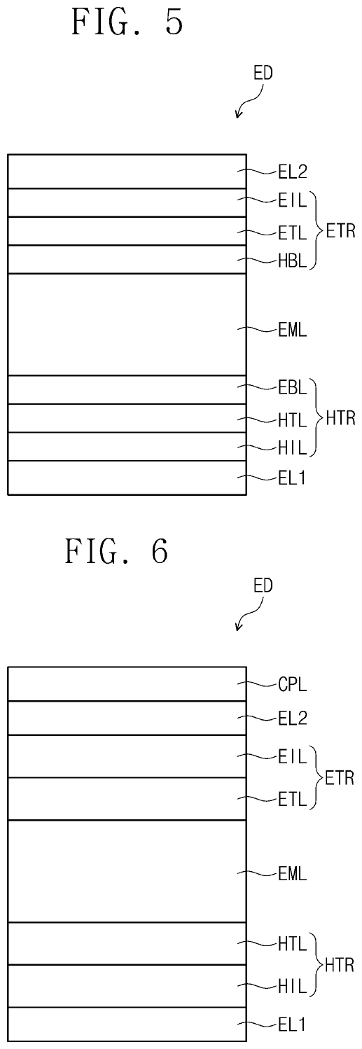

Compared with FIG. 3, FIG. 4 shows the cross-sectional view of an organic electroluminescence device ED according to an embodiment, wherein a hole transport region HTR includes a hole injection layer HIL and a hole transport layer HTL, and an electron transport region ETR includes an electron injection layer EIL and an electron transport layer ETL. Compared with FIG. 3, FIG. 5 shows the cross-sectional view of an electroluminescence device ED according to an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 shows the cross-sectional view of an organic electroluminescence device ED according to an embodiment, which includes the capping layer CPL disposed on the second electrode EL2.

The first electrode EL1 has conductivity. The first electrode EL1 may be formed utilizing a metal material, a metal alloy, and/or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. When the first electrode EL1 is a transmissive electrode, the first electrode EL1 may include transparent metal oxide (such as indium tin oxide (ITO), indium zinc oxide (IZO), zinc oxide (ZnO), indium tin zinc oxide (ITZO), and/or the like). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, or a compound or a mixture thereof (for example, a mixture of Ag and Mg). In some embodiments, the first electrode EL1 may have a multilayered structure including a reflective film or a transflective film formed utilizing the above-described materials and a transparent conductive film formed utilizing indium tin oxide (ITO), indium zinc oxide (IZO), zinc oxide (ZnO), indium tin zinc oxide (ITZO), and/or the like. For example, the first electrode EL1 may have a three-layer structure of ITO/Ag/ITO, but embodiments of the present disclosure are not limited thereto. In some embodiments, the first electrode EL1 may include the above-described metal material, a combination of two or more metal materials, or an oxide of the above-described metal materials. A thickness of the first electrode EL1 may be about 700 Å to about 10000 Å. For example, the thickness of the first electrode EL1 may be about 1000 Å to about 3000 Å.

The hole transport region HTR is provided on the first electrode EL1. The hole transport region HTR may include at least one of a hole injection layer HIL, a hole transport layer HTL, a buffer layer or a light-emitting auxiliary layer, or an electron blocking layer EBL. The thickness of the hole transport region HTR may be, for example, about 50 Å to about 15,000 Å.

The hole transport region HTR may have a single layer formed using a single material, a single layer formed using a plurality of different materials, or a multilayer structure having a plurality of layers formed using a plurality of different materials.

For example, the hole transport regions HTR may have a structure of a single layer of a hole injection layer HIL or a hole transport layer HTL, and may have a structure of a single layer formed using a hole injection material and a hole transport material. Further, the hole transport regions HTR may have a structure of a single layer formed using a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed by using various suitable methods (such as a vacuum deposition method, a spin coating method, a cast method, a Langmuir-Blodgett (LB) method, an inkjet printing method, a laser printing method, and/or a laser induced thermal imaging (LITI) method).

The hole transport region HTR may further include a compound represented by Formula H-1.

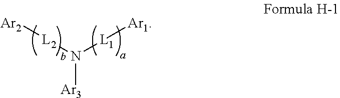

In Formula H-1, L₁ and L₂ may each independently be a direct linkage, a substituted or unsubstituted ring-forming arylene group having 6 to 30 carbon atoms, or a substituted or unsubstituted ring-forming heteroarylene group having 2 to 30 carbon atoms. “a” and “b” may each independently be an integer of 0 to 10. When “a” or “b” is an integer of 2 or more, a plurality of L₁ and L₂ may each independently be a substituted or unsubstituted ring-forming arylene group having 6 to 30 carbon atoms, or a substituted or unsubstituted ring-forming heteroarylene group having 2 to 30 carbon atoms.

In Formula H-1, Ar₁ and Ar₂ may each independently be a substituted or unsubstituted ring-forming aryl group having 6 to 30 carbon atoms, or a substituted or unsubstituted ring-forming heteroaryl group having 2 to 30 carbon atoms. In some embodiments, in Formula H-1, Ar₃ may be a substituted or unsubstituted ring-forming aryl group having 6 to 30 carbon atoms.

The compound represented by Formula H-1 above may be a monoamine compound (e.g., may have only one amino functional group). In some embodiments, the compound represented by Formula H-1 above may be a diamine compound (e.g., may have two amino functional groups) in which at least one among Ar₁ to Ar₃ includes an amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds in Compound Group H. However, the compounds listed in Compound Group H are illustrative, and the compound represented by Formula H-1 is not limited to those represented in Compound Group H.

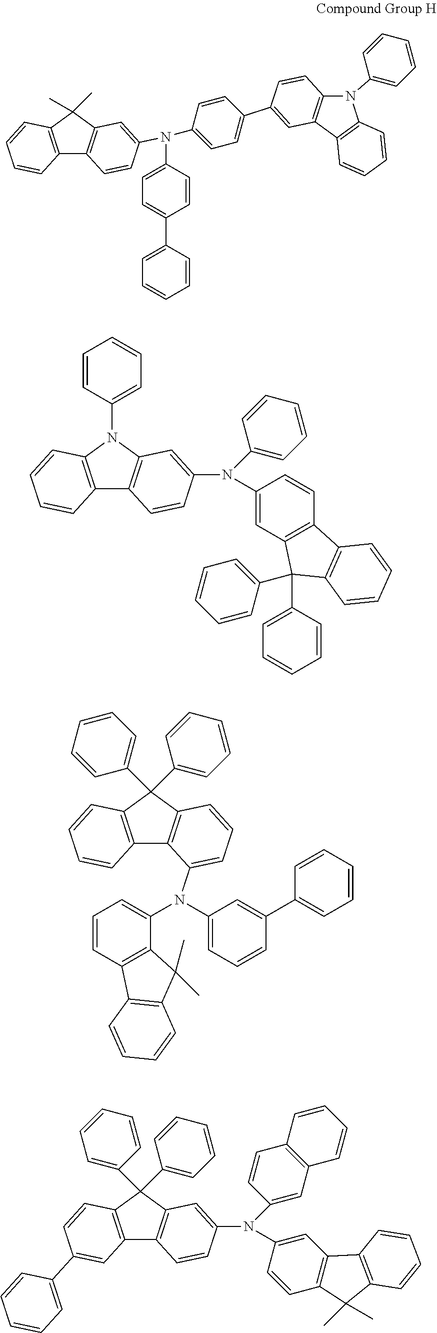 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

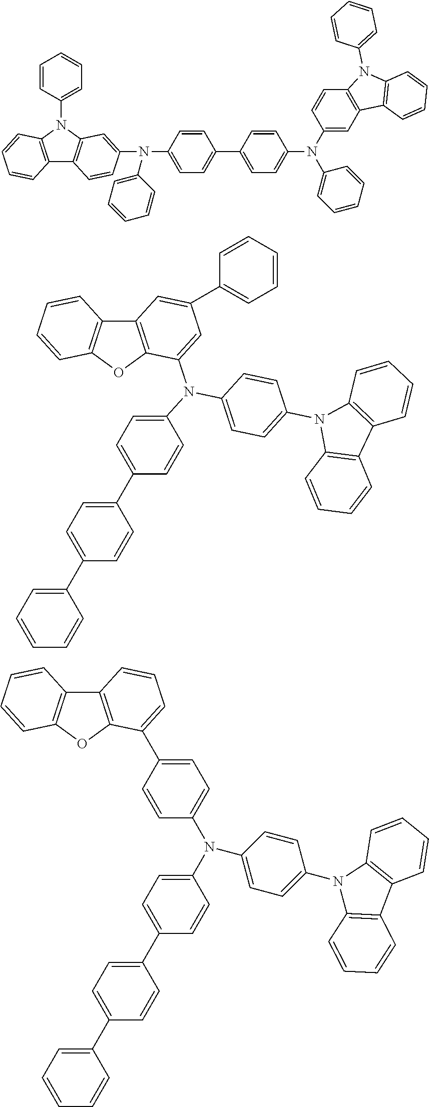

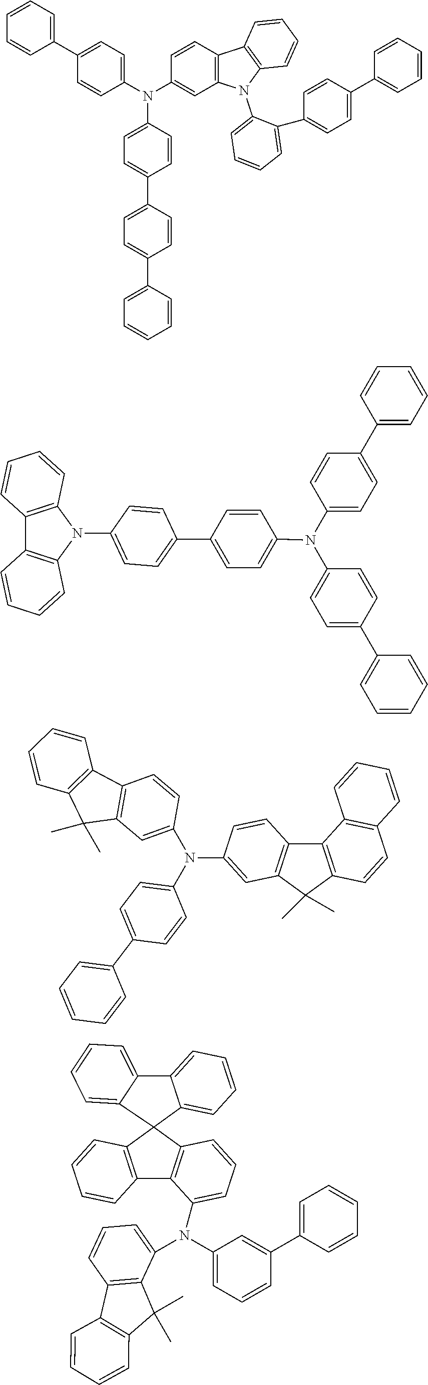

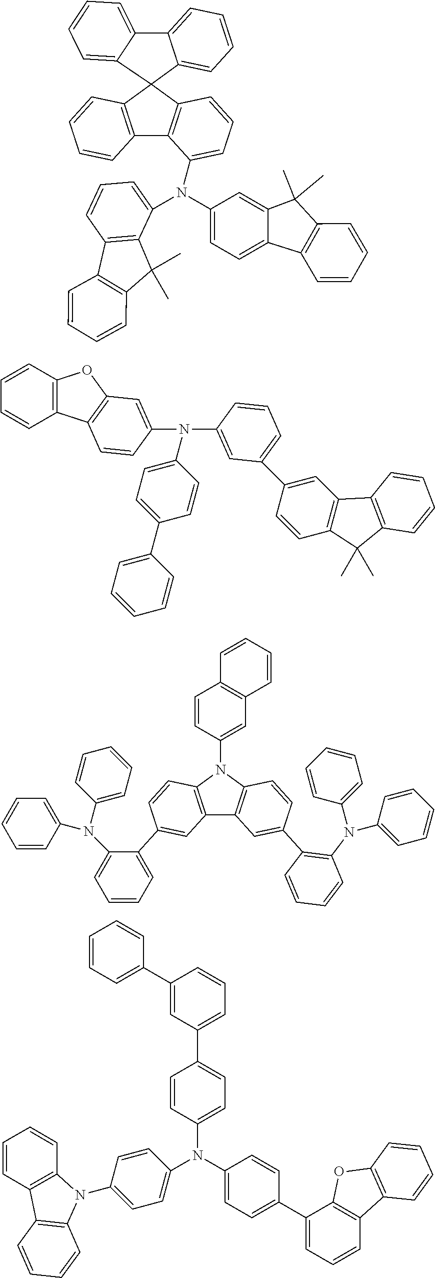

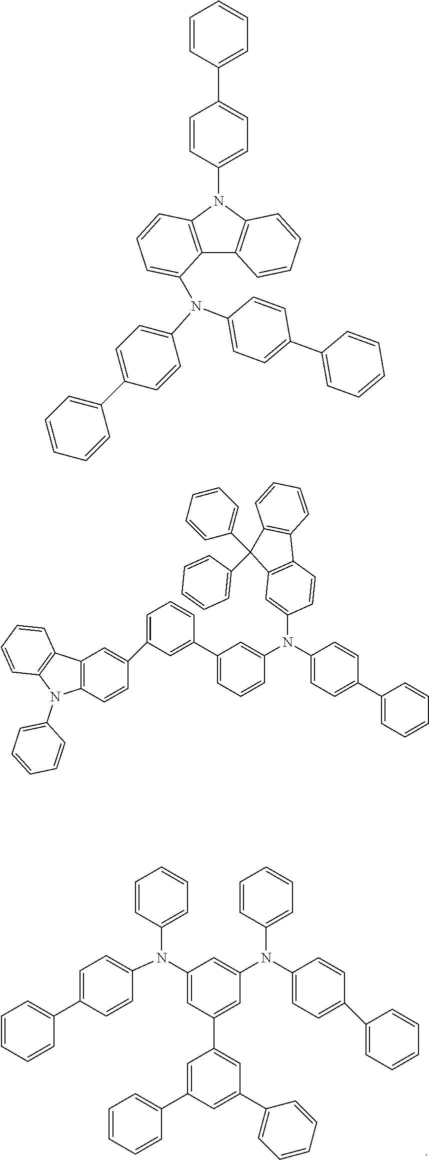 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

The hole transport region HTR may include a phthalocyanine compound (such as copper phthalocyanine), N¹,N¹′-([1,1′-biphenyl]-4,4′-diyl)bis(N1-phenyl-N⁴,N⁴-di-m-tolylbenzene-1,4-diamine) (DNTPD), 4,4′,4″-[tris(3-methyl phenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylene dioxythiophene)/poly(4-styrene sulfonate) (PEDOT/PSS), polyaniline/dodecylbenzene sulfonic acid (PANI/DBSA), polyaniline/camphor sulfonic acid (PANI/CSA), polyaniline/poly(4-styrene sulfonate) (PANI/PSS), N,N′-di(naphthalene-1-yl)-N,N′-diphenyl-benzidine (NPB), triphenylamine-containing polyether ketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

The hole transport region HTR may include a carbazole-based derivative (such as N-phenyl carbazole and/or polyvinyl carbazole), a fluorene-based derivative, N,N′-bis(3-methylphenyl)-N,N′-diphenyl-[1,1-biphenyl]-4,4′-diamine (TPD), a triphenylamine-based derivative (such as 4,4′,4″-tris(N-carbazolyl)triphenylamine (TCTA)), N,N′-di(naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the aforementioned compounds of the hole transport region in at least one of the hole injection layer HIL, the hole transport layer HTL, or the electron blocking layer EBL.

A thickness of the hole transport region HTR may be about 100 Å to about 10000 Å, for example, about 100 Å to about 5000 Å. When the hole transport region HTR includes the hole injection layer HIL, the thickness of the hole injection layer HIL may be, for example, about 30 Å to about 1000 Å. When the hole transport region HTR includes the hole transport layer HTL, the thickness of the hole transport layer HTL may be about 30 Å to about 1000 Å. For example, when the hole transport region HTR includes the electron blocking layer EBL, the thickness of the electron blocking layer EBL may be about 10 Å to about 1000 Å. When the thicknesses of the hole transport region HTR, the hole injection layer HIL, the hole transport layer HTL, and the electron blocking layer EBL satisfy the above-described ranges, satisfactory hole transport properties may be obtained without substantial increase of a driving voltage.

The hole transport region HTR may further include a charge generating material in addition to the above-described materials to improve conductivity. The charge generating material may be substantially uniformly or non-uniformly dispersed in the hole transport region HTR. The charge generating material may be, for example, a p-dopant. The p-dopant may include at least one among a halogenated metal compound, a quinone derivative, metal oxide, and a cyano group-containing compound, but embodiments of the present disclosure are not limited thereto. For example, the p-dopant may include a halogenated metal compound (such as CuI and/or Rbl), a quinone derivative (such as tetracyanoquinodimethane (TCNQ) and/or 2,3,5,6-tetrafluoro-7,7′,8,8-tetracyanoquinodimethane (F4-TCNQ)), a metal oxide (such as tungsten oxide and molybdenum oxide), a cyano group-containing compound (such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile), but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for an optical resonance distance of the wavelength of light emitted from the emission layer EML to increase light luminous efficiency. Materials that may be included in the hole transport region HTR may be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example about 100 Å to about 1000 Å or about 100 Å to about 300 Å. The emission layer EML may have a single layer formed utilizing a single material, a single layer formed utilizing a plurality of different materials, or a multilayer structure having a plurality of layers formed utilizing a plurality of different materials.

The emission layer EML may be to emit at least one of red light, green light, blue light, white light, yellow light, or cyan light. The emission layer EML may include a fluorescence material and/or a phosphorescence material.

In an embodiment, the emission layer EML may be a fluorescent emission layer. For example, some of the light emitted from the emission layer EML may be produced by thermally activated delayed fluorescence (TADF). For example, the emission layer EML may include a light emitting component to emit thermally activated delayed fluorescence, and in an embodiment, the emission layer EML may be a thermally activated delayed fluorescence emission layer to emit blue light.

An organic electroluminescence device ED according to an embodiment includes a polycyclic compound according to an embodiment of the present disclosure. For example, an emission layer EML of an organic electroluminescence device ED according to an embodiment includes a polycyclic compound according to an embodiment of the present disclosure.

In the description, the term “substituted or unsubstituted” refers to being unsubstituted, or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group. Each of the exemplified substituents may be substituted or unsubstituted. For example, a biphenyl group may be interpreted as a named aryl group, or as a phenyl group substituted with a phenyl group.

In the description, the phase “combined with an adjacent group to form a ring” may refer to being combined with an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and heterocycle may each independently be a monocycle or a polycycle. In some embodiments, the ring formed by combining with each other may be connected to another ring to form a spiro structure.

In the description, the term “adjacent group” may refer to a substituent on the same atom or point, a substituent on an atom that is directly connected to the base atom or point, or a substituent sterically positioned (e.g., within intramolecular bonding distance) to the nearest position to a corresponding substituent. For example, in 1,2-dimethylbenzene, two methyl groups may be interpreted as “adjacent groups” to each other, and in 1,1-diethylcyclopentane, two ethyl groups may be interpreted as “adjacent groups” to each other. In 4,5-dimethylphenanthrene, two methyl groups may be interpreted as “adjacent groups” to each other.

In the description, examples of the halogen atom may include a fluorine atom, a chlorine atom, a bromine atom, and an iodine atom.

In the description, the alkyl may be a linear, branched, or cyclic group. The number of carbon atoms of the alkyl group may be 1 to 50, 1 to 30, 1 to 20, 1 to 10, or 1 to 6. Examples of the alkyl group may include, but are not limited to, methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, and/or the like.

In the description, an alkenyl group may be a hydrocarbon group including one or more carbon-carbon double bonds in the middle or end of an alkyl group having 2 or more carbon atoms. The alkenyl group may be linear or branched. The number of carbon atoms is not particularly limited, and for example may be 2 to 30, 2 to 20, or 2 to 10. Examples of the alkenyl group may include, but are not limited to, a vinyl group, a 1-butenyl group, a 1-pentenyl group, a 1,3-butadienyl aryl group, a styrenyl group, a styrylvinyl group, and/or the like.

In the description, an alkynyl group refers to a hydrocarbon group including one or more carbon-carbon triple bonds in the middle or end of an alkyl group having 2 or more carbon atoms. The alkynyl group may be linear or branched. The number of carbon atoms is not particularly limited, but is 2 to 30, 2 to 20, or 2 to 10. Non-limiting examples of the alkynyl group may include, but are not limited to, an ethynyl group, a propynyl group, and/or the like.

In the description, the aryl group may be an optional functional group or substituent derived from an aromatic hydrocarbon ring. The aryl group may be a monocyclic aryl group or a polycyclic aryl group. The number of ring-forming carbon atoms of the aryl group may be 6 to 30, 6 to 20, or 6 to 15. Examples of the aryl group may include, but are not limited to, phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, and/or the like.

In the description, the heteroaryl group may include one or more among boron (B), oxygen (O), nitrogen (N), phosphorus (P), silicon (Si) and sulfur (S) as a heteroatom. When the heteroaryl group includes two or more heteroatoms, the two or more heteroatoms may be the same as or different from each other. The heteroaryl group may be a monocyclic heterocyclic group or a polycyclic heterocyclic group. The number of ring-forming carbon atoms of the heteroaryl group may be 2 to 30, 2 to 20, or 2 to 10. Examples of the heteroaryl group may include, but are not limited to thiophene, furan, pyrrole, imidazole, triazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isoxazole, oxazole, oxadiazole, thiadiazole, phenothiazine, dibenzosilole, dibenzofuran, and/or the like.

In the description, the number of carbon atoms of the amine group may be 1 to 30, but is not particularly limited thereto. In the description, the number of carbon atoms of the amine group may be 1 to 30, but is not particularly limited thereto. Examples of the amine group may include, but are not limited to methylamine, dimethylamine, phenylamine, diphenylamine, naphthylamine, 9-methyl-anthracenylamine, triphenylamine, and/or the like.

The polycyclic compound according to an embodiment of the present disclosure is represented by Formula 1:

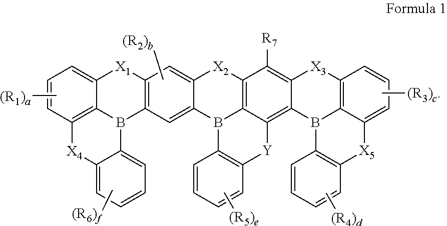

In Formula 1, X₁ to X₅ may each independently be O, NAr₁, S, or Se, Ar₁ may be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 1, Y may be O, S, or Se.

In Formula 1, R₁ to R₇ may each independently be a hydrogen atom, a deuterium atom, a halogen atom, a cyano group, a substituted or unsubstituted alkyl group having 1 to 20 carbon atoms, a substituted or unsubstituted amine group, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 1, “a” may be an integer of 0 to 3. When “a” is 2 or more, a plurality of R₁ are the same as or different from each other.

In Formula 1, “b” may be an integer of 0 to 2. When “b” is 2, a plurality of R₂ are the same as or different from each other.

In Formula 1, “c” may be an integer of 0 to 3. When “c” is 2 or more, a plurality of R₃ are the same as or different from each other.

In Formula 1, “d” may be an integer of 0 to 4. When “d” is 2 or more, a plurality of R₄ are the same as or different from each other.

In Formula 1, “e” may be an integer of 0 to 4. When “e” is 2 or more, a plurality of R₅ are the same as or different from each other.

In Formula 1, “f” may be an integer of 0 to 4. When “f” is 2 or more, a plurality of R₆ are the same as or different from each other.

In an embodiment, X₁ to X₅ may be all O or all NAr₁.

In an embodiment, one of X₁ to X₅ may O, and the other four may be NAr₁.

In an embodiment, two of X₁ to X₅ may O, and the other three may be NAr₁.

In an embodiment, three of X₁ to X₅ may O, and the other two may be NAr₁.

In an embodiment, four of X₁ to X₅ may O, and the other one may be NAr₁.

In an embodiment, in Formula 1, the sum of “a” and “c” may be integer of 1 or more, and at least one of R₁ or R₃ may be a substituted amine group.

In an embodiment, Formula 1 may be represented by Formula 2-1 or Formula 2-2:

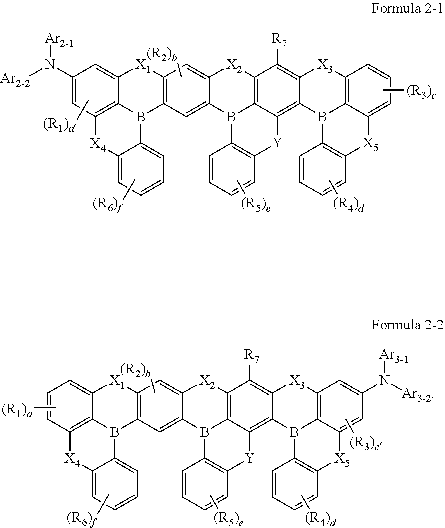

In Formula 2-1, Ar₂₋₁ and Ar₂₋₂ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 2-1, a′ may be an integer of 0 to 2. When a′ is 2, a plurality of R₁ are the same as or different from each other.

In Formula 2-2, Ar₃₋₁ and Ar₃₋₂ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 2-2, c′ may be an integer of 0 to 2. When c′ is 2, a plurality of R₃ are the same as or different from each other.

In Formula 2-1 and Formula 2-2, X₁ to X₅, Y, R₁ to R₇, and “a” to “f” may each independently be the same as defined in Formula 1.

In an embodiment, Formula 1 may be represented by Formula 3:

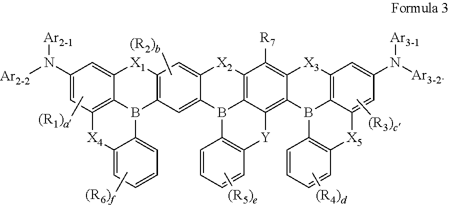

In Formula 3, Ar₂₋₁, Ar₂₋₂, Ar₃₋₁, and Ar₃₋₂ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 3, a′ may be an integer of 0 to 2. When a′ is 2, a plurality of R₁ are the same as or different from each other.

In Formula 3, c′ may be an integer of 0 to 2. When c′ is 2, a plurality of R₃ are the same as or different from each other.

In Formula 3, X₁ to X₅, Y, R₁ to R₇, “b”, and “d” to “f” may each independently be the same as defined in Formula 1.

In an embodiment, in Formula 3, Ar₂₋₁, Ar₂₋₂, Ar₃₋₁, and Ar₃₋₂ may each independently be a substituted or unsubstituted ring-forming aryl group having 6 to 18 carbon atoms.

In an embodiment, Formula 1 may be represented by any one among Formula 4-1 to Formula 4-4:

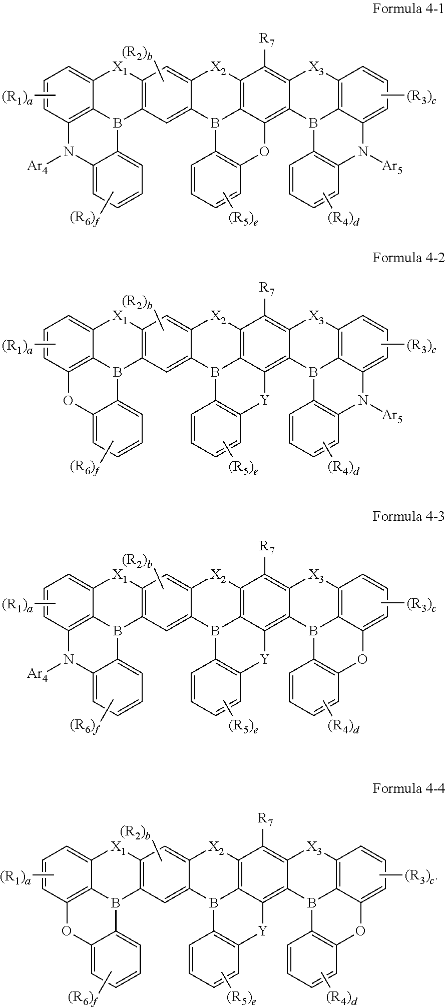

In Formula 4-1 to Formula 4-3, Ar₄ and Ar₅ may each independently be a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms.

In Formula 4-1 to Formula 4-4, X₁ to X₃, Y, R₁ to R₇, and “a” to “f” may each independently be the same as defined in Formula 1.

In an embodiment, Formula 1 may be represented by any one among Formula 5-1 to Formula 5-3:

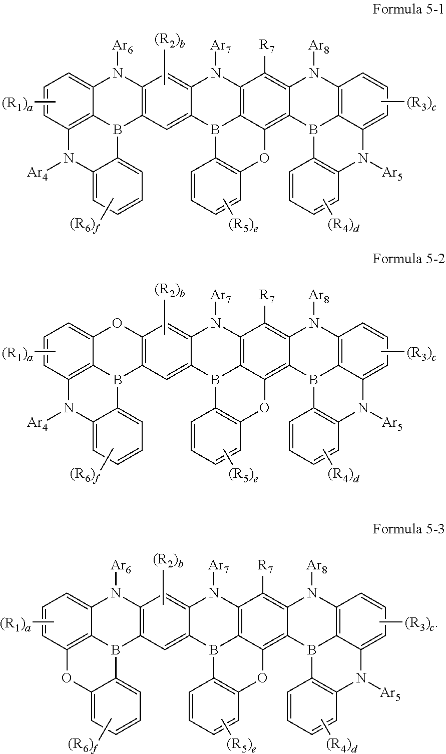

In Formula 5-1 to Formula 5-3, Ar₄ to Ar₈ may each independently be a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

In Formula 5-1 to Formula 5-3, Y, R₁ to R₇, and, “a” to “f” may each independently be the same as defined in Formula 1.

In an embodiment, Ar₄ to Ar₈ may each independently be represented by any one among Formula 6-1 to Formula 6-3:

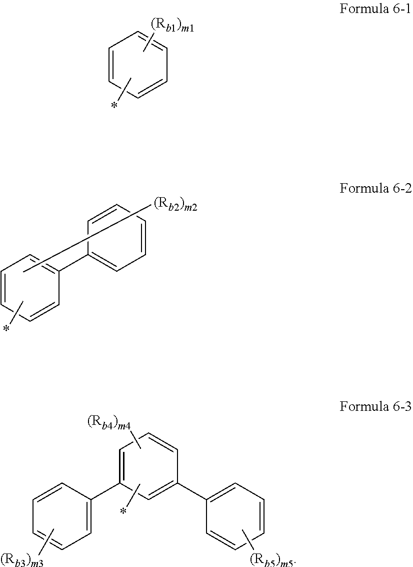

In Formula 6-1 to Formula 6-3, R_{b1} to R_{b5} may each independently be a hydrogen atom, a deuterium atom, a halogen atom, a cyano group, a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring.

m1 may be an integer of 0 to 5. When m1 is 2 or more, a plurality of R_{b1} are the same as or different from each other.

m2 may be an integer of 0 to 9. When m2 is 2 or more, a plurality of R_{b2} are the same as or different from each other.

m3 may be an integer of 0 to 5. When m3 is 2 or more, a plurality of R_{b3} are the same as or different from each other.

m4 may be an integer of 0 to 3. When m4 is 2 or more, a plurality of R_{b4} are the same as or different from each other.

m5 may be an integer of 0 to 5. When m5 is 2 or more, a plurality of R_{b5} are the same as or different from each other.

In an embodiment, the polycyclic compound represented by Formula 1 may be any one among the compounds represented in Compound Group 1. However, embodiments of the present disclosure are not limited thereto.

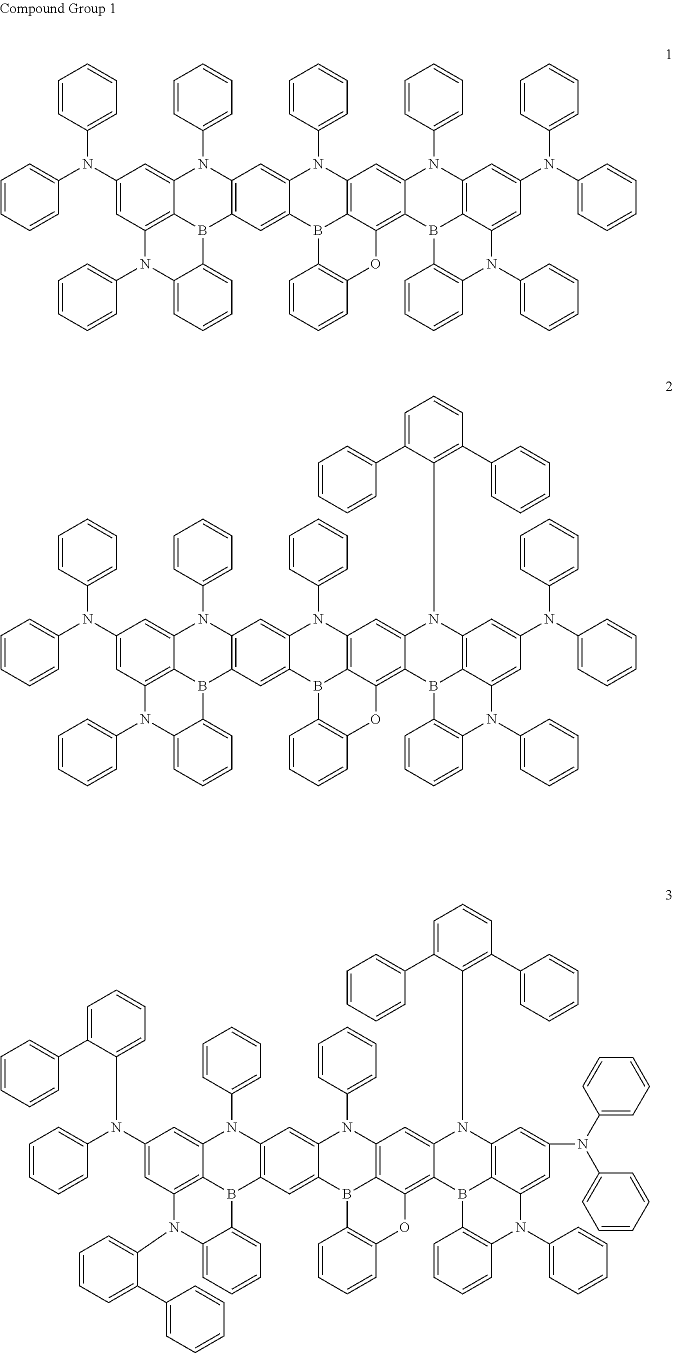

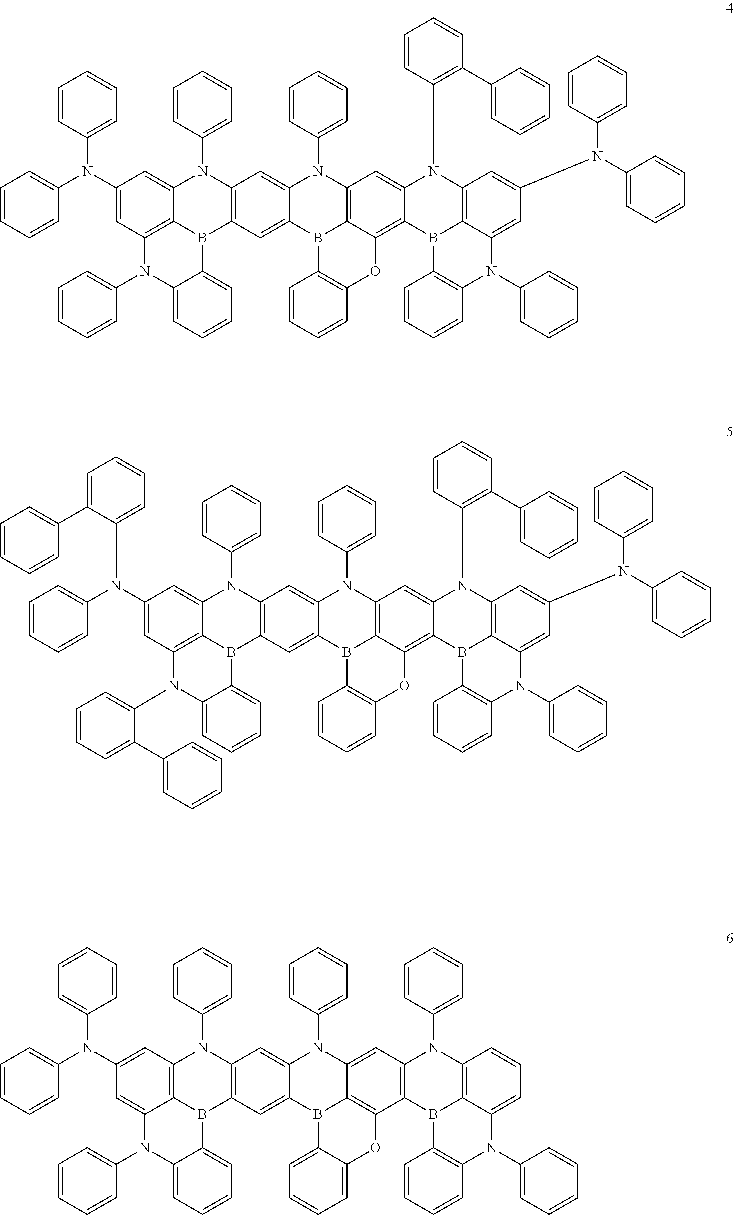

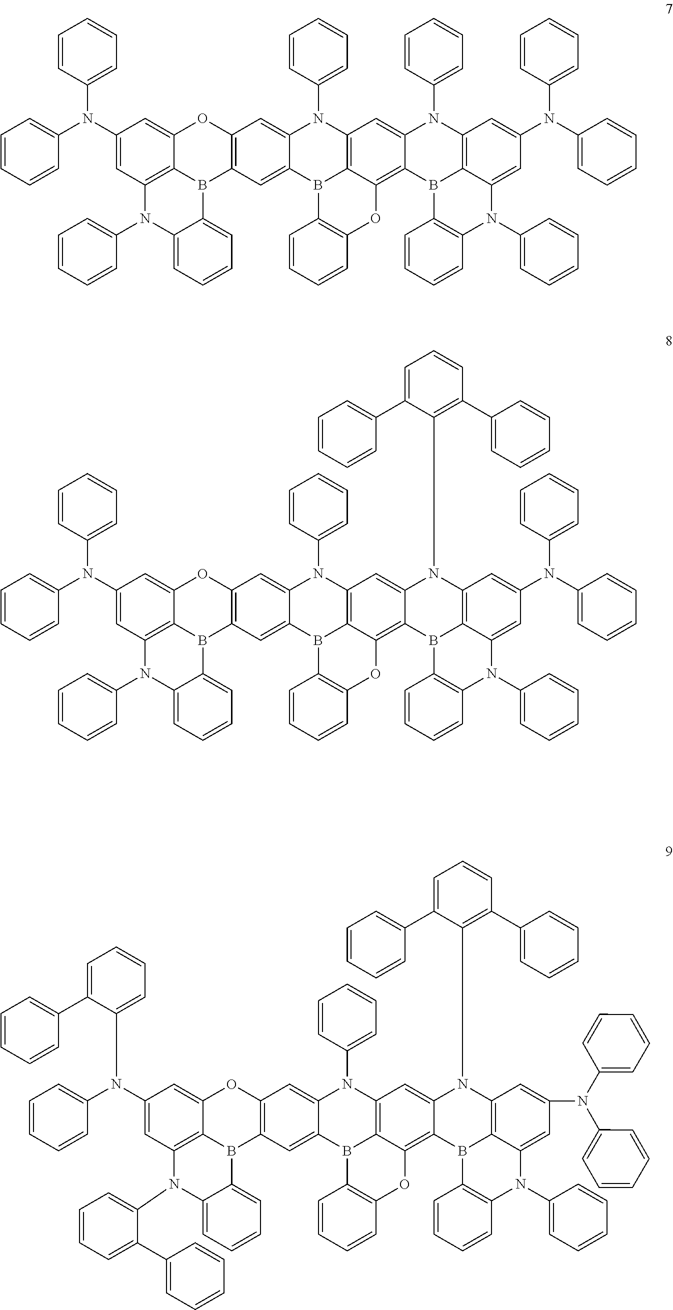

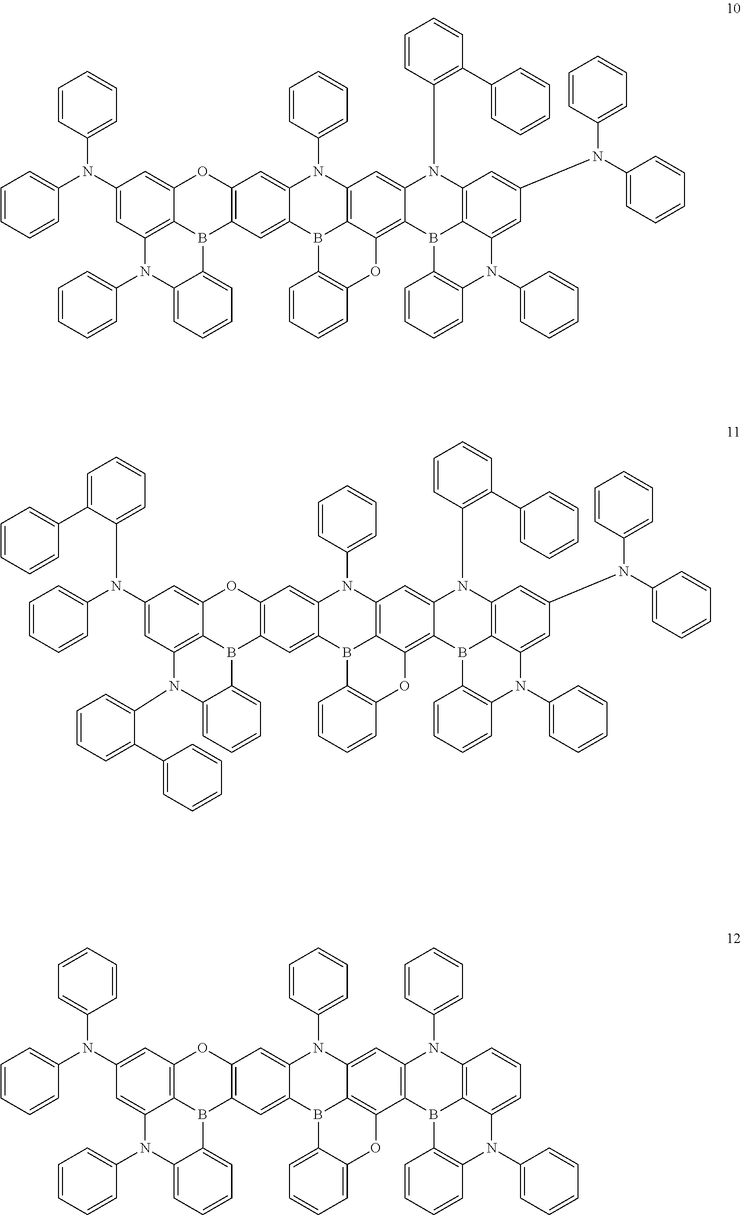

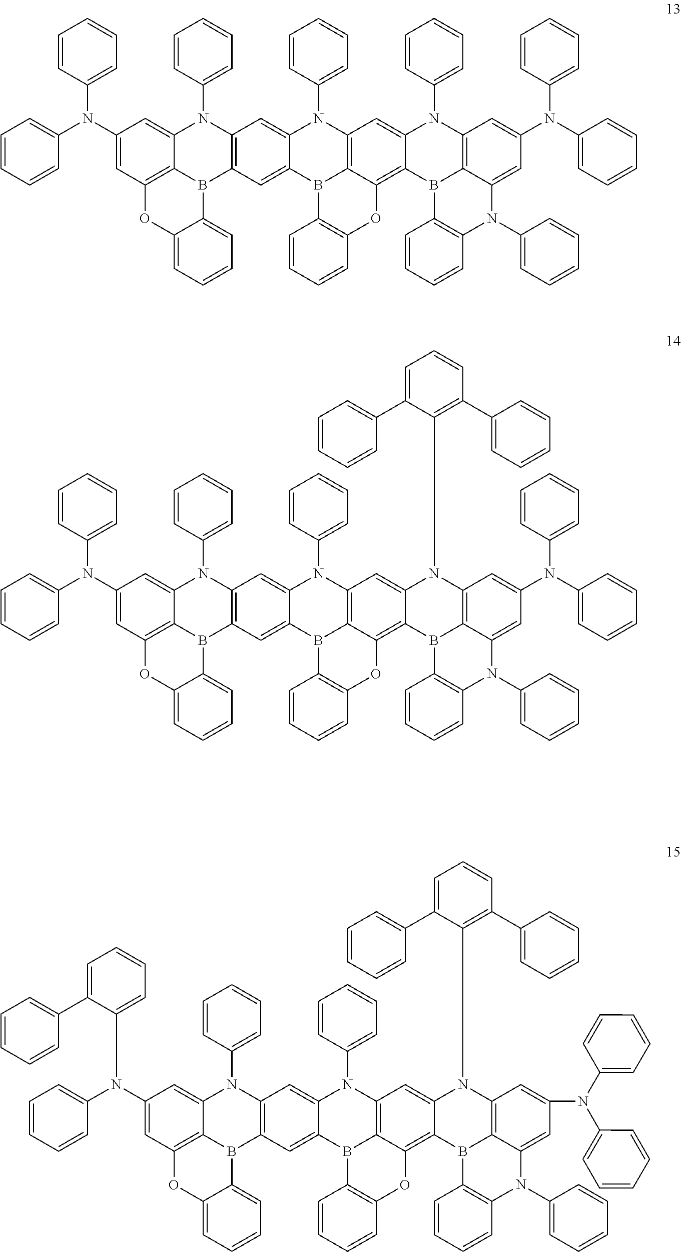

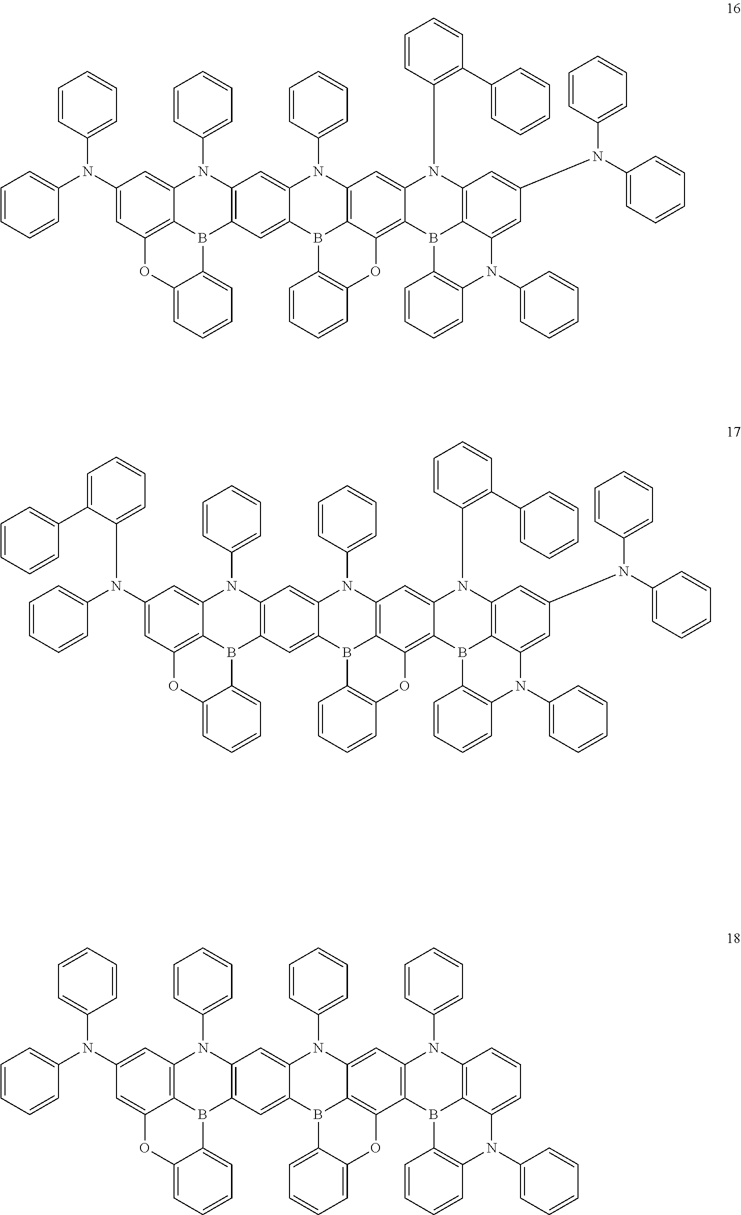 [SMILES: c1ccc(-c2ccccc2N2c3cc(N(c4ccccc4)c4ccccc4)cc4c3B(c3ccccc3N4c3ccccc3)c3c2cc2c4c3Oc3ccccc3B4c3cc4c(cc3N2c2ccccc2)N(c2ccccc2)c2cc(N(c3ccccc3)c3ccccc3)cc3c2B4c2ccccc2O3)cc1 ; c1ccc(-c2ccccc2N(c2ccccc2)c2cc3c4c(c2)N(c2ccccc2)c2cc5c(cc2B4c2ccccc2O3)B2c3ccccc3Oc3c2c(cc2c3B3c4ccccc4N(c4ccccc4)c4cc(N(c6ccccc6)c6ccccc6)cc(c43)N2c2ccccc2-c2ccccc2)N5c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4N(c4ccccc4)c4cccc(c43)N2c2ccccc2)N5c2ccccc2)cc1]

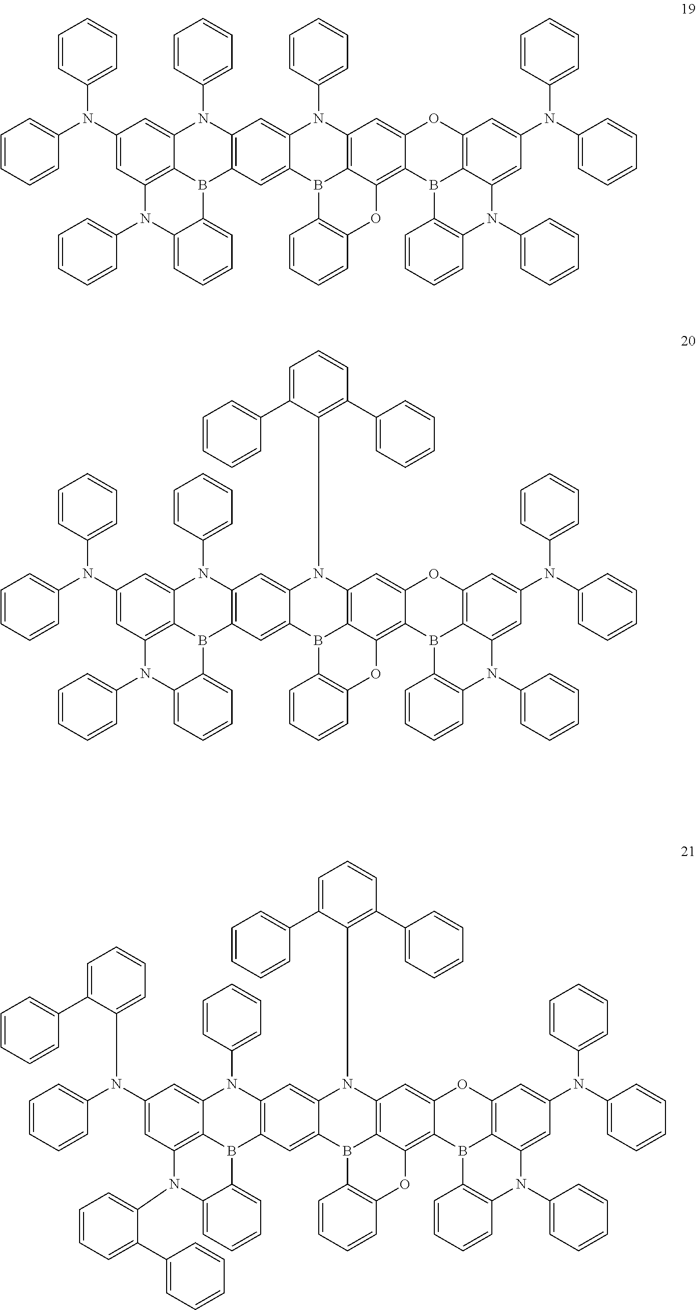

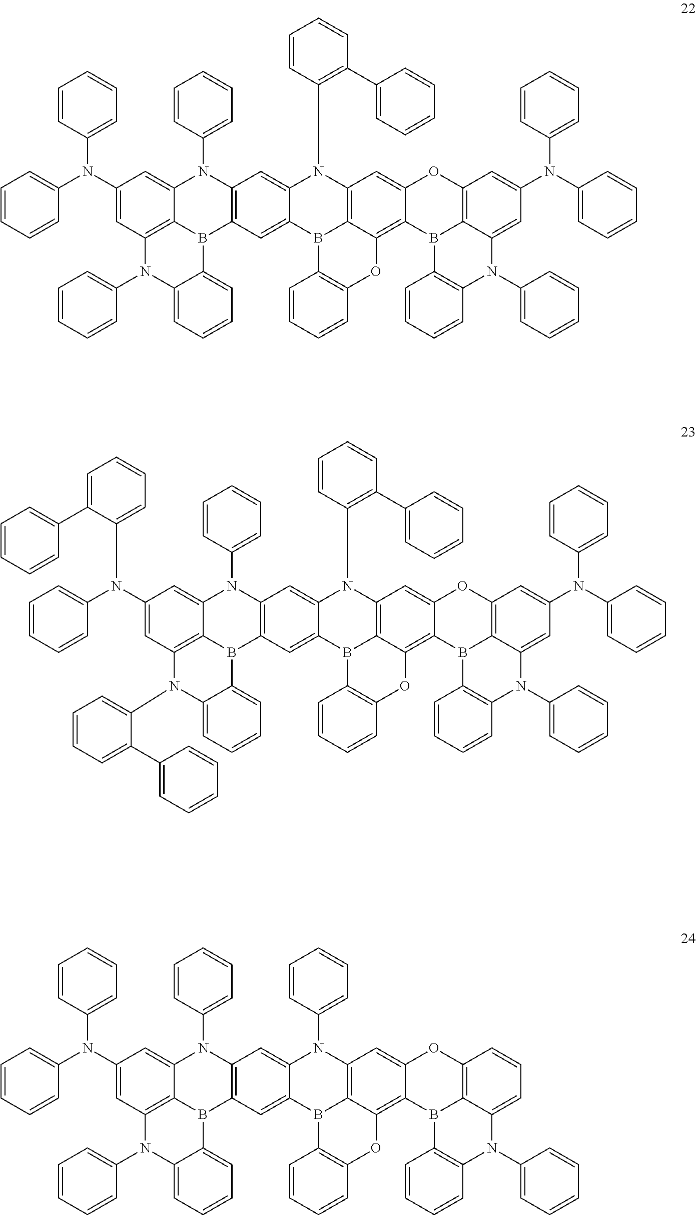

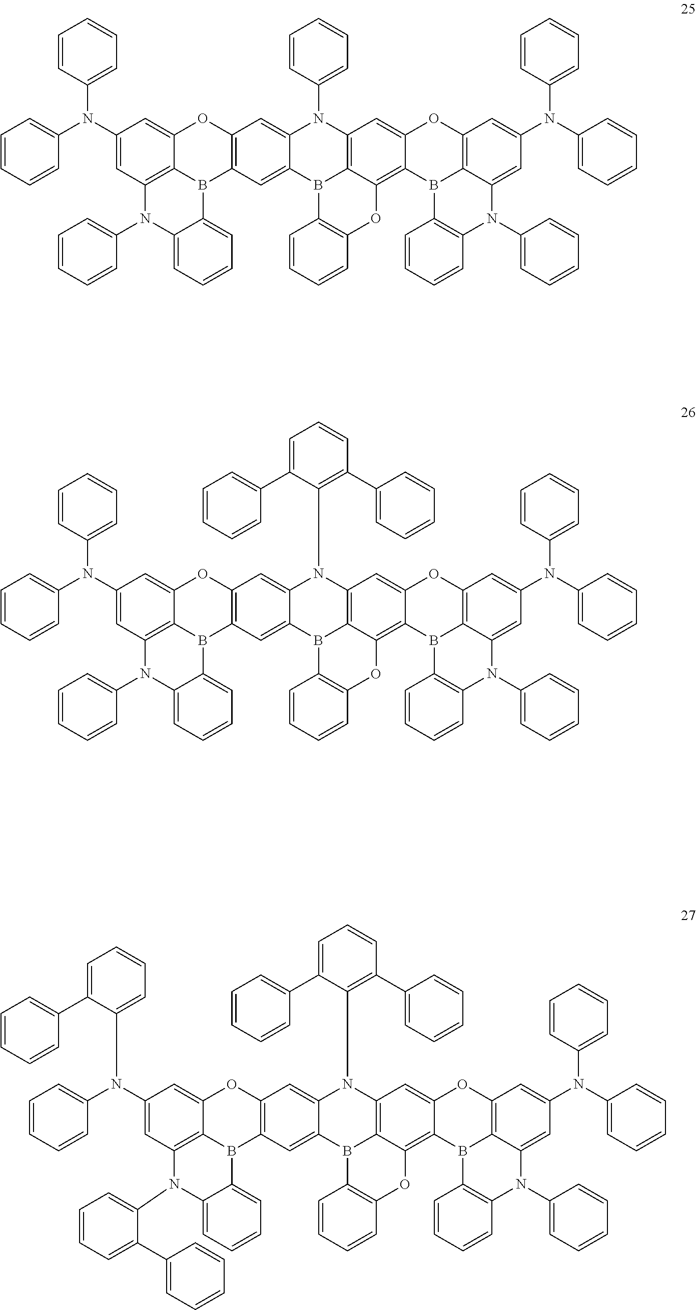

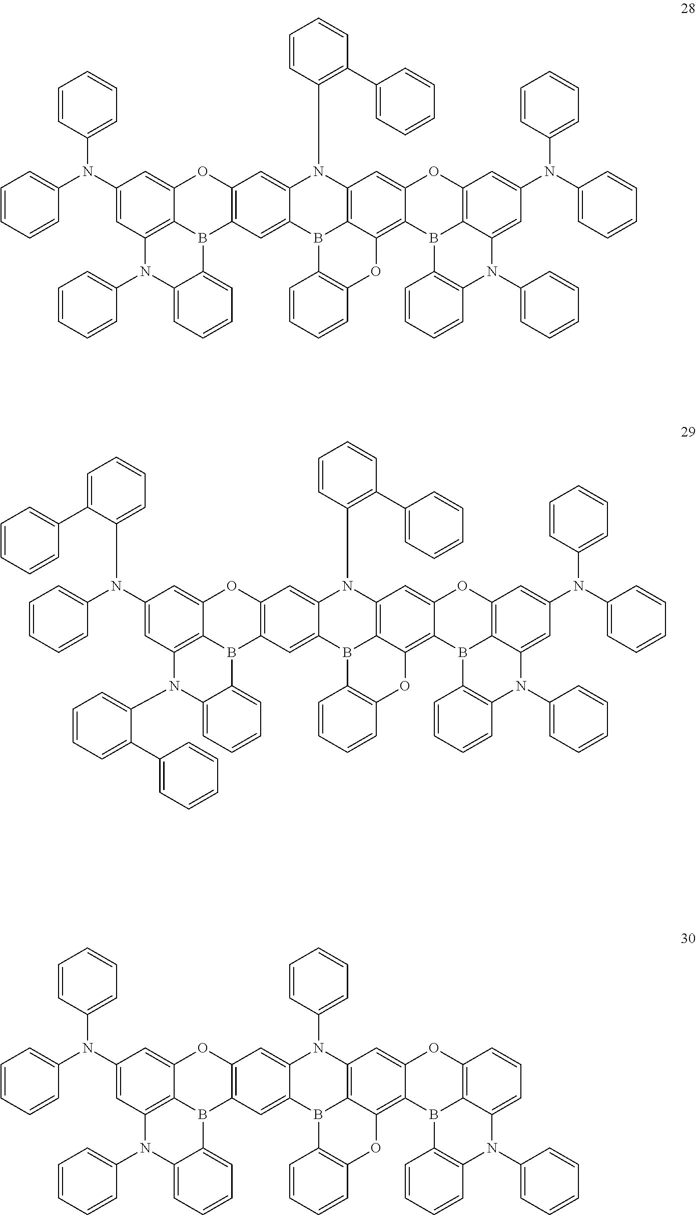 [SMILES: c1ccc(-c2ccccc2N2c3cc4c(cc3B3c5ccccc5Oc5c6c(cc2c53)Oc2cc(N(c3ccccc3)c3ccccc3)cc3c2B6c2ccccc2N3c2ccccc2)B2c3ccccc3N(c3ccccc3)c3cc(N(c5ccccc5)c5ccccc5)cc(c32)O4)cc1 ; c1ccc(-c2ccccc2N(c2ccccc2)c2cc3c4c(c2)N(c2ccccc2-c2ccccc2)c2ccccc2B4c2cc4c(cc2O3)N(c2ccccc2-c2ccccc2)c2cc3c(c5c2B4c2ccccc2O5)B2c4ccccc4N(c4ccccc4)c4cc(N(c5ccccc5)c5ccccc5)cc(c42)O3)cc1 ; c1ccc(N(c2ccccc2)c2cc3c4c(c2)N(c2ccccc2)c2ccccc2B4c2cc4c(cc2O3)N(c2ccccc2)c2cc3c(c5c2B4c2ccccc2O5)B2c4ccccc4N(c4ccccc4)c4cccc(c42)O3)cc1]

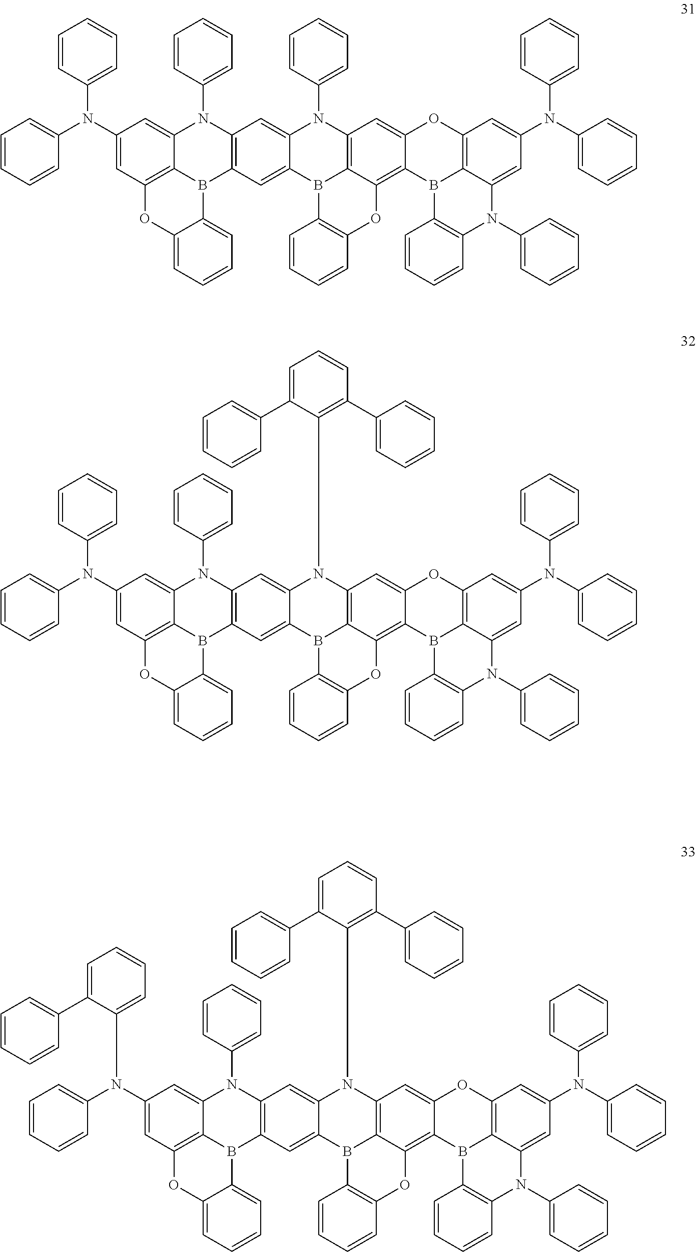

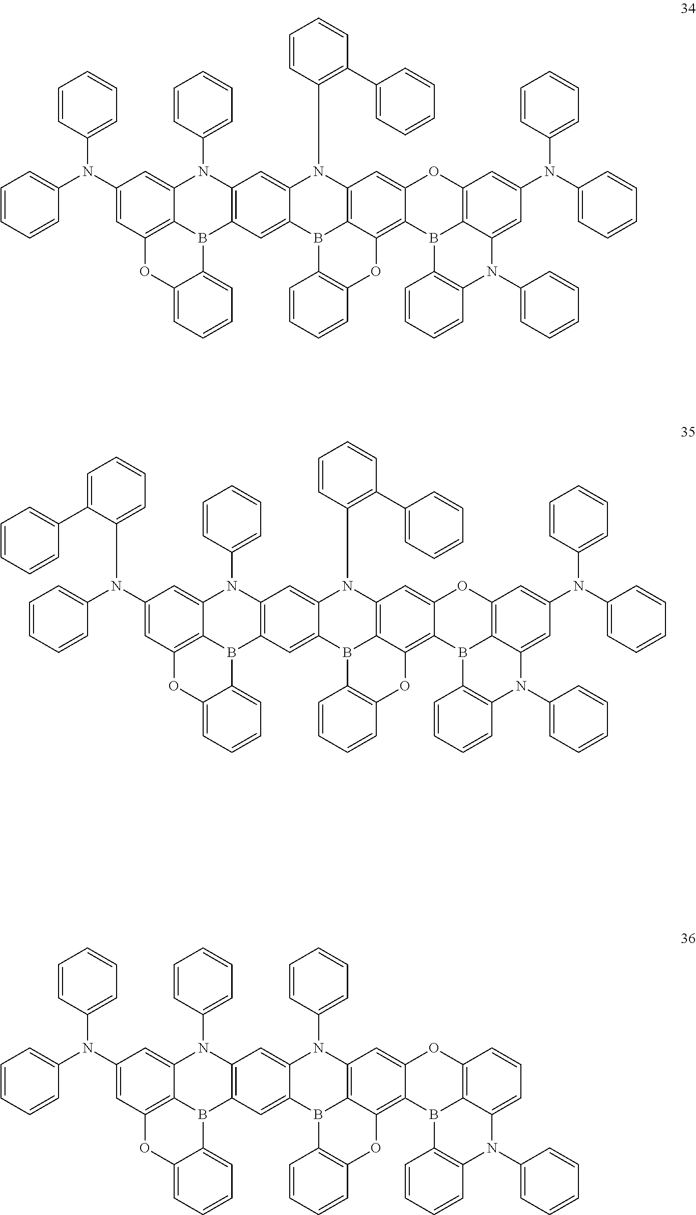 [SMILES: c1ccc(-c2ccccc2N2c3cc4c(cc3B3c5ccccc5Oc5c6c(cc2c53)Oc2cc(N(c3ccccc3)c3ccccc3)cc3c2B6c2ccccc2N3c2ccccc2)B2c3ccccc3Oc3cc(N(c5ccccc5)c5ccccc5)cc(c32)N4c2ccccc2)cc1 ; c1ccc(-c2ccccc2N(c2ccccc2)c2cc3c4c(c2)N(c2ccccc2)c2cc5c(cc2B4c2ccccc2O3)B2c3ccccc3Oc3c4c(cc(c32)N5c2ccccc2-c2ccccc2)Oc2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c4c(cc(c32)N5c2ccccc2)Oc2cccc3c2B4c2ccccc2N3c2ccccc2)cc1]

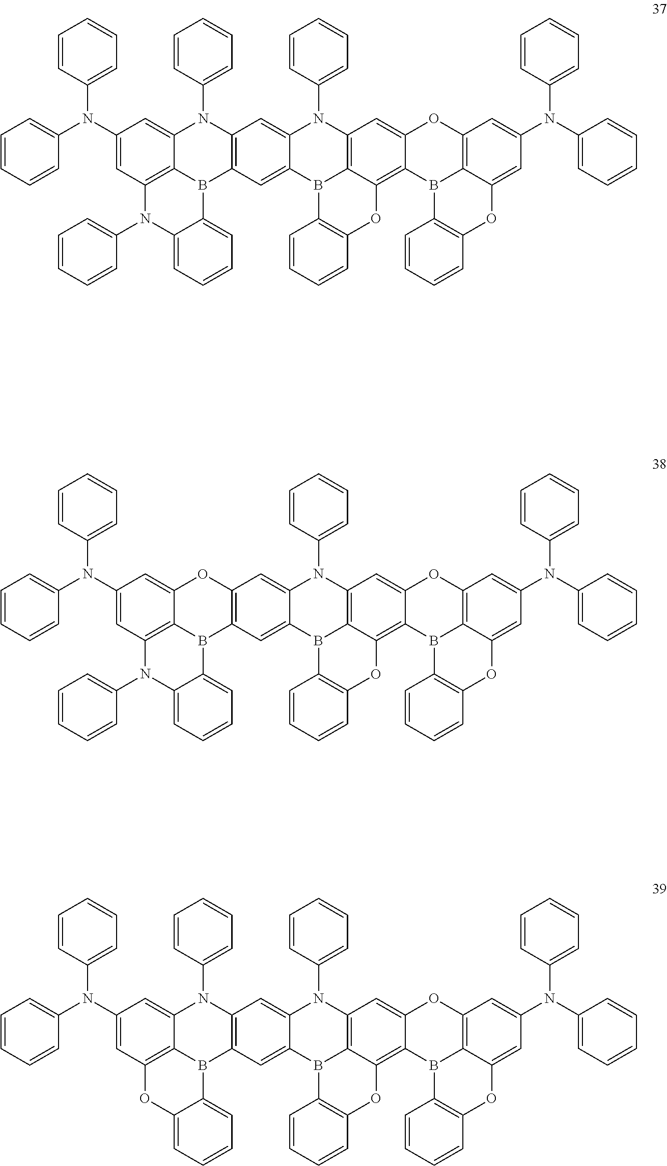 [SMILES: c1ccc(N(c2ccccc2)c2cc3c4c(c2)Oc2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2N5c2ccccc2)Oc2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2O4)cc1]

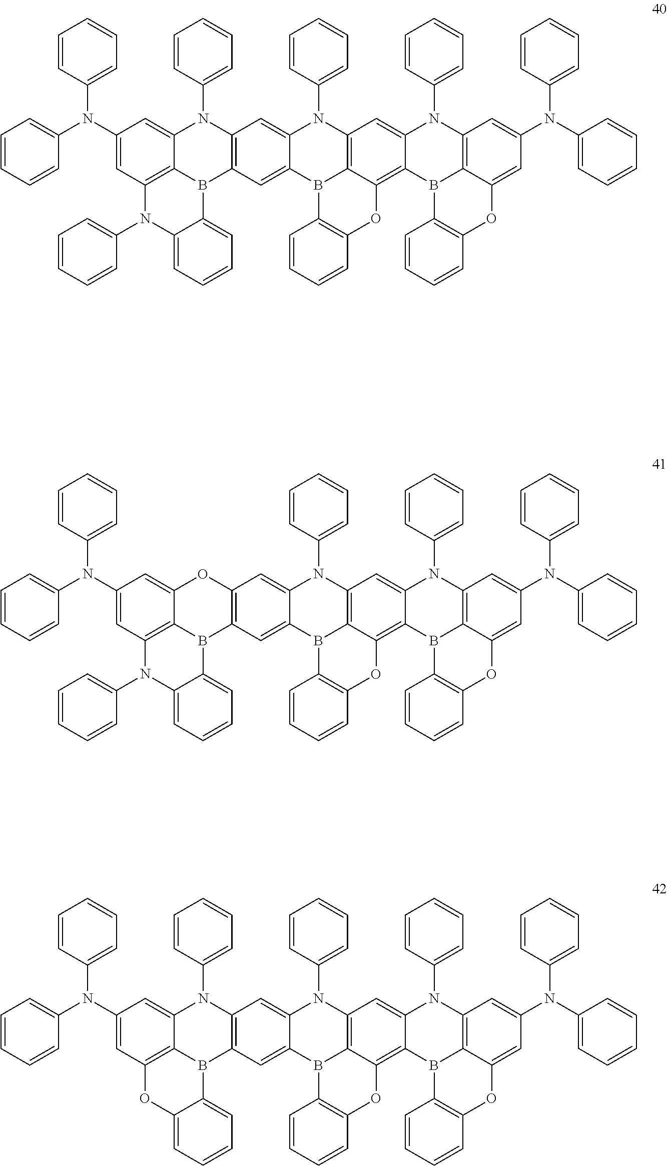 [SMILES: c1ccc(N(c2ccccc2)c2cc3c4c(c2)N(c2ccccc2)c2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc3c(c5c2B4c2ccccc2O5)B2c4ccccc4Oc4cc(N(c5ccccc5)c5ccccc5)cc(c42)N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4Oc4cc(N(c6ccccc6)c6ccccc6)cc(c43)N2c2ccccc2)N5c2ccccc2)cc1]

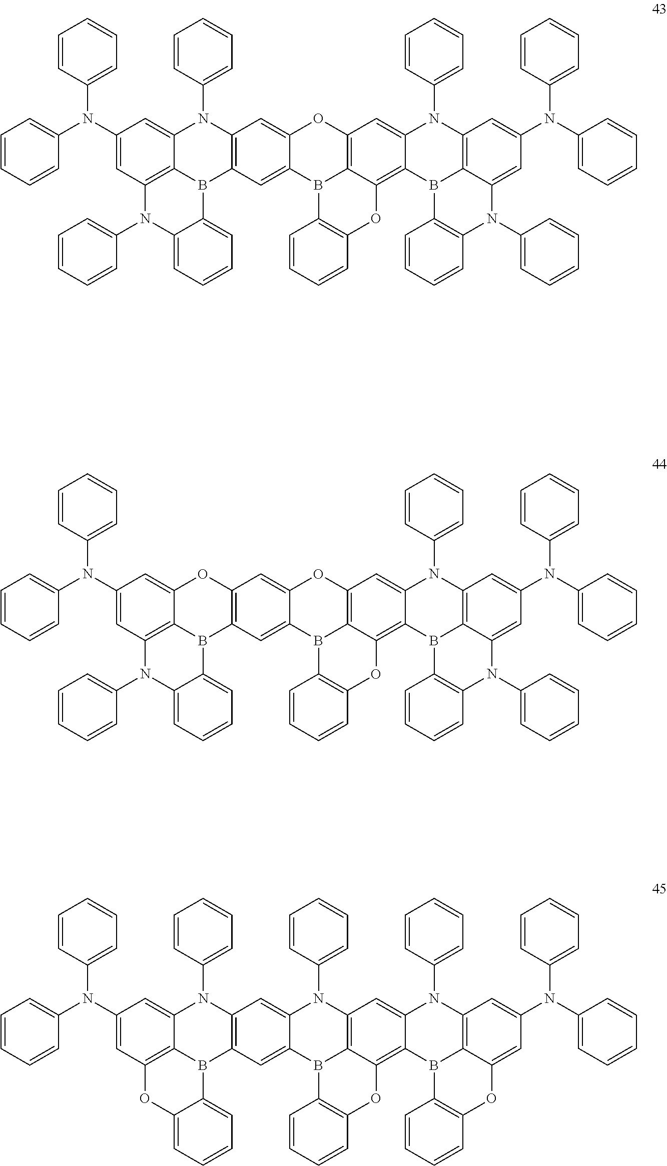 [SMILES: c1ccc(N(c2ccccc2)c2cc3c4c(c2)N(c2ccccc2)c2cc5c(cc2B4c2ccccc2N3c2ccccc2)B2c3ccccc3Oc3c2c(cc2c3B3c4ccccc4N(c4ccccc4)c4cc(N(c6ccccc6)c6ccccc6)cc(c43)N2c2ccccc2)O5)cc1 ; c1ccc(N(c2ccccc2)c2cc3c4c(c2)N(c2ccccc2)c2ccccc2B4c2cc4c(cc2O3)Oc2cc3c(c5c2B4c2ccccc2O5)B2c4ccccc4N(c4ccccc4)c4cc(N(c5ccccc5)c5ccccc5)cc(c42)N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4Oc4cc(N(c6ccccc6)c6ccccc6)cc(c43)N2c2ccccc2)N5c2ccccc2)cc1]

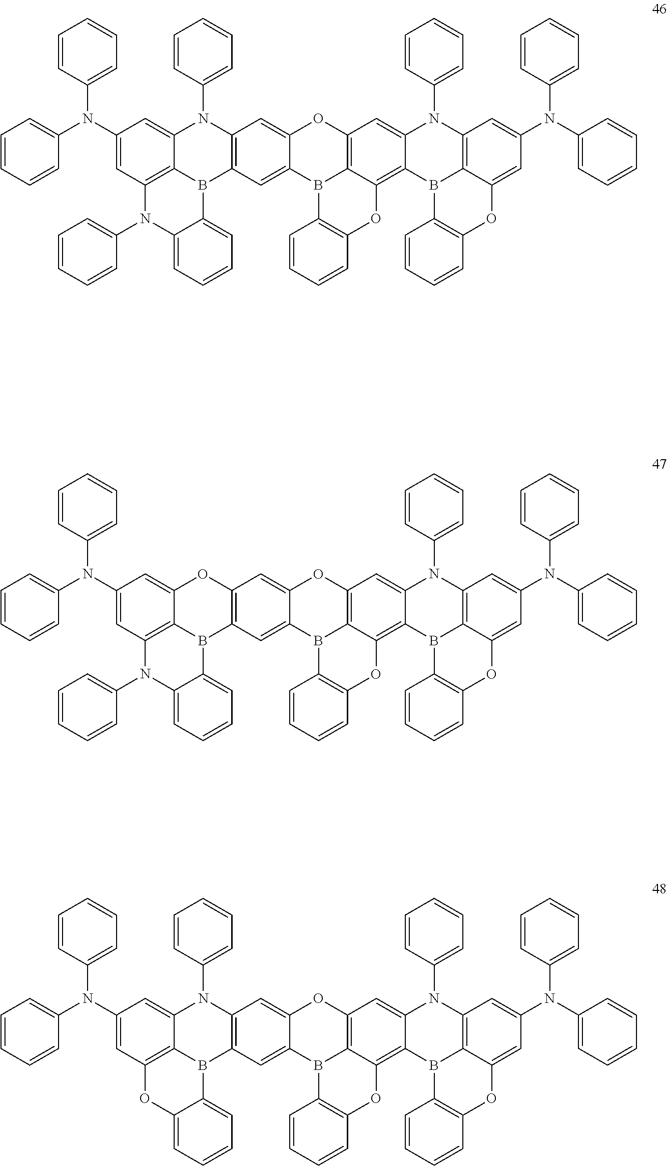 [SMILES: c1ccc(N(c2ccccc2)c2cc3c4c(c2)N(c2ccccc2)c2cc5c6c(c2B4c2ccccc2O3)Oc2ccccc2B6c2cc3c(cc2O5)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2ccccc2B4c2cc4c(cc2O3)Oc2cc3c(c5c2B4c2ccccc2O5)B2c4ccccc4Oc4cc(N(c5ccccc5)c5ccccc5)cc(c42)N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4Oc4cc(N(c6ccccc6)c6ccccc6)cc(c43)N2c2ccccc2)O5)cc1]

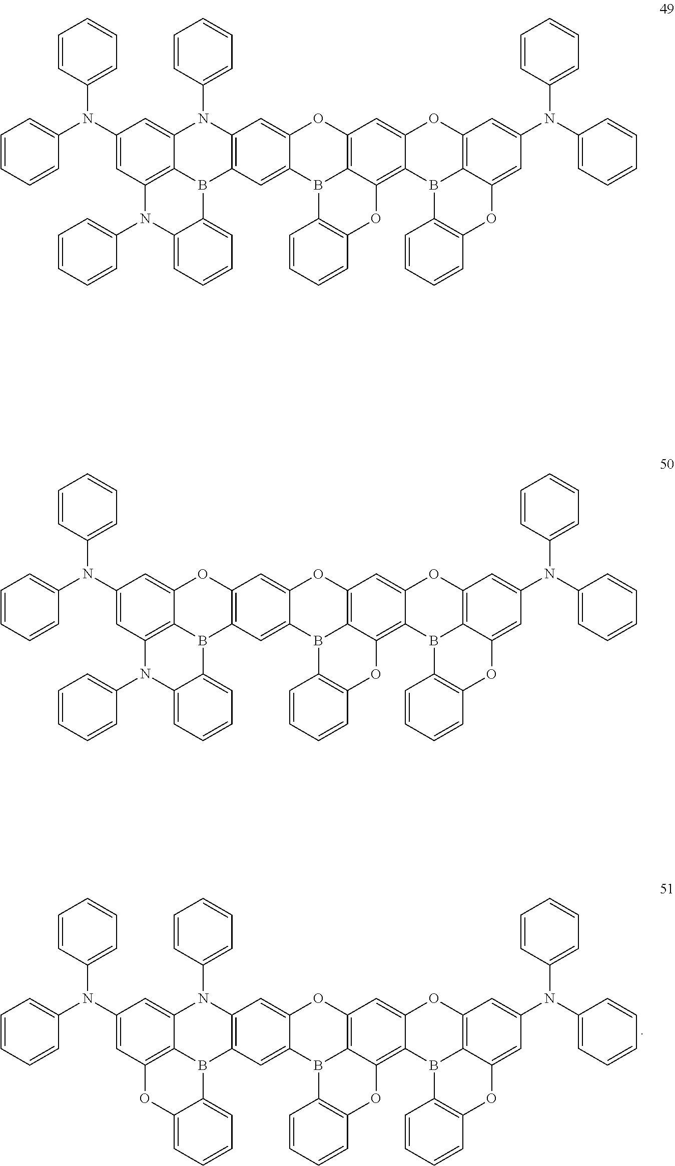 [SMILES: c1ccc(N(c2ccccc2)c2cc3c4c(c2)Oc2cc5c6c(c2B4c2ccccc2O3)Oc2ccccc2B6c2cc3c(cc2O5)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2O5)Oc2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2O5)N(c2ccccc2)c2cc(N(c4ccccc4)c4ccccc4)cc4c2B3c2ccccc2O4)cc1]

The polycyclic compound according to an embodiment may have a multiple-resonance structure (e.g. a structure capable of multiple resonance structures) having a wide plate-like skeleton structure by including a structure in which 7 aromatic rings are connected through 3 boron atoms and 6 heteroatoms, compared to a polycyclic compound including a (e.g., one) boron atom and a (e.g., one) nitrogen atom in the core.

Accordingly, the polycyclic compound according to an embodiment may include 3 boron atoms and exhibit multiple resonance structures in a wide plate-like skeleton structure so that the HOMO and LUMO states are easily separated, and thus may be utilized as a delayed fluorescence material. The polycyclic compound according to an embodiment may have a decreased energy difference (AEST) between the lowest triplet excitation energy level (T1 level) and the lowest singlet excitation energy level (S1 level) due to the structure, and the luminous efficiency of the organic electroluminescence device may be further improved when utilized as a delayed fluorescence material.

In an embodiment, the emission layer EML may include a host and a dopant, the host may be a host for a delayed fluorescence, and the dopant may be a dopant for delayed fluorescence. In some embodiments, the polycyclic compound according to an embodiment represented by Formula 1 may be included in the emission layer EML as a dopant material. For example, the polycyclic compound according to an embodiment represented by Formula 1 may be utilized as a TADF dopant.

In some embodiments, the organic electroluminescence device ED according to an embodiment may include a plurality of emission layers. The plurality of emission layers may be provided by sequentially stacking, and for example, an organic electroluminescence device ED including a plurality of emission layers may be to emit white light. The organic electroluminescence device including a plurality of emission layers may be an organic electroluminescence device having a tandem structure. When the organic electroluminescence device ED includes a plurality of emission layers, at least one emission layer EML may include the polycyclic compound according to an embodiment of the present disclosure, as described above.

In the organic electroluminescence device ED according to an embodiment, the emission layer EML may further include an anthracene derivative, a pyrene derivative, a fluoranthene derivative, a chrysene derivative, a dihydrobenzanthracene derivative, and/or a triphenylene derivative. For example, the emission layer EML may further include an anthracene derivative and/or a pyrene derivative.

The emission layer EML may include a compound represented by Formula E-1. The compound represented by Formula E-1 may be utilized as a fluorescent host material:

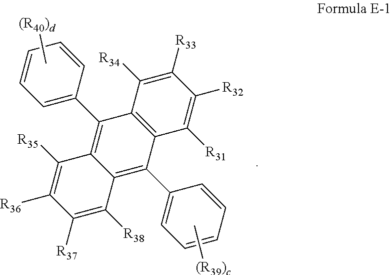

In Formula E-1, R₃₁ to R₄₀ may each independently be a hydrogen atom, a deuterium atom, a halogen atom, a substituted or unsubstituted silyl group, a substituted or unsubstituted alkyl group having 1 to 10 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring. In some embodiments, R₃₁ to R₄₀ may be combined with an adjacent group to form a saturated hydrocarbon ring or an unsaturated hydrocarbon ring.

In Formula E-1, “c” and “d” may each independently be an integer of 0 to 5.

Formula E-1 may be represented by any one among Compound E1 to Compound E19.

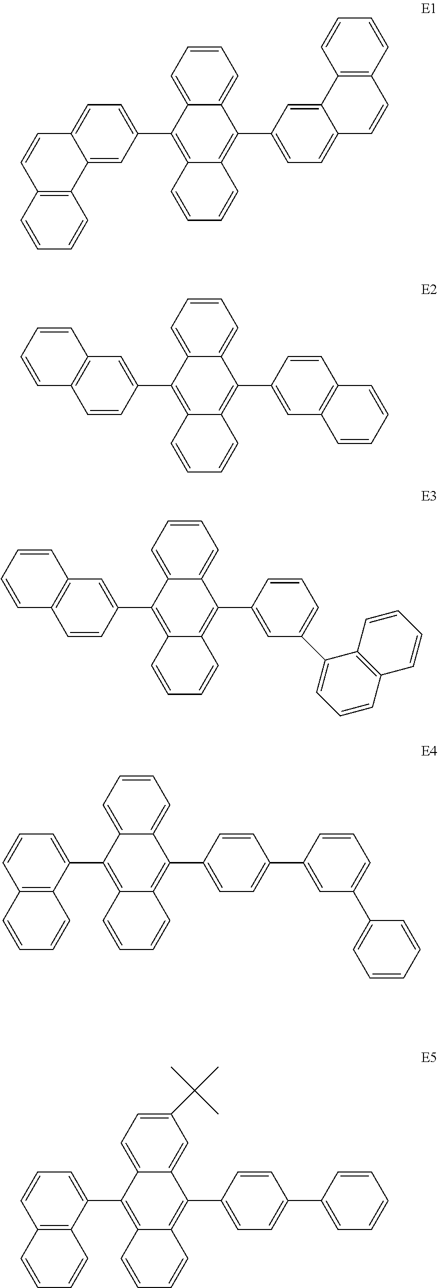

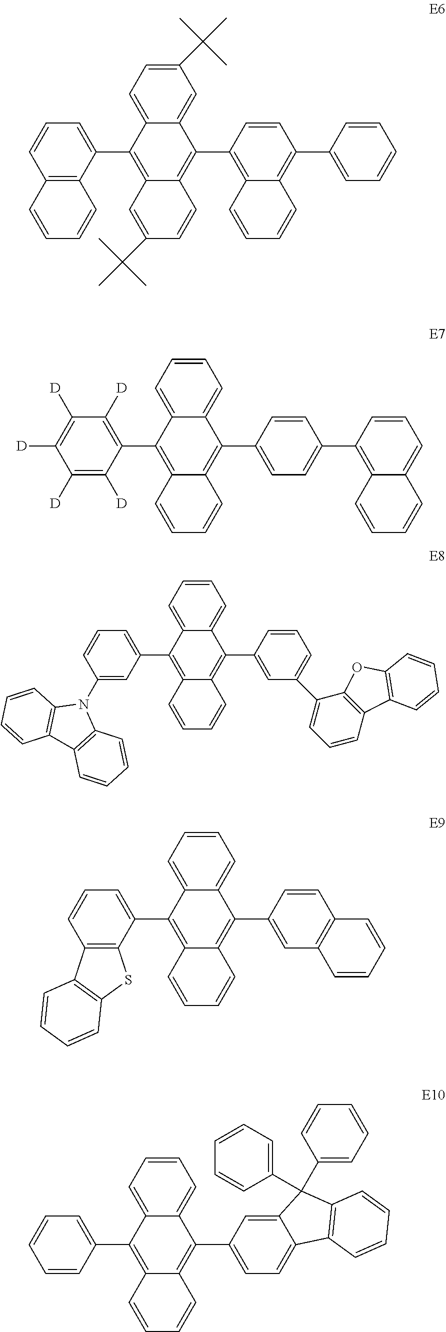

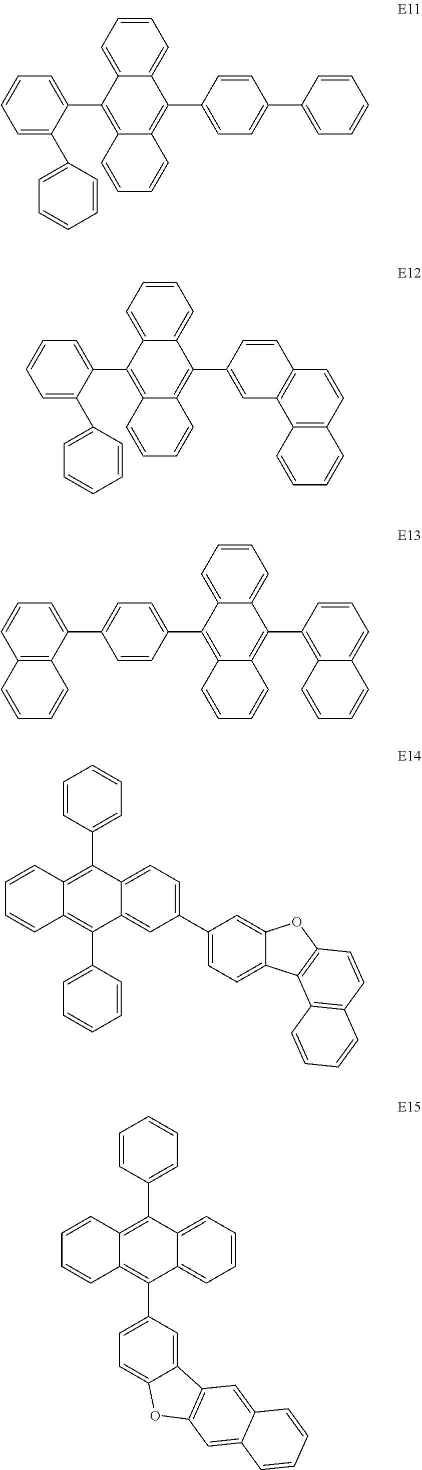

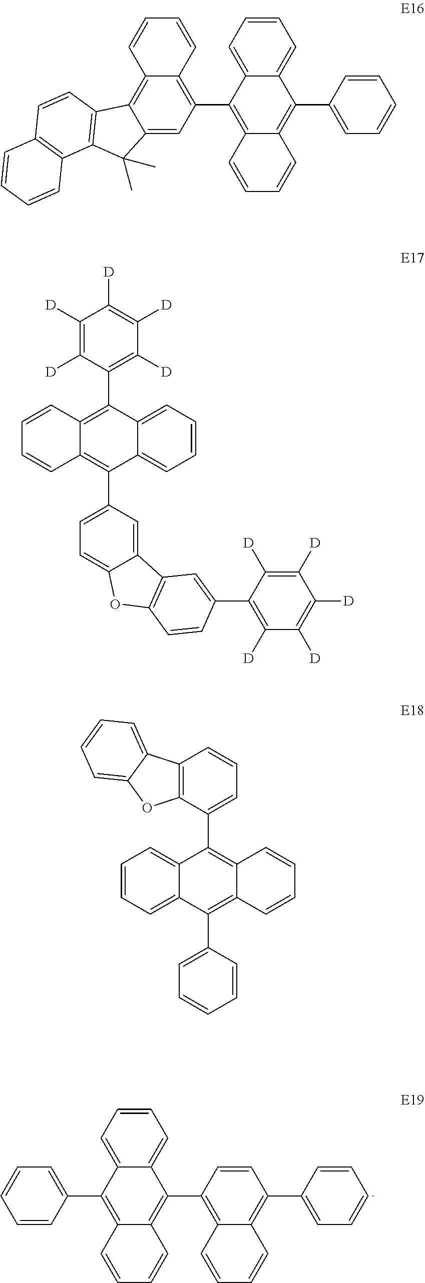

In an embodiment, the emission layer EML may include the compound represented by Formula E-2a or Formula E-2b. The compound represented by Formula E-2a or Formula E-2b may be utilized as a phosphorescent host material.

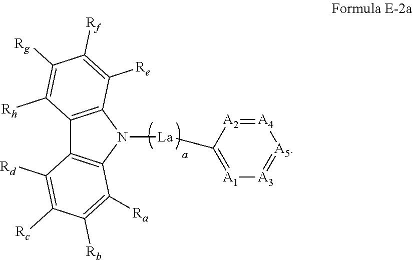

In Formula E-2a, “a” may be an integer of 0 to 10, and Lₐ may be a direct linkage, a substituted or unsubstituted ring-forming arylene group having 6 to 30 carbon atoms, or a substituted or unsubstituted ring-forming heteroarylene group having 2 to 30 carbon atoms. When “a” is an integer of 2 or more, a plurality of Lₐ may each independently be a substituted or unsubstituted ring-forming arylene group having 6 to 30 carbon atoms, or a substituted or unsubstituted ring-forming heteroarylene group having 2 to 30 carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring. Rₐ to Rᵢ may combined with an adjacent group to form hydrocarbon ring or hetero ring including N, O, S, and/or the like as a ring-forming atom.

In some embodiments, in Formula E-2a, two or three selected among A₁ to A₅ may be N, and the remainder may be CRᵢ.

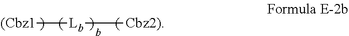

In Formula E-2b, Cbz1 and Cbz2 may each independently be an unsubstituted carbazole group, or a carbazole group substituted with a ring-forming aryl group having 6 to 30 carbon atoms. L_{b} may be a direct linkage, a substituted or unsubstituted ring-forming arylene group having 6 to 30 carbon atoms, or a substituted or unsubstituted ring-forming heteroarylene group having 2 to 30 carbon atoms. When “b” is an integer of 0 to 10, and “b” is an integer of 2 or more, a plurality of L_{b} may each independently be a substituted or unsubstituted ring-forming arylene group having 6 to 30 carbon atoms, or a substituted or unsubstituted ring-forming heteroarylene group having 2 to 30 carbon atoms.

The compound represented by Formula E-2a or Formula E-2b may be represented by any one among the compounds in Compound Group E-2. However, the compounds listed in Compound Group E-2 are illustrative, and the compound represented by Formula E-2a or Formula E-2b is not limited to those represented in Compound Group E-2.

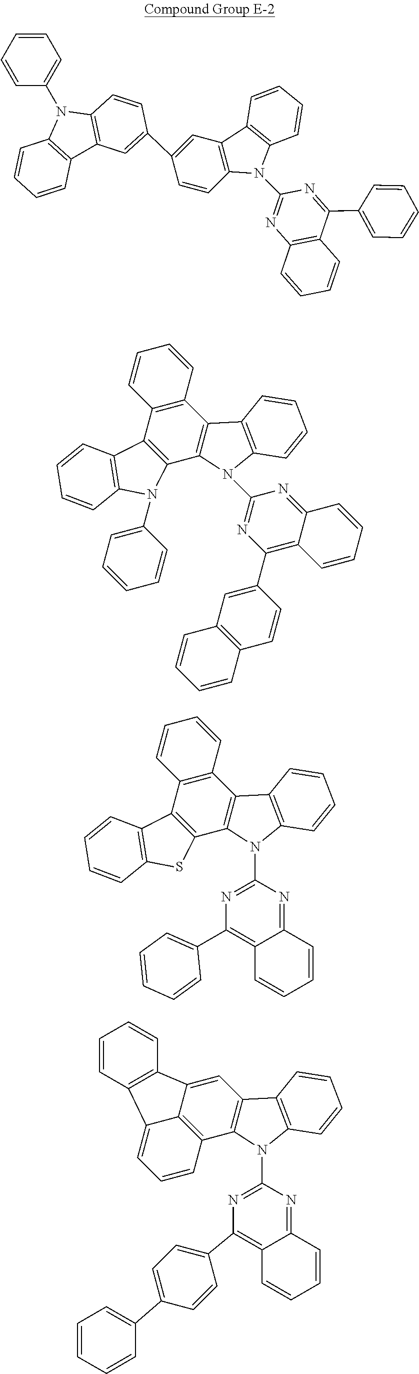

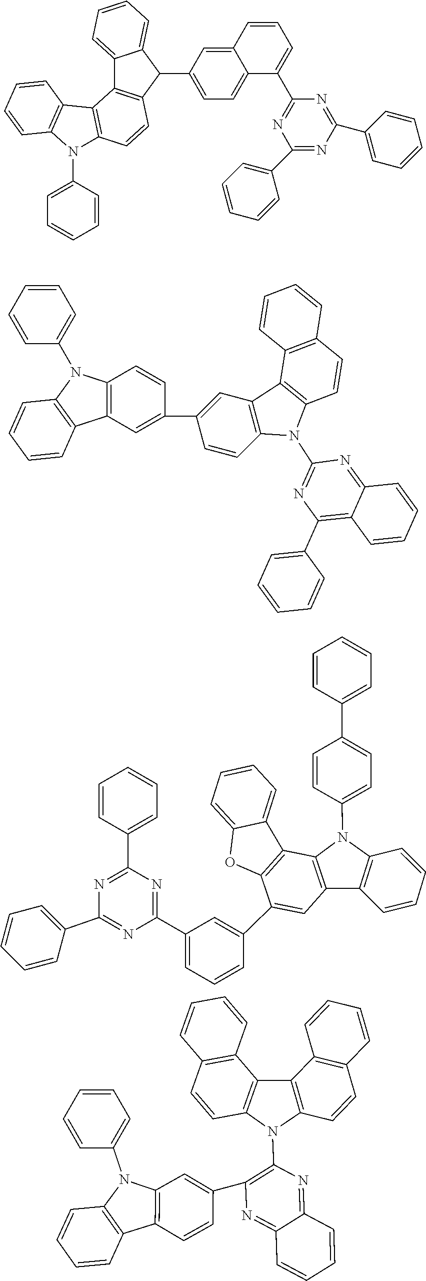

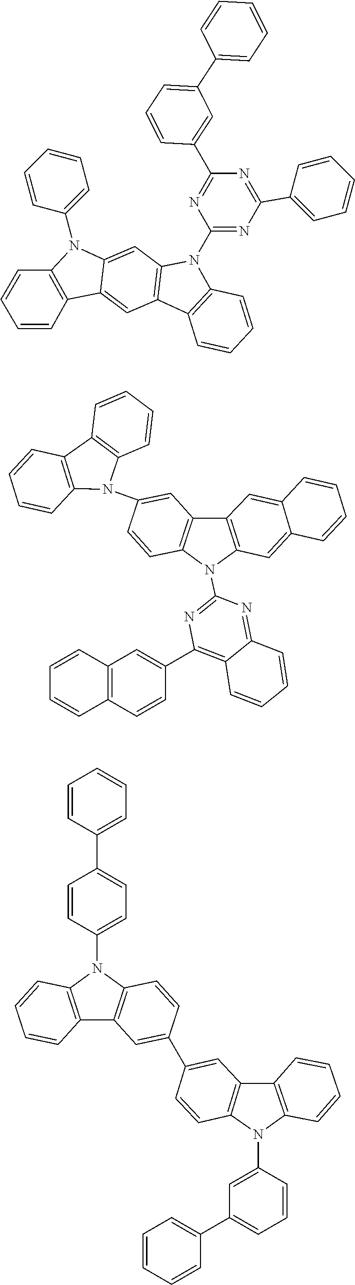 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

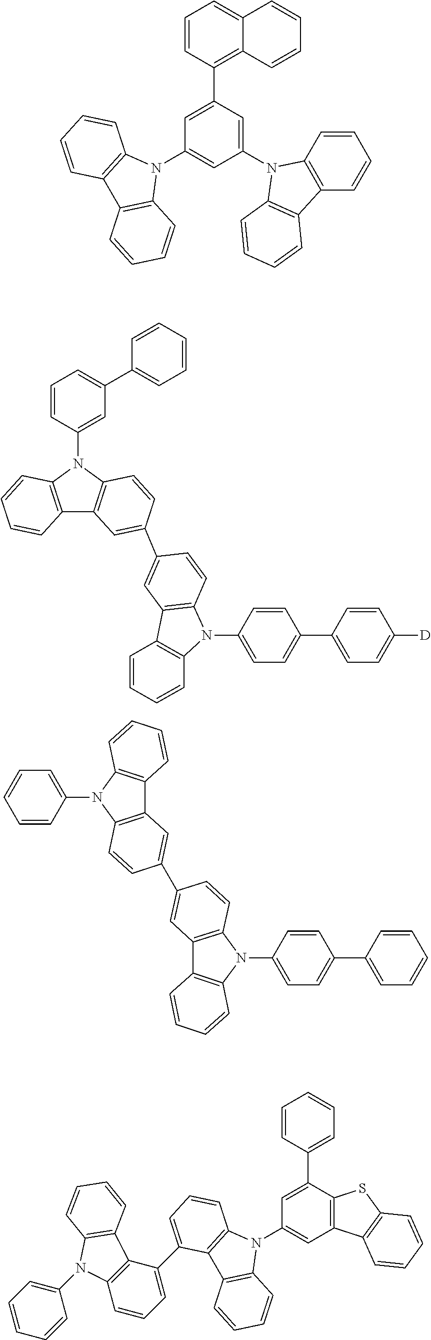

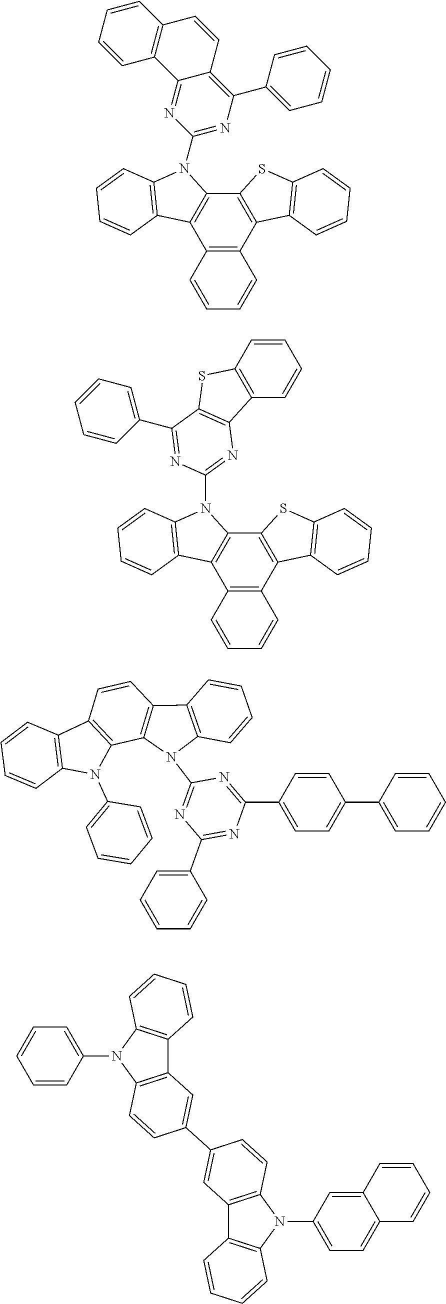

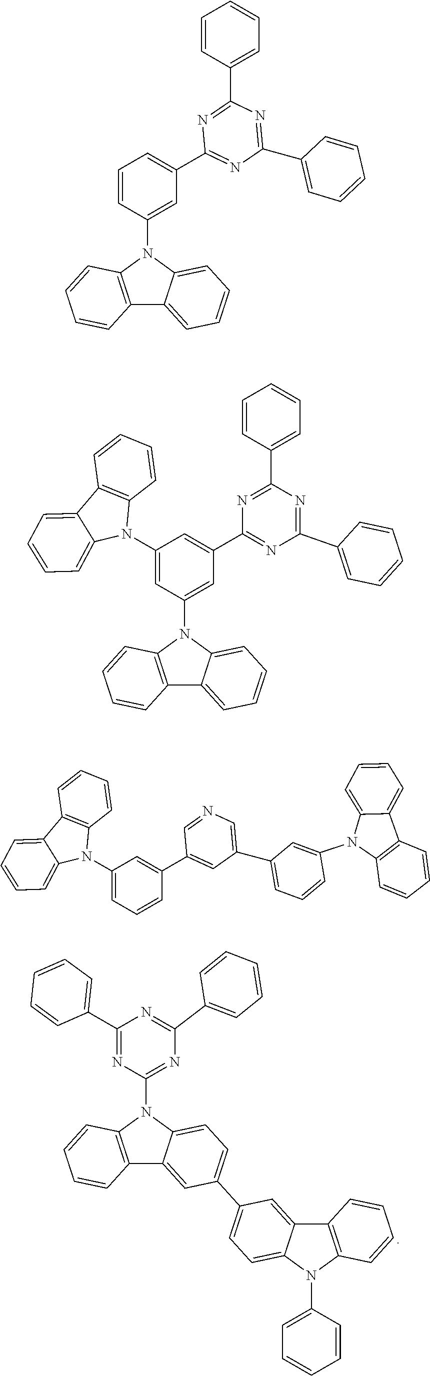 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include any suitable material in the art as a host material. For example, the emission layer EML may include at least one among bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenyl phosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi) as the host material. However, embodiments of the present disclosure are not limited thereto, and for example, tris(8-hydroxyquinolino)aluminum (Alq3), 4,4′-bis(N-carbazolyl)-1,1′-biphenyl (CBP), poly(N-vinylcarbazole) (PVK), 9,10-di(naphtha lene-2-yl)anthracene (ADN), 4,4′,4″-tris(carbazol-9-yl)-triphenylamine (TCTA), 1,3,5-tris(N-phenylbenzimidazole-2-yl)benzene (TPBi), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), 2,8-bis(diphenylphosphoryl)dibenzofuran (PPF), and/or the like may be utilized as the host material.

The emission layer EML may include the compound represented by Formula M-a or Formula M-b. The compound represented by Formula M-a or Formula M-b may be utilized as a phosphorescent dopant material.

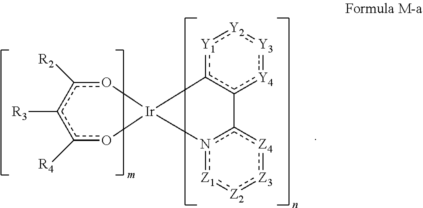

In Formula M-a above, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring. In Formula M-a, “m” may be 0 or 1, and “n” may be 2 or 3. In Formula M-a, when “m” is 0, “n” is 3, and when “m” is 1, “n” is 2.

The compound represented by Formula M-a may be utilized as a red phosphorescent dopant or a green phosphorescent dopant.

The compound represented by Formula M-a may be represented by any one among Compounds M-a1 to M-a19. However, Compounds M-a1 to M-a19 are illustrative, and the compound represented by Formula M-a is not limited to those represented by Compounds M-a1 to M-a19.

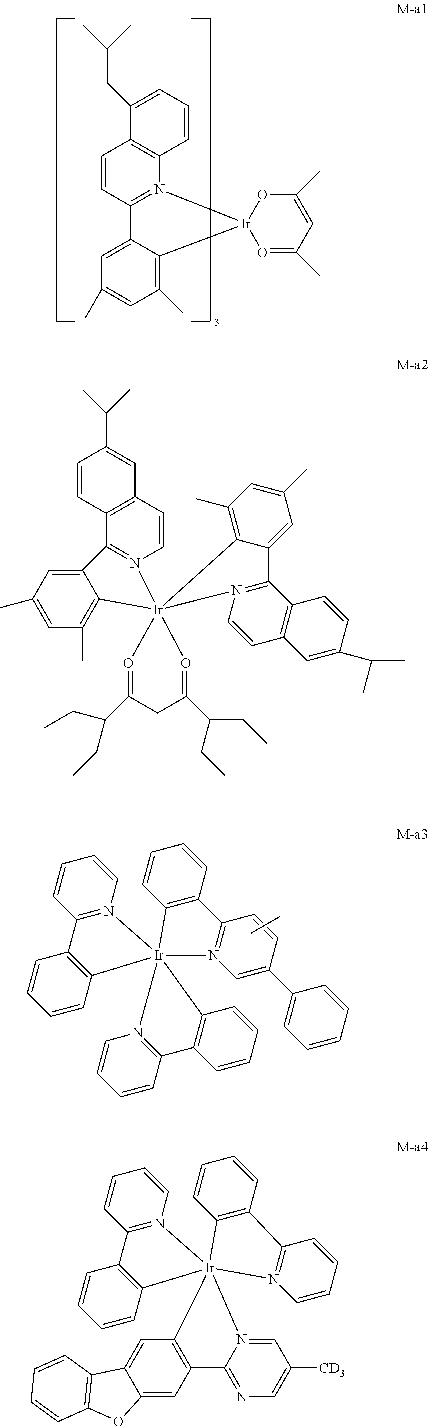

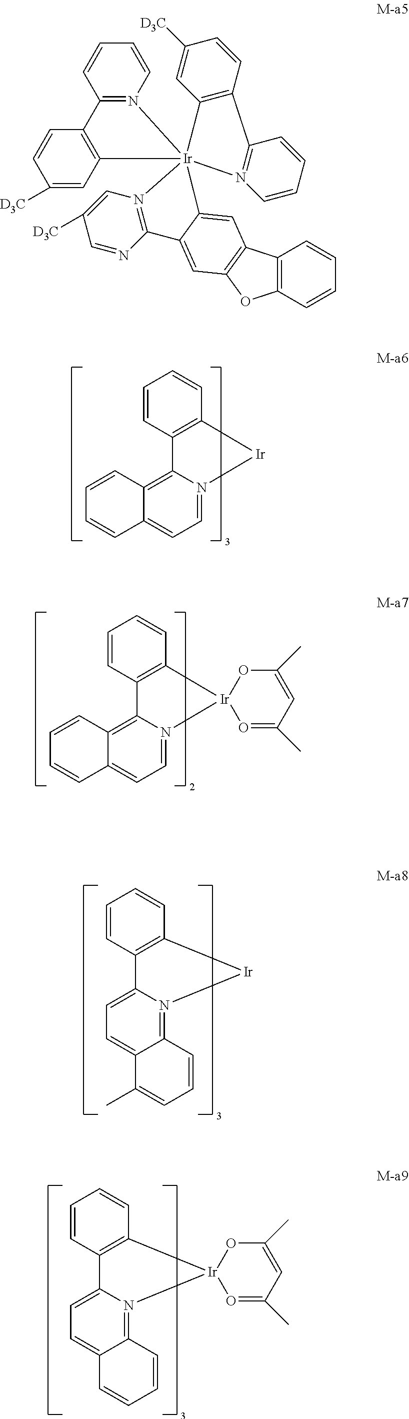

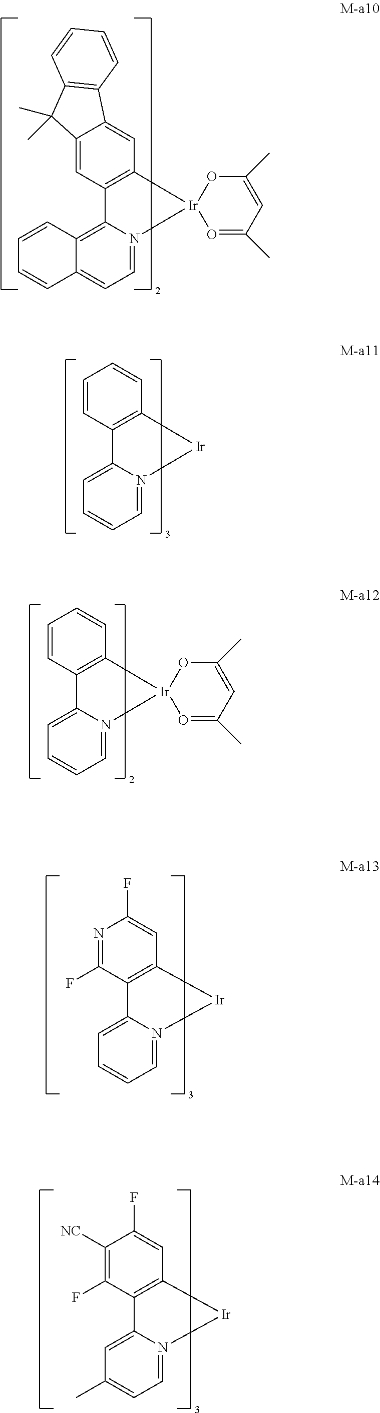

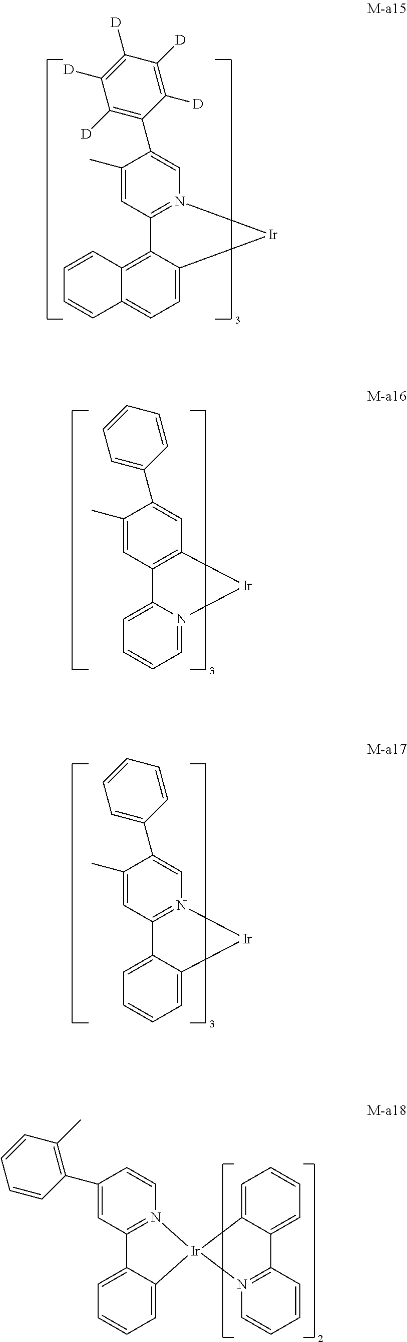

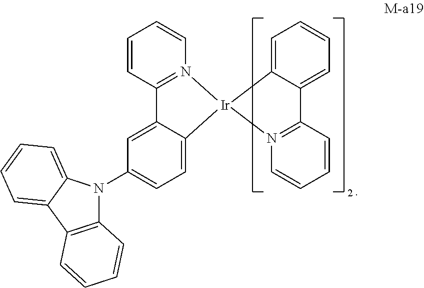

Compounds M-a1 and M-a2 may be utilized as a red dopant material, and Compounds M-a3 to M-a5 may be utilized as a green dopant material.

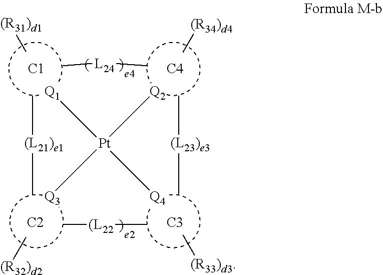

In Formula M-b, Q₁ to Q₄ may each independently be C or N, and C1 to C4 may each independently be a substituted or unsubstituted ring-forming hydrocarbon ring having 5 to 30 carbon atoms, or a substituted or unsubstituted ring-forming heterocycle having 2 to 30 carbon atoms. L₂₁ to L₂₄ may each independently be a direct linkage,

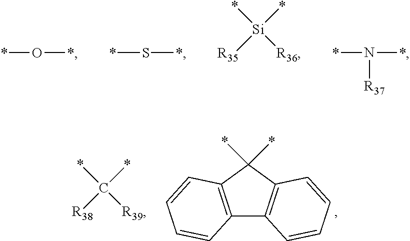

a substituted or unsubstituted divalent alkyl group having 1 to 20 carbon atoms, a substituted or unsubstituted ring-forming arylene group having 6 to 30 carbon atoms, or a substituted or unsubstituted ring-forming heteroarylene group having 2 to 30 carbon atoms, and e1 to e4 may each independently be 0 or 1. R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring, and d1 to d4 may each independently be an integer of 0 to 4.

The compound represented by Formula M-b may be utilized as a blue phosphorescent dopant or a green phosphorescent dopant.

The compound represented by Formula M-b may be represented by any one among the compounds blew. However, the compounds are illustrative, and the compound represented by Formula M-b is not limited to those represented in the compounds below.

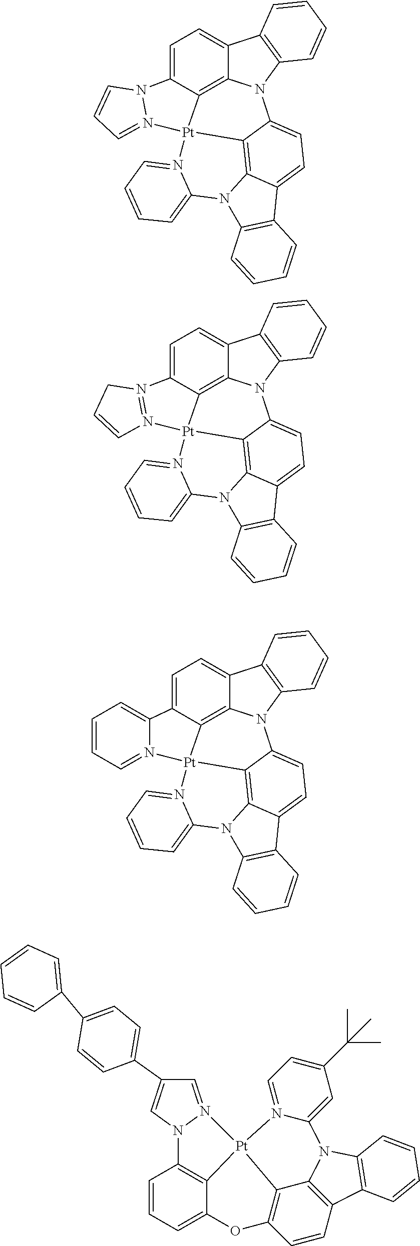

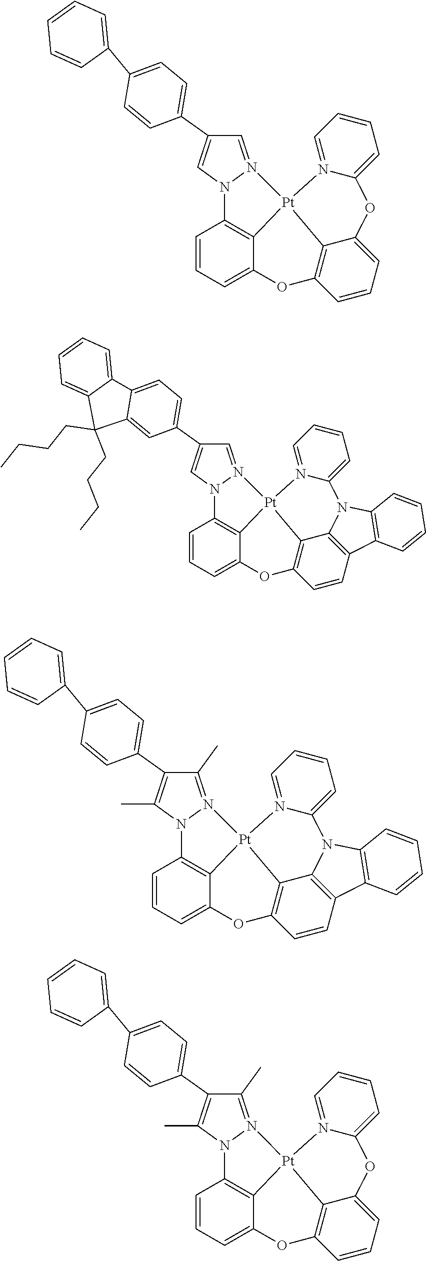

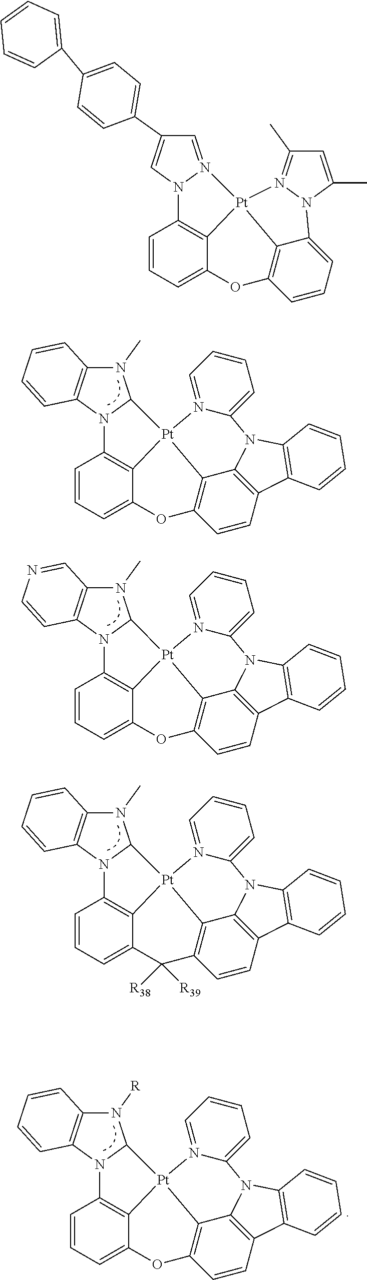

In the above compounds, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms.

The emission layer EML may include the compound represented by any one among Formula F-a to Formula F-c. The compound represented by Formula F-a to Formula F-c may be utilized as a fluorescent dopant material.

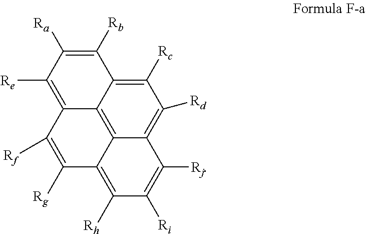

In Formula F-a above, two selected among Rₐ to Rⱼ may each independently be substituted with *—NAr₁Ar₂. The remainder among Rₐ to Rⱼ that are not substituted with *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms.

In *—NAr₁Ar₂, Ar₁ and Ar₂ may each independently be a substituted or unsubstituted ring-forming aryl group having 6 to 30 carbon atoms, or a substituted or unsubstituted ring-forming heteroaryl group having 2 to 30 carbon atoms. For example, at least one of Ar₁ or Ar₂ may be a heteroaryl group including O or S as a ring-forming atom.

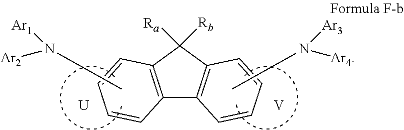

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring. Ar₁-Ar₄ may each independently be a substituted or unsubstituted ring-forming aryl group having 6 to 30 carbon atoms, or a substituted or unsubstituted ring-forming heteroaryl group having 2 to 30 carbon atoms.

In Formula F-b, U and V may each independently be a substituted or unsubstituted ring-forming hydrocarbon ring having 5 to 30 carbon atoms, or a substituted or unsubstituted ring-forming heterocycle having 2 to 30 carbon atoms.

In Formula F-b, the number of rings marked as U and V may each independently be 0 or 1. For example, if the number of U or V is 1 in Formula F-b, one ring forms a condensed ring at the portion indicated by U or V, and if the number of U or V is 0, it refers to that the ring indicated as U or V does not exist. For example, if the number of U is 0 and the number of V is 1, or the number of U is 1 and the number of V is 0, the condensed ring having a fluorene core of Formula F-b may be a tetracyclic compound. When the numbers of U and V are both (e.g., simultaneously) 0, the condensed ring of Formula F-b may be a tricyclic compound. Further, when the numbers of U and V are both (e.g., simultaneously) 1, the condensed ring having a fluorene core of Formula F-b may be a pentacyclic compound.

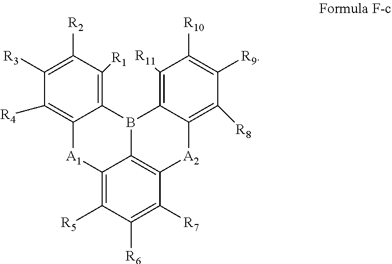

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms, and/or combined with an adjacent group to form a ring.

In Formula F-c, A₁ and A₂ may each independently be combined with substituents of an adjacent ring to form a condensed ring. For example, when A₁ and A₂ are each independently NRₘ, A₁ may be combined with R₄ or R₅ to form a ring. In some embodiments, A₂ may be combined with R₇ or R₈ to form a ring.

In an embodiment, the emission layer EML may include, as a suitable dopant material, a styryl derivative (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and/or one or more derivatives thereof (for example, 2,5,8,11-tetra-t-butylperylene (TBP)), pyrene and/or one or more derivatives thereof (for example, 1,1-dipyrene,1,4-dipyrenylbenzene,1,4-bis(N,N-diphenylamino)pyrene), and/or the like.

The emission layer EML may further include any suitable phosphorescent dopant material. For example, a metal complex including iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, embodiments of the present disclosure are not limited thereto.

In the organic electroluminescence devices ED according to an embodiment illustrated in FIGS. 3 to 6, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed utilizing a single material, a single layer formed utilizing a plurality of different materials, or a multilayer structure having a plurality of layers formed utilizing a plurality of different materials.

For example, the electron transport region ETR may have a structure of a single layer of an electron injection layer EIL or an electron transport layer ETL, and may have a structure of a single layer formed utilizing an electron injection material and an electron transport material. Further, the electron transport region ETR may have a single layer structure formed utilizing a plurality of different materials, or a structure in which an electron transport layer ETL/electron injection layer EIL, or a hole blocking layer HBL/electron transport layer ETL/electron injection layer EIL are stacked in order from the emission layer EML, but embodiments of the present disclosure are not limited thereto. A thickness of the electron transport region ETR may be, for example, about 1000 Å to about 1500 Å.

The electron transport region ETR may be formed by utilizing one or more suitable methods (such as a vacuum deposition method, a spin coating method, a cast method, a Langmuir-Blodgett (LB) method, an inkjet printing method, a laser printing method, and/or a laser induced thermal imaging (LITI) method).

The electron transport region ETR may include the compound represented by Formula ET-1:

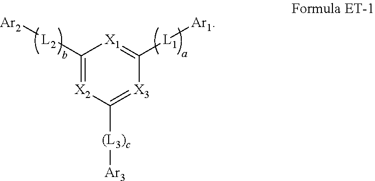

In Formula ET-1, at least one among X₁ to X₃ is N, and the remainder are CRₐ. Rₐ may be a hydrogen atom, a deuterium atom, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms. Ar₁ to Ar₃ may each independently be a hydrogen atom, a deuterium atom, a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms.

In Formula ET-1, “a” to “c” may each independently be an integer of 0 to 10.

In Formula ET-1, L₁ to L₃ may each independently be a direct linkage, a substituted or unsubstituted ring-forming arylene group having 6 to 30 carbon atoms, or a substituted or unsubstituted ring-forming heteroarylene group having 2 to 30 carbon atoms. When “a” to “c” are integer of 2 or more, L₁ to L₃ may each independently be a substituted or unsubstituted ring-forming arylene group having 6 to 30 carbon atoms, or a substituted or unsubstituted ring-forming heteroarylene group having 2 to 30 carbon atoms. The electron transport region ETR may further include an anthracene-based compound. However, embodiments of the present disclosure are not limited thereto, and the electron transport region ETR may include, for example, diphenyl[4-(triphenylsilyl)phenyl]phosphine oxide (TSPO1), tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In some embodiments, the electron transport region ETR may include a halogenated metal (such as LiF, NaCl, CsF, RbCl, RbI, CuI, and/or KI), a lanthanide metal (such as Yb), or a co-deposited material of the above-described halogenated metal and lanthanide metal. For example, the electron transport region ETR may include KI:Yb, R_{b1}:Yb, and/or the like as a co-deposited material. In some embodiments, a metal oxide (such as Li₂O and BaO), 8-hydroxyl-lithium quinolate (LiQ), and/or the like may be utilized in the electron transport region ETR, but embodiments of the present disclosure are not limited thereto. The electron transport region ETR may also be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates, but embodiments of the present disclosure are not limited thereto.

The electron transport region ETR may include the aforementioned compounds of the electron transport region in at least one of the electron injection layer EIL, the electron transport layer ETL, or the hole blocking layer HBL.

When the electron transport region ETR includes the electron transport layer ETL, a thickness of the electron transport layer ETL may be about 100 Å to about 1000 Å, for example, about 150 Å to about 500 Å. When the thickness of the electron transport layer ETL satisfies the above-described range, satisfactory electron transport properties may be obtained without substantial increase of a driving voltage.

When the electron transport region ETR includes the electron injection layer EIL, a thickness of the electron injection layer EIL may be about 1 Å to about 100 Å, for example, about 3 Å to about 90 Å. When the thickness of the electron injection layer EIL satisfies the above-described range, satisfactory electron injection properties may be obtained without substantial increase of a driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be made of a transparent metal oxide (such as indium tin oxide (ITO), indium zinc oxide (IZO), zinc oxide (ZnO), indium tin zinc oxide (ITZO), and/or the like).

When the second electrode EL2 is a transflective electrode or a reflective electrode, the second electrode EL2 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/calcium (Ca), LiF/aluminum (Al), molybdenum (Mo), titanium (Ti), ytterbium (Yb), tungsten (W), or a compound or a mixture thereof (for example, AgMg, AgYb, or MgAg). In some embodiments, the second electrode EL2 may have a multilayered structure including a reflective film or a transflective film formed utilizing the above-described materials and a transparent conductive film formed utilizing indium tin oxide (ITO), indium zinc oxide (IZO), zinc oxide (ZnO), indium tin zinc oxide (ITZO), and/or the like. For example, the second electrode EL2 may include the above-described metal material, a combination of two or more metal materials selected from the above-described metal materials, or an oxide of the above-described metal materials.

In some embodiments, the second electrode EL2 may be connected to an auxiliary electrode. When the second electrode EL2 is connected to the auxiliary electrode, the resistance of the second electrode EL2 may decrease.

In some embodiments, the capping layer CPL may be further disposed on the second electrode EL2 of the organic electroluminescence device ED according to an embodiment. The capping layer CPL may include multiple layers or a single layer.

In an embodiment, the capping layer CPL may be an organic layer or an inorganic layer. For example, when the capping layer CPL includes an inorganic material, the inorganic material may include an alkali metal compound (such as LiF), an alkaline earth metal compound (such as MgF₂, SiON, SiN_{X}, and/or SiO_{y}), and/or the like.

For example, when the capping layer CPL includes an organic material, the organic material may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol-9-yl) triphenylamine (TCTA), etc., an epoxy resin, or an acrylate (such as methacrylate). However, embodiments of the present disclosure are not limited thereto, and the capping layer CPL may include at least one among Compounds P1 to P5:

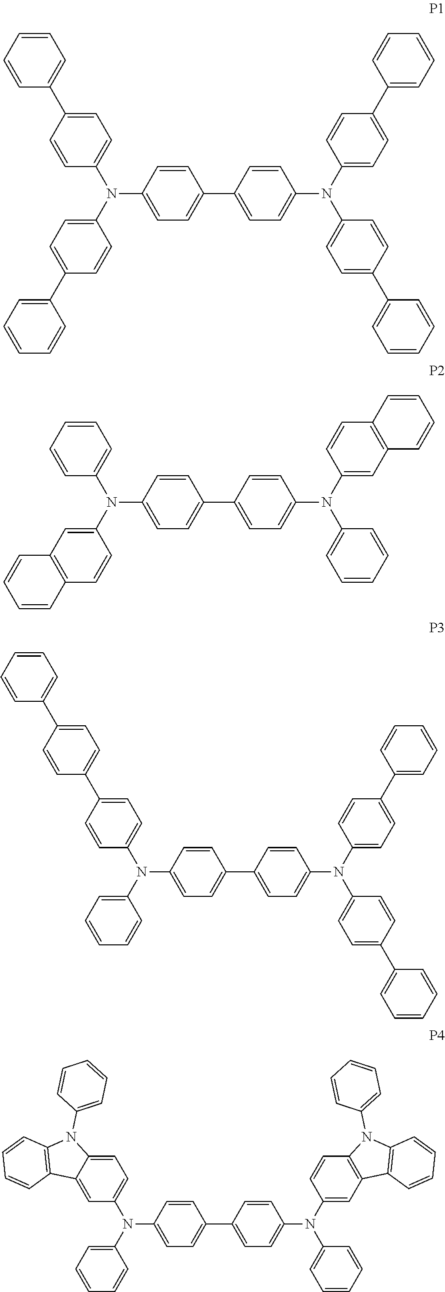 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

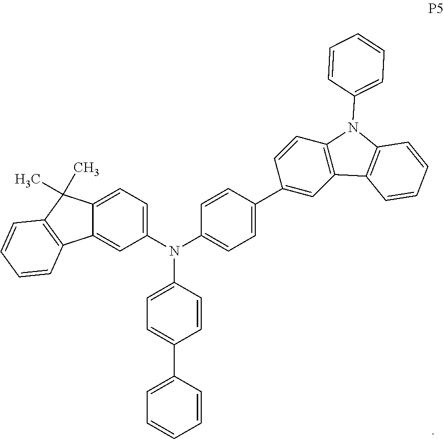 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, for light having the wavelength range of about 550 nm to about 660 nm, the refractive index of the capping layer CPL may be about 1.6 or more.

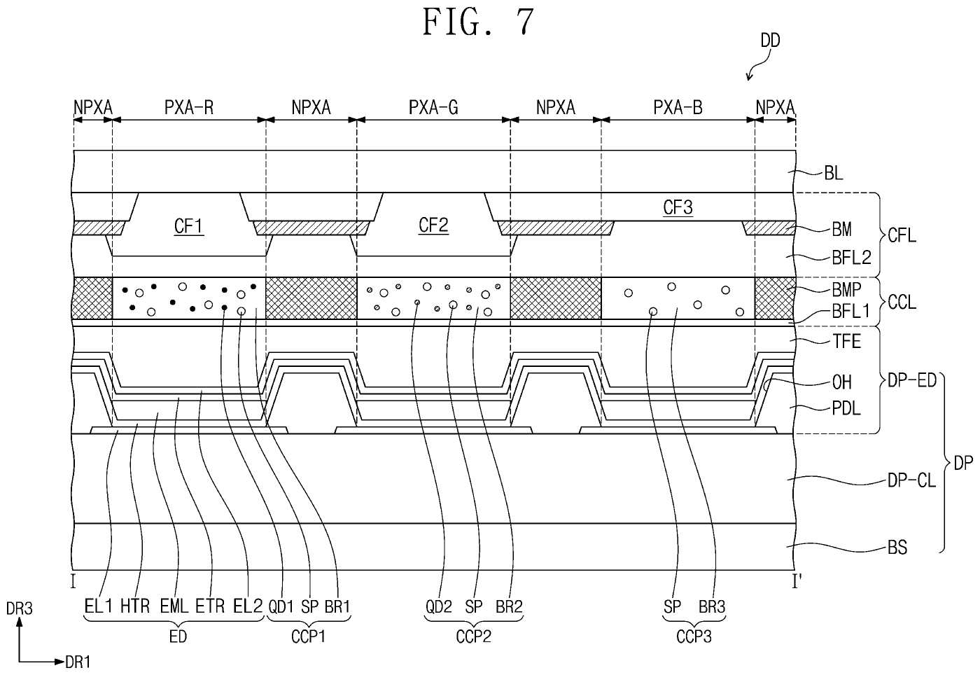

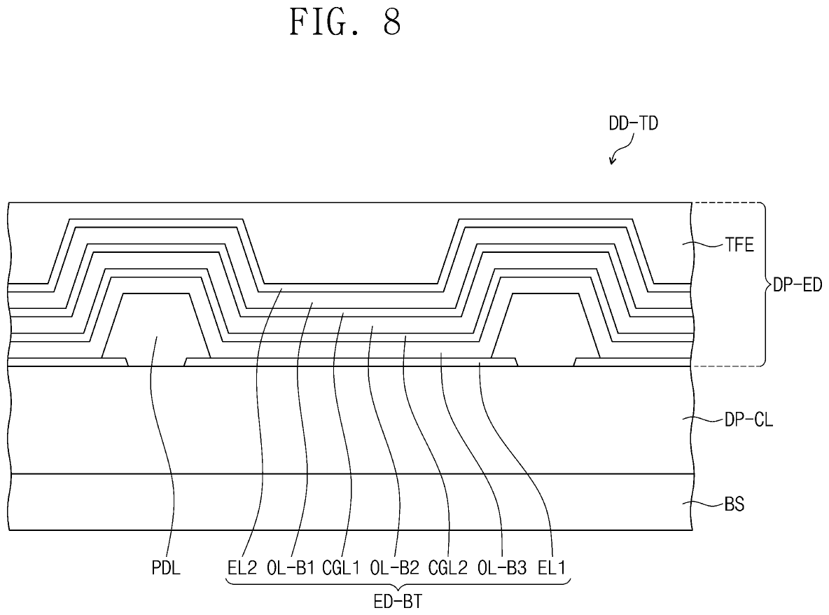

FIGS. 7 and 8 are each a cross-sectional view of a display apparatus according to an embodiment. In the description of the display apparatus according to an embodiment described with reference to FIGS. 7 and 8, the contents overlapping with those described in FIGS. 1 to 6 will not be described again, and differences will be mainly described.

Referring to FIG. 7, a display apparatus DD according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display device layer DP-ED, and the display device layer DP-ED may include an organic electroluminescence device ED.

The organic electroluminescence device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The structure of the organic electroluminescence device in FIGS. 4 to 6 described above may be equally applicable to the structure of the organic electroluminescence device ED illustrated in FIG. 7.

Referring to FIG. 7, the emission layer EML may be disposed in the opening OH defined in the pixel-defining film PDL. For example, the emission layer EML separated by the pixel-defining film PDL and provided corresponding to each of light-emitting regions PXA-R, PXA-G, and PXA-B may be to emit light of the same wavelength region. In a display apparatus DD according to an embodiment, the emission layer EML may be to emit blue light. In some embodiments, the emission layer EML may be provided as a common layer over all of the light-emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may convert the wavelength of received light to emit light. For example, the light control layer CCL may be a layer including a quantum dot or a layer including a phosphor.

The core of the quantum dot may be selected from II-VI compounds, III-V compounds, IV-VI compounds, Group IV elements, IV compounds, and a combination thereof.

The II-VI compounds may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI compounds may include a binary compound (such as In₂S₃ and In₂Se₃), a ternary compound (such as InGaS₃ and InGaSe₃), or any combination thereof.

The I—III-VI compounds may be selected from a ternary compound selected from the group consisting of AgInS, AgInS₂, CuInS, CulnS₂, AgGaS₂, CuGaS₂ CuGaO₂, AgGaO₂, AgAlO₂, and mixtures thereof, and a quaternary compound (such as AgInGaS₂ and CuInGaS₂).

The III-V compounds may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GalnNSb, GaInPAs, GaInPSb, InAlNP, InAlNAs, InAlNSb, InAlPAs, InAlPSb, and mixtures thereof. In some embodiments, the III-V compounds may further include a Group II metal. For example, InZnP and/or the like may be selected as III-II-V compounds.

The IV-VI compounds may be selected from the group consisting of: a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. Group IV elements may be selected from the group consisting of Si, Ge, and mixtures thereof. IV compounds may be a binary compound selected from the group consisting of SiC, SiGe, and mixtures thereof.

In this case, a binary compound, a ternary compound, or a quaternary compound may be present in the particle at a substantially uniform concentration, or may be present in the same particle while being divided to have partially different concentration distribution. In some embodiments, these compounds may have a core/shell structure in which one quantum dot surrounds another quantum dot. The core/shell structure may have a concentration gradient in which a concentration of an element present in the shell gradually decreases toward the core.

In some examples, the quantum dot may have a core-shell structure that includes a core including the aforementioned nanocrystal and a shell surrounding the core. The shell of the quantum dot may serve as a protective layer for maintaining characteristics of a semiconductor by preventing or reducing chemical modification of the core and/or a charging layer for imparting electrophoretic characteristics to the quantum dot. The shell may be a single layer or multiple layers. Examples of the shell of the quantum dot may include a metal or non-metal oxide, a semiconductor compound, and combinations thereof.

For example, the metal or non-metal oxide may be illustrated as a binary compound (such as SiO₂, Al₂O₃, TiO₂, ZnO, MnO, Mn₂O₃, Mn₃O₄, CuO, FeO, Fe₂O₃, Fe₃O₄, CoO, CO₃O₄, and NiO), or a ternary compound (such as MgAl₂O₄, CoFe₂O₄, NiFe₂O₄, and CoMn₂O₄), but embodiments of the present disclosure are not limited thereto.

In some embodiments, the semiconductor compound may be or include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

The quantum dot may have a full width of half maximum (FWHM) of an emission wavelength spectrum of about 45 nm or less, about 40 nm or less, or about 30 nm or less, and color purity or color gamut may be improved in this range. In some embodiments, as light emitted through this quantum dot is emitted in all directions, an improved wide viewing angle may be obtained.

The shape of the quantum dot may be any suitable shape in the art, and is not particularly limited, and for example, spherical, pyramidal, multi-arm, or cubic nanoparticles, nanotubes, nanowires, nanofibers, plate-shaped nanoparticles, and/or the like may be utilized.

The quantum dot may control the color of emitted light according to the particle size, and thus, the quantum dots may have one or more suitable light-emitting colors (such as blue, red, green, and/or the like).

The light control layer CCL may include a plurality of light control portions CCP1, CCP2, and CCP3. The light control portions CCP1, CCP2, and CCP3 may be spaced apart from each other.

Referring to FIG. 7, a division pattern BMP may be disposed between the light control portions CCP1, CCP2, and CCP3, which are spaced apart from each other, but embodiments of the present disclosure are not limited thereto. In FIG. 7, the division pattern BMP is illustrated to be non-overlapping with the light control portions CCP1, CCP2, and CCP3, but at least part of edges of the light control portions CCP1, CCP2, and CCP3 may overlap the division pattern BMP.

The light control layer CCL may include a first light control portion CCP1 including a first quantum dot QD1 configured to convert first color light provided by the electroluminescence device ED into second color light, a second light control portion CCP2 including a second quantum dot QD2 configured to convert the first color light into third color light, and a third light control portion CCP3 configured to transmit the first color light.

In an embodiment, the first light control portion CCP1 may be to provide red light (which is second color light), and the second light control portion CCP2 may be to provide green light (which is third color light). The third light control portion CCP3 may be to transmit and provide blue light, which is the first light provided by the organic electroluminescence device ED. For example, the first quantum dot QD1 may be a red quantum dot, and the second quantum dot QD2 may be a green quantum dot. The same description as described above may be applied to the quantum dots QD1 and QD2.

In some embodiments, the light control layer CCL may further include a scatterer SP. The first light control portion CCP1 may include the first quantum dot QD1 and the scatterer SP, the second light control portion CCP2 may include the second quantum dot QD2 and the scatterer SP, and the third light control portion CCP3 may not include a quantum dot but may include the scatterer SP.

The scatterer SP may be an inorganic particle. For example, the scatterer SP may include at least one of TiO₂, ZnO, Al₂O₃, SiO₂, or hollow silica. The scatterer SP may include at least one of TiO₂, ZnO, Al₂O₃, SiO₂, or hollow silica, or may be a mixture of two or more materials selected from TiO₂, ZnO, Al₂O₃, SiO₂, and hollow silica.

Each of the first light control portion CCP1, the second light control portion CCP2, and the third light control portion CCP3 may include base resins BR1, BR2, and BR3 to disperse the quantum dots QD1 and QD2, and the scatterer SP. In an embodiment, the first light control portion CCP1 may include the first quantum dot QD1 and the scatterer SP dispersed in the first base resin BR1, the second light control portion CCP2 may include the second quantum dot QD2 and the scatterer SP dispersed in the second base resin BR2, and the third light control portion CCP3 may include the scatterer SP dispersed in the third base resin BR3. The base resins BR1, BR2, and BR3 are media in which the quantum dots QD1 and QD2 and the scatterer SP are dispersed, and may be made of one or more suitable resin compositions (which may be generally referred to as binders). For example, the base resins BR1, BR2, and BR3 may be acrylic-based resins, urethane-based resins, silicone-based resins, epoxy-based resins, and/or the like. The base resins BR1, BR2, and BR3 may be transparent resins. In an embodiment, the first base resin BR1, the second base resin BR2, and the third base resin BR3 may be substantially the same as or different from each other.

The light control layer CCL may include a barrier layer BFL1.

The barrier layer BFL1 may serve to prevent or reduce penetration of moisture and/or oxygen (hereinafter referred to as “moisture/oxygen”). The barrier layer BFL1 may be disposed on the light control portions CCP1, CCP2, and CCP3 to prevent or reduce the light control portions CCP1, CCP2, and CCP3 from being exposed to moisture/oxygen. In some embodiments, the barrier layer BFL1 may cover the light control portions CCP1, CCP2, and CCP3. In some embodiments, a barrier layer BFL2 may also be provided between the color filter layer CFL and the light control portions CCP1, CCP2, and CCP3.

The barrier layers BFL1 and BFL2 may include at least one inorganic layer. For example, the barrier layers BFL1 and BFL2 may include an inorganic material. For example, the barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or a metal thin film in which light transmittance is secured. In some embodiments, the barrier layers BFL1 and BFL2 may further include an organic film. The barrier layers BFL1 and BFL2 may be comprised of a single layer or a plurality of layers.

In a display apparatus DD according to an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include a light-shielding portion BM and filters CF-B, CF-G, and CF-R. The color filter layer CFL may include a first filter CF1 configured to transmit second color light, a second filter CF2 configured to transmit third color light, and a third filter CF3 configured to transmit first color light. For example, the first filter CF1 may be a red filter, the second filter CF2 may be a green filter, and the third filter CF3 may be a blue filter. Each of the filters CF1, CF2, and CF3 may include a polymer photosensitive resin and/or a pigment and/or dye. The first filter CF1 may include a red pigment and/or dye, the second filter CF2 may include a green pigment and/or dye, and the third filter CF3 may include a blue pigment and/or dye. In some embodiments, the third filter CF3 may not include a pigment and/or dye. The third filter CF3 may include a polymer photosensitive resin and may not include a pigment and/or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated from each other and may be provided integrally.

The light-shielding portion BM may be a black matrix. The light-shielding portion BM may include an organic light-shielding material or an inorganic light-shielding material including a black pigment or a black dye. The light-shielding portion BM may prevent or reduce light leakage, and separate the boundary between the adjacent color filters CF1, CF2, and CF3. In some embodiments, the light-shielding portion BM may be formed of a blue filter.

The first to third filters CF1, CF2, and CF3 may be disposed to respectively correspond to a red light-emitting region PXA-R, a green light-emitting region PXA-G, and a blue light-emitting region PXA-B.

A base substrate BL may be disposed on the color filter layer CFL. The base substrate BL may be a member providing a base surface on which the color filter layer CFL, the light control layer CCL, or the like is disposed. The base substrate BL may be a glass substrate, a metal substrate, a plastic substrate, or the like. However, the embodiment of the present disclosure is not limited thereto, and the base substrate BL may be an inorganic layer, an organic layer, or a composite material layer. In some embodiments, the base substrate BL may be omitted.

FIG. 8 is a cross-sectional view illustrating a portion of a display apparatus according to an embodiment. FIG. 8 illustrates a cross-sectional view of the display panel DP of FIG. 7. In the display apparatus DD-TD according to an embodiment, the organic electroluminescence device ED-BT may include a plurality of light-emitting structures OL-B1, OL-B2, and OL-B3. The organic electroluminescence device ED-BT may include a first electrode EL1 and a second electrode EL2 that face each other, and a plurality of light-emitting structures OL-B1, OL-B2, and OL-B3 that are provided by sequentially stacking layers in a thickness direction between the first electrode EL1 and the second electrode EL2. Each of the light-emitting structures OL-B1, OL-B2, and OL-B3 may include the emission layer EML (FIG. 7), and the hole transport region HTR and the electron transport region ETR with the emission layer EML (FIG. 7) interposed therebetween.

For example, the organic electroluminescence device ED-BT included in the display apparatus DD-TD according to an embodiment may be an organic electroluminescence device having a tandem structure including a plurality of emission layers.

In an embodiment illustrated in FIG. 8, all the light emitted from each of the light-emitting structures OL-B1, OL-B2, and OL-B3 may be blue light. However, embodiments of the present disclosure are not limited thereto, and the wavelength ranges of light emitted from each of the light-emitting structures OL-B1, OL-B2, and OL-B3 may be different from each other. For example, the organic electroluminescence device ED-BT including the plurality of light-emitting structures OL-B1, OL-B2, and OL-B3 that emit light of different wavelength regions may be to emit white light.

A charge generating layer CGL may be disposed between the adjacent light-emitting structures OL-B1, OL-B2, and OL-B3. The charge generating layer CGL may include a p-type charge generating layer and/or an n-type charge generating layer.

The organic electroluminescence device ED according to an embodiment of the present disclosure may include the aforementioned polycyclic compound represented by Formula 1, and may thus exhibit excellent or suitable luminous efficiency characteristics. In some embodiments, the organic electroluminescence device ED according to an embodiment may exhibit high efficiency characteristics in a blue wavelength region.

Hereinafter, the present disclosure will be described in more detail with reference to Examples and Comparative Examples. The following Examples are only illustrative to assist understanding of the present disclosure, and the scope of the present disclosure is not limited thereto.

### Synthesis Example

A compound according to an embodiment of the present disclosure may be synthesized, for example, as follows. However, a method for synthesizing a compound according to an embodiment of the present disclosure is not limited thereto.

### 1. Synthesis of Compound 1

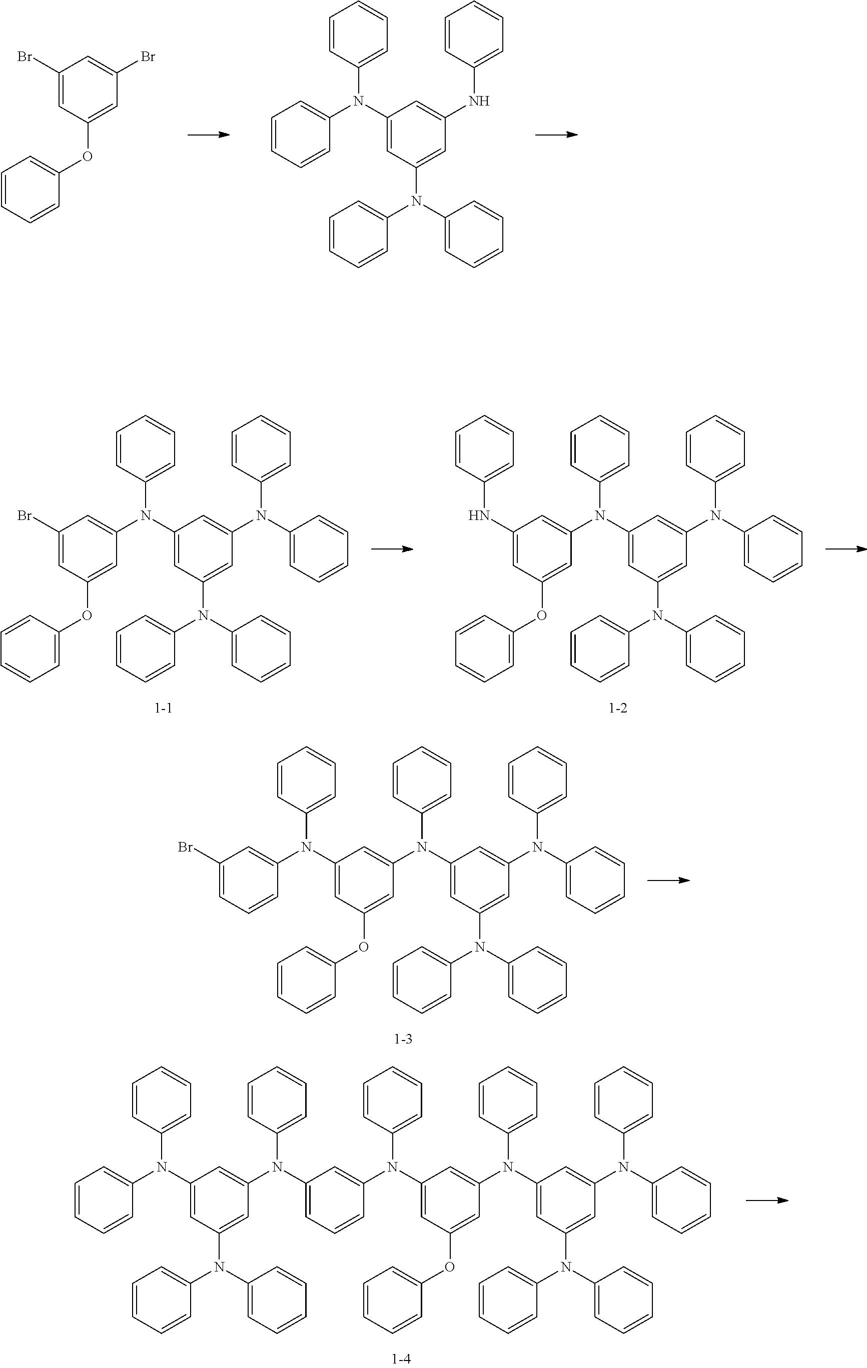

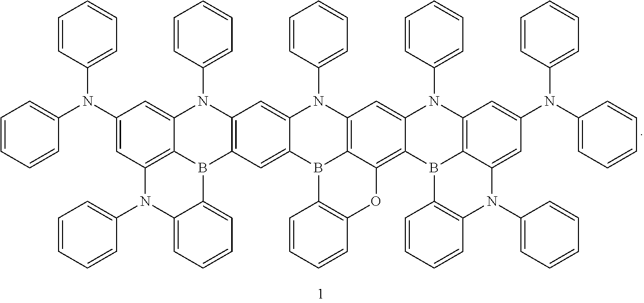 [SMILES: c1ccc(N(c2ccccc2)c2cc3c4c(c2)N(c2ccccc2)c2cc5c(cc2B4c2ccccc2N3c2ccccc2)B2c3ccccc3Oc3c2c(cc2c3B3c4ccccc4N(c4ccccc4)c4cc(N(c6ccccc6)c6ccccc6)cc(c43)N2c2ccccc2)N5c2ccccc2)cc1]

### 1.1 Synthesis of Intermediate 1-1

1,3-dibromo-5-phenoxybenzene (1.0 equivalent), N1,N1,N3,N3,N5-pentaphenylbenzene-1,3,5-triamine (0.9 equivalent), tris(dibenzylideneacetone)dipalladium(0) (0.05 equivalent), BINAP (0.1 equivalent), and sodium tert-butoxide (3.0 equivalent) were dissolved in toluene, and then stirred at about 100° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 1-1. (yield: 60%)

### 1.2 Synthesis of Intermediate 1-2

Intermediate 1-1 (1.0 equivalent), aniline (1.5 equivalent), tris(dibenzylideneacetone)dipalladium(0) (0.05 equivalent), tri-tert-butylphosphine (0.1 equivalent), and sodium tert-butoxide (3.0 equivalent) were dissolved in toluene, and then stirred at about 100° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 1-2. (yield: 65%)

### 1.3 Synthesis of Intermediate 1-3

Intermediate 1-2 (1.0 equivalent), 1-bromo-3-iodobenzene (1.1 equivalent), tris(dibenzylideneacetone)dipalladium(0) (0.05 equivalent), tri-tert-butylphosphine (0.1 equivalent), and sodium tert-butoxide (3.0 equivalent) were dissolved in toluene, and then stirred at about 100° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 1-3. (yield: 65%)

### 1.4 Synthesis of Intermediate 1-4

Intermediate 1-3 (1.5 equivalent), N1,N1,N3,N3,N5-pentaphenylbenzene-1,3,5-triamine (1.0 equivalent), tris(dibenzylideneacetone)dipalladium(0) (0.05 equivalent), tri-tert-butylphosphine (0.1 equivalent), and sodium tert-butoxide (3.0 equivalent) were dissolved in xylene, and then stirred at about 140° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 1-4. (yield: 50%)

### 1.5 Synthesis of Compound 1

Intermediate 1-4 (1.0 equivalent) and boron triiodide (8.0 equivalent) were dissolved in ortho dichlorobenzene. The temperature was raised to about 180° C. and stirred for about 12 hours in a nitrogen environment. After cooling, the reaction was quenched by slowly adding triethylamine, and then was added to methyl alcohol to precipitate, and filtered to obtain the reaction. Purification was performed by column chromatography to obtain Compound 1. (yield: 3%)

### 2. Synthesis of Compound 2

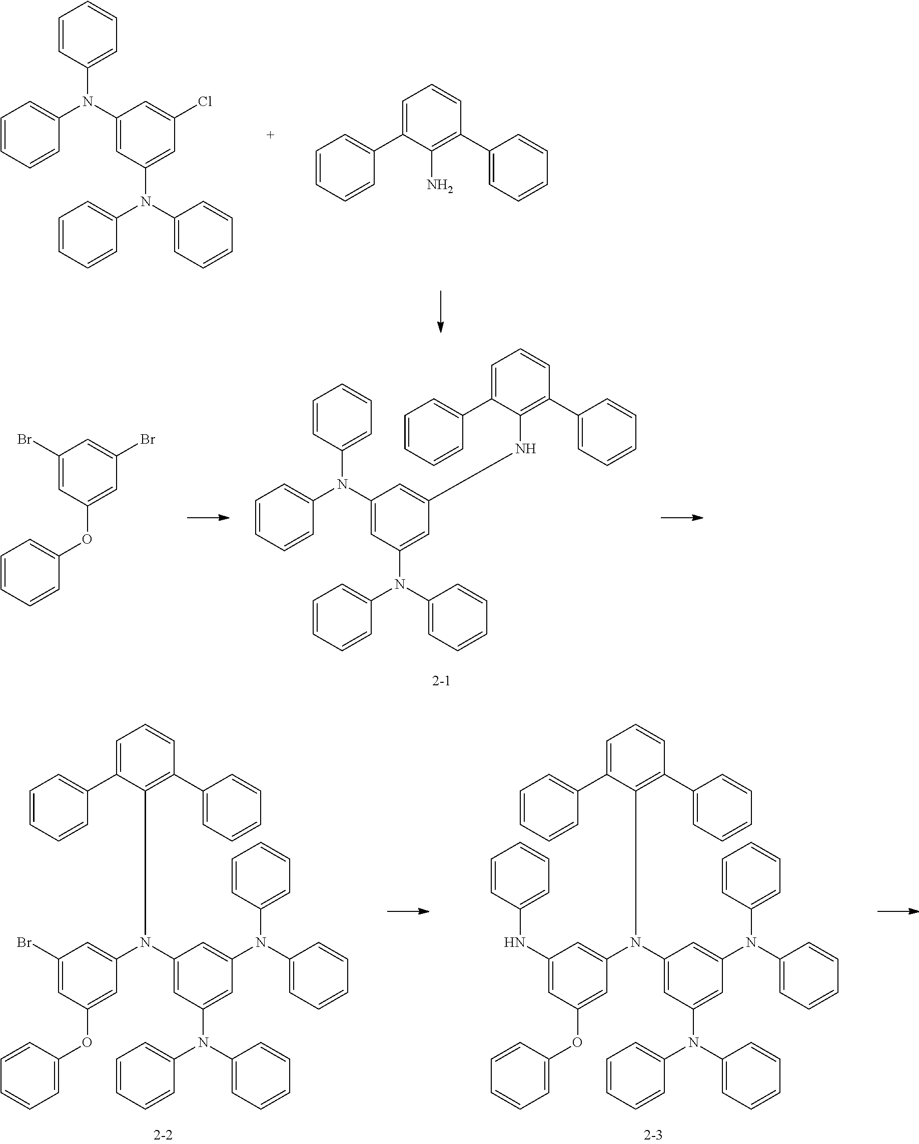 [SMILES: Clc1cc(N(c2ccccc2)c2ccccc2)cc(N(c2ccccc2)c2ccccc2)c1 ; Nc1c(-c2ccccc2)cccc1-c1ccccc1 ; Brc1cc(Br)cc(Oc2ccccc2)c1 ; c1ccc(-c2cccc(-c3ccccc3)c2Nc2cc(N(c3ccccc3)c3ccccc3)cc(N(c3ccccc3)c3ccccc3)c2)cc1 ; Brc1cc(Oc2ccccc2)cc(N(c2cc(N(c3ccccc3)c3ccccc3)cc(N(c3ccccc3)c3ccccc3)c2)c2c(-c3ccccc3)cccc2-c2ccccc2)c1 ; c1ccc(Nc2cc(Oc3ccccc3)cc(N(c3cc(N(c4ccccc4)c4ccccc4)cc(N(c4ccccc4)c4ccccc4)c3)c3c(-c4ccccc4)cccc3-c3ccccc3)c2)cc1]

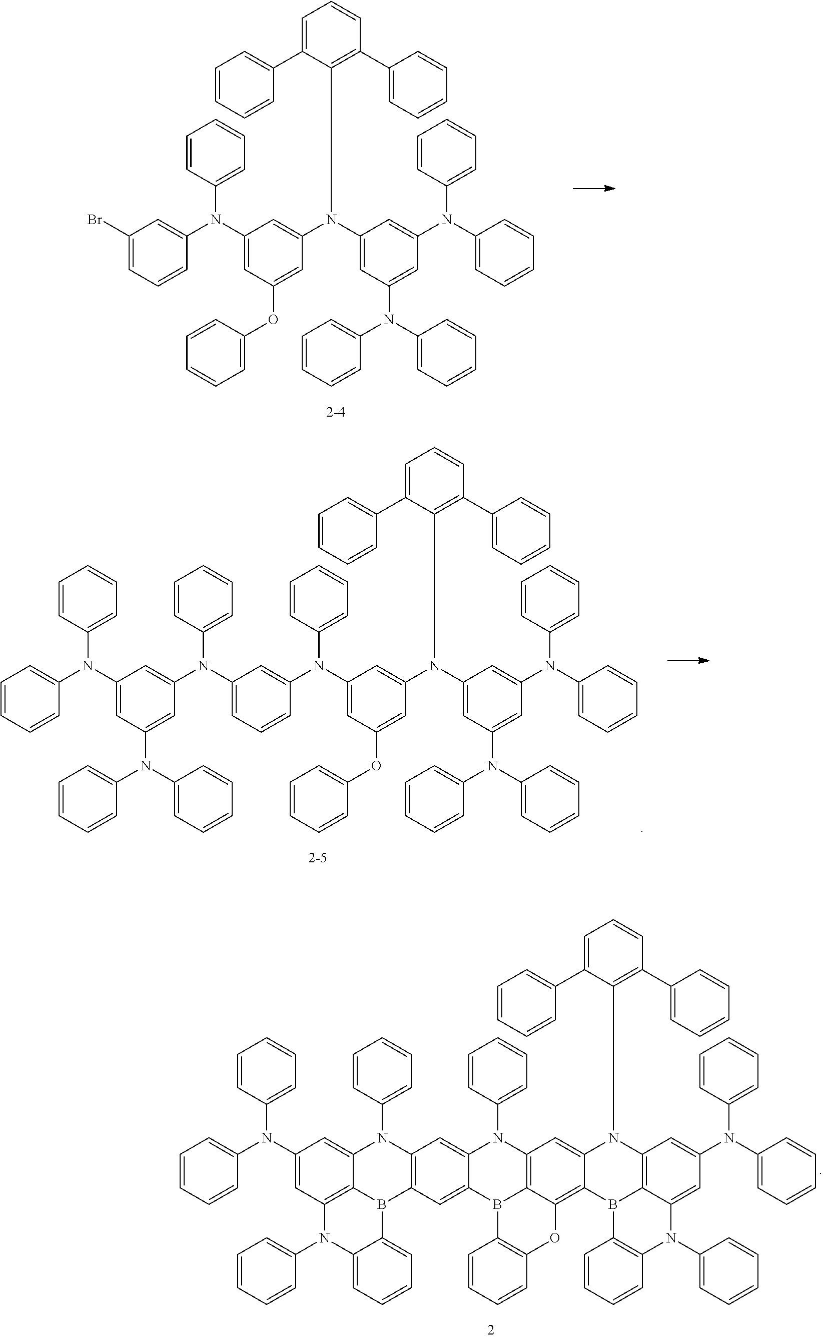

### 2.1 Synthesis of Intermediate 2-1

5-chloro-N1,N1,N3,N3-tetraphenylbenzene-1,3-diamine (1.5 equivalent), [1,1′:3′,1″-terphenyl]-2′-amine (1.0 equivalent), tris(dibenzylideneacetone)dipalladium(0) (0.05 equivalent), tri-tert-butylphosphine (0.1 equivalent), and sodium tert-butoxide (3.0 equivalent) were dissolved in xylene, and then stirred at about 140° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 2-1. (yield: 75%)

### 2.2 Synthesis of Intermediate 2-2

1,3-dibromo-5-phenoxybenzene (1.0 equivalent), Intermediate 2-1 (0.9 equivalent), tris(dibenzylideneacetone)dipalladium(0) (0.05 equivalent), BINAP (0.1 equivalent), and sodium tert-butoxide (3.0 equivalent) were dissolved in xylene, and then stirred at about 140° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 2-2. (yield: 40%)

### 2.3 Synthesis of Intermediate 2-3

Intermediate 2-3 was synthesized utilizing Intermediate 2-2 instead of Intermediate 1-1 in substantially the same manner as for the synthesis of Intermediate 1-2. (yield: 60%)

### 2.4 Synthesis of Intermediate 2-4

Intermediate 2-4 was synthesized utilizing Intermediate 2-3 instead of Intermediate 1-2 in substantially the same manner as for the synthesis of Intermediate 1-3. (yield: 60%)

### 2.5 Synthesis of Intermediate 2-5

Intermediate 2-5 was synthesized utilizing Intermediate 2-4 instead of Intermediate 1-3 in substantially the same manner as for the synthesis of Intermediate 1-4. (yield: 50%)

### 2.6 Synthesis of Compound 2

Compound 2 was synthesized utilizing Intermediate 2-5 instead of Intermediate 1-4 in substantially the same manner as for the synthesis of Compound 1. (yield: 3%)

### 3. Synthesis of Compound 3

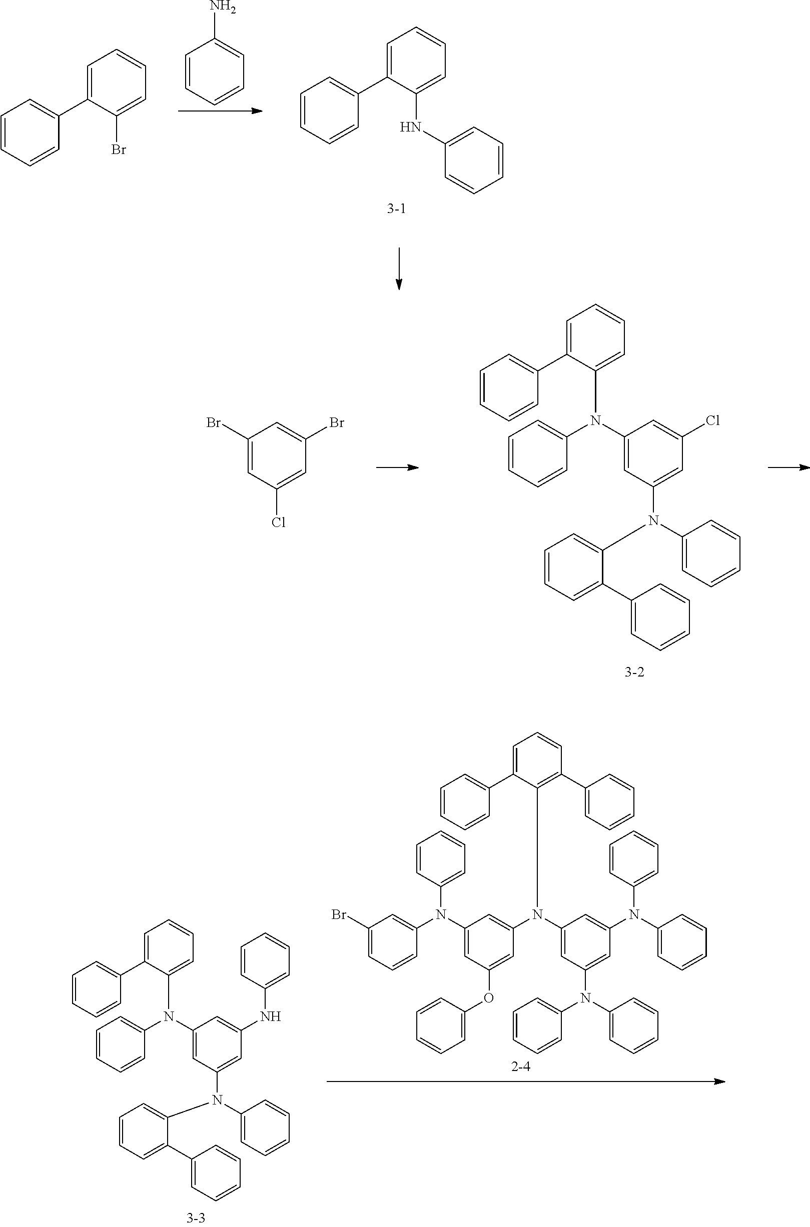

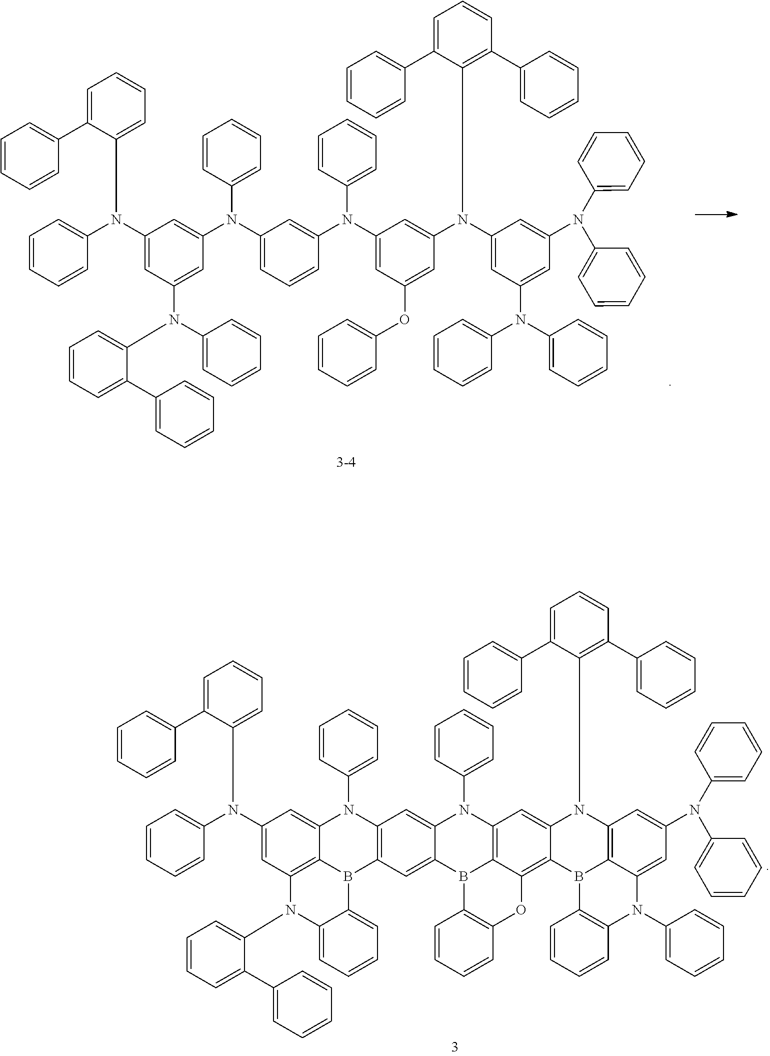 [SMILES: c1ccc(Oc2cc(N(c3ccccc3)c3cccc(N(c4ccccc4)c4cc(N(c5ccccc5)c5ccccc5-c5ccccc5)cc(N(c5ccccc5)c5ccccc5-c5ccccc5)c4)c3)cc(N(c3cc(N(c4ccccc4)c4ccccc4)cc(N(c4ccccc4)c4ccccc4)c3)c3c(-c4ccccc4)cccc3-c3ccccc3)c2)cc1 ; c1ccc(-c2ccccc2N(c2ccccc2)c2cc3c4c(c2)N(c2ccccc2-c2ccccc2)c2ccccc2B4c2cc4c(cc2N3c2ccccc2)N(c2ccccc2)c2cc3c(c5c2B4c2ccccc2O5)B2c4ccccc4N(c4ccccc4)c4cc(N(c5ccccc5)c5ccccc5)cc(c42)N3c2c(-c3ccccc3)cccc2-c2ccccc2)cc1]

### 3.1 Synthesis of Intermediate 3-1

2-bromo-1,1′-biphenyl (1.0 equivalent), aniline (0.9 equivalent), tris(dibenzylideneacetone)dipalladium(0) (0.05 equivalent), tri-tert-butylphosphine (0.1 equivalent), and sodium tert-butoxide (3.0 equivalent) were dissolved in toluene, and then stirred at about 100° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 3-1. (yield: 80%)

### 3.2 Synthesis of Intermediate 3-2

1,3-dibromo-5-chlorobenzene (1.0 equivalent), Intermediate 3-1 (2.1 equivalent), tris(dibenzylideneacetone)dipalladium(0) (0.05 equivalent), tri-tert-butylphosphine (0.1 equivalent), and sodium tert-butoxide (3.0 equivalent) were dissolved in toluene, and then stirred at about 100° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 3-2. (yield: 65%)

### 3.3 Synthesis of Intermediate 3-3

Intermediate 3-2 was synthesized utilizing Intermediate 3-2 instead of Intermediate 1-3 and aniline instead of N1,N 1, N3,N3,N5-pentaphenylbenzene-1,3,5-triamine in substantially the same manner as for the synthesis of Intermediate 1-4. (yield: 65%)

### 3.4 Synthesis of Intermediate 3-4

Intermediate 3-4 was synthesized utilizing Intermediate 2-4 instead of Intermediate 1-3 and Intermediate 3-3 instead of N1,N1,N3,N3,N5-pentaphenylbenzene-1,3,5-triamine in substantially the same manner as for the synthesis of Intermediate 1-4. (yield: 55%)

### 3.5 Synthesis of Compound 3

Compound 3 was synthesized utilizing Intermediate 3-4 instead of Intermediate 1-4 in substantially the same manner as for the synthesis of Compound 1. (yield: 3%)

### 4. Synthesis of Compound 6

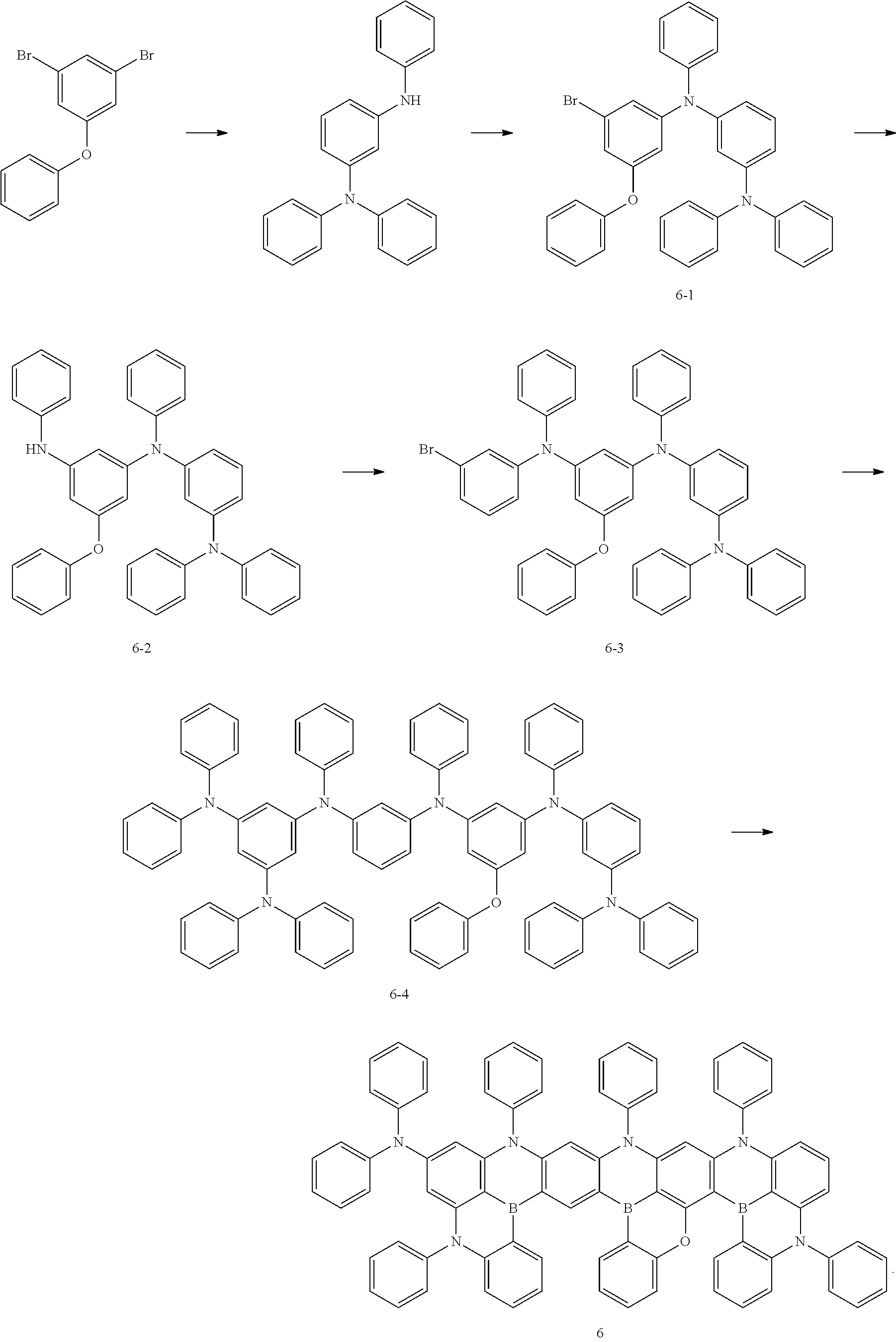

### 4.1 Synthesis of Intermediate 6-1

Intermediate 6-1 was synthesized utilizing N1,N1,N3-triphenylbenzene-1,3-diamine instead of N1,N1,N3,N3,N5-pentaphenylbenzene-1,3,5-triamine in substantially the same manner as for the synthesis of Intermediate 1-1. (yield: 70%)

### 4.2 Synthesis of Intermediate 6-2

Intermediate 6-2 was synthesized utilizing Intermediate 6-1 instead of Intermediate 1-1 in substantially the same manner as for the synthesis of Intermediate 1-2. (yield: 65%)

### 4.3 Synthesis of Intermediate 6-3

Intermediate 6-3 was synthesized utilizing Intermediate 6-2 instead of Intermediate 1-2 in substantially the same manner as for the synthesis of Intermediate 1-3. (yield: 65%)

### 4.4 Synthesis of Intermediate 6-4

Intermediate 6-4 was synthesized utilizing Intermediate 6-3 instead of Intermediate 1-3 in substantially the same manner as for the synthesis of Intermediate 1-4. (yield: 50%)

### 4.5 Synthesis of Compound 6

Compound 6 was synthesized utilizing Intermediate 6-4 instead of Intermediate 1-4 in substantially the same manner as for the synthesis of Compound 1. (yield: 3%)

### 5. Synthesis of Compound 7

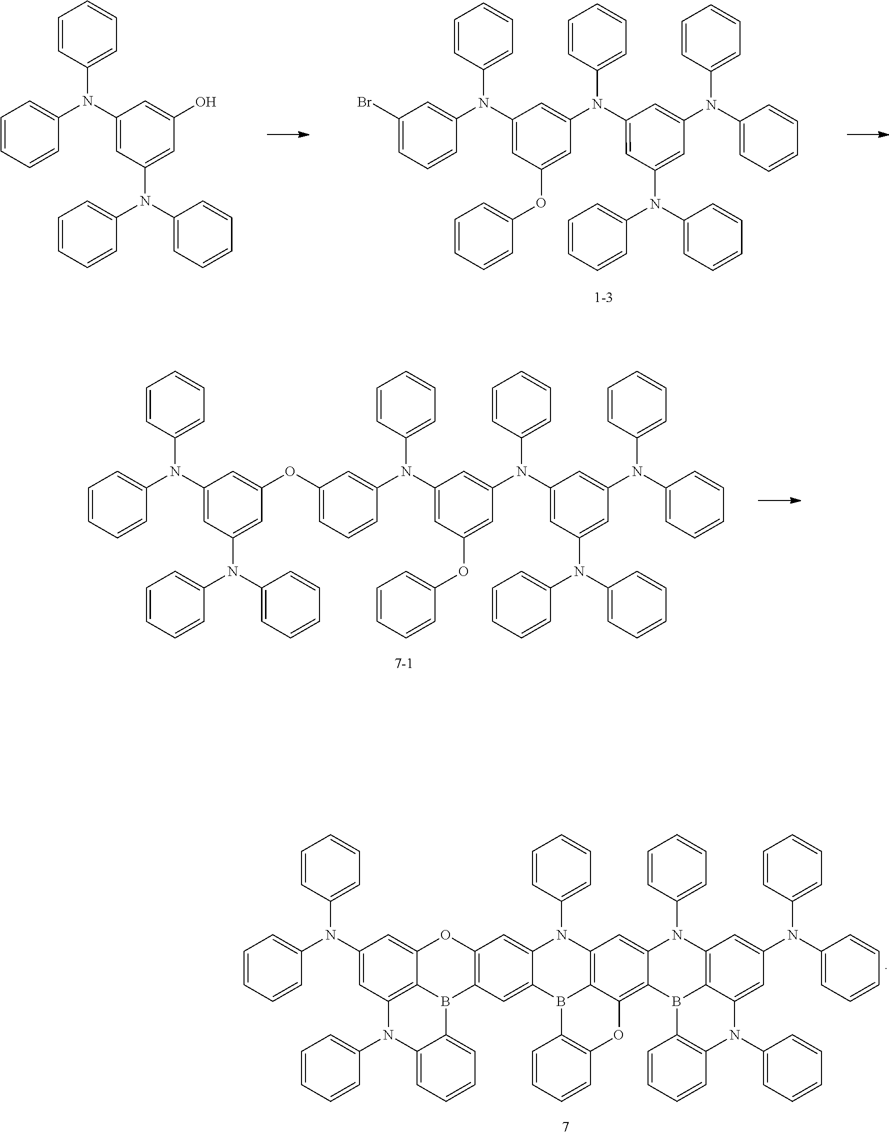 [SMILES: Oc1cc(N(c2ccccc2)c2ccccc2)cc(N(c2ccccc2)c2ccccc2)c1 ; Brc1cccc(N(c2ccccc2)c2cc(Oc3ccccc3)cc(N(c3ccccc3)c3cc(N(c4ccccc4)c4ccccc4)cc(N(c4ccccc4)c4ccccc4)c3)c2)c1 ; c1ccc(Oc2cc(N(c3ccccc3)c3cccc(Oc4cc(N(c5ccccc5)c5ccccc5)cc(N(c5ccccc5)c5ccccc5)c4)c3)cc(N(c3ccccc3)c3cc(N(c4ccccc4)c4ccccc4)cc(N(c4ccccc4)c4ccccc4)c3)c2)cc1 ; c1ccc(N(c2ccccc2)c2cc3c4c(c2)N(c2ccccc2)c2ccccc2B4c2cc4c(cc2O3)N(c2ccccc2)c2cc3c(c5c2B4c2ccccc2O5)B2c4ccccc4N(c4ccccc4)c4cc(N(c5ccccc5)c5ccccc5)cc(c42)N3c2ccccc2)cc1]

### 5.1 Synthesis of Intermediate 7-1

Intermediate 1-3 (1 equivalent), 3,5-bis(diphenylamino)phenol (1.5 equivalent), copper iodide (0.1 equivalent), 2-picolinic acid (0.1 equivalent), and potassium carbonate (3 equivalent) were dissolved in DMF, and then stirred at about 180° C. for about 12 hours under a nitrogen atmosphere. After cooling, the mixture was washed with ethyl acetate and water three times, and then the resulting organic layer was dried over MgSO₄, followed by drying under reduced pressure. Then, separation and purification were performed by column chromatography to obtain Intermediate 7-1. (yield: 60%)

### 5.2 Synthesis of Compound 7

Compound 7 was synthesized utilizing Intermediate 7-1 instead of Intermediate 1-4 in substantially the same manner as for the synthesis of Compound 1. (yield: 3%)

### 6. Synthesis of Compound 13

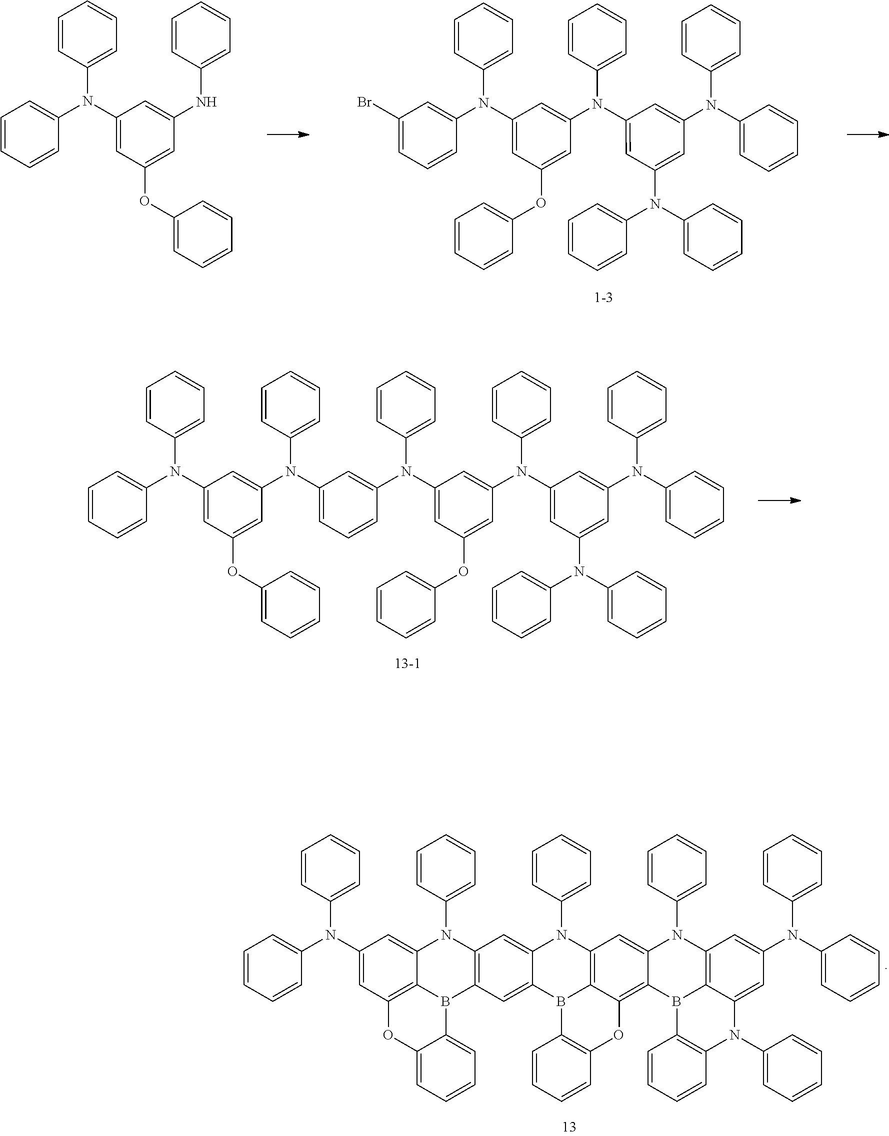 [SMILES: c1ccc(Nc2cc(Oc3ccccc3)cc(N(c3ccccc3)c3ccccc3)c2)cc1 ; Brc1cccc(N(c2ccccc2)c2cc(Oc3ccccc3)cc(N(c3ccccc3)c3cc(N(c4ccccc4)c4ccccc4)cc(N(c4ccccc4)c4ccccc4)c3)c2)c1 ; c1ccc(Oc2cc(N(c3ccccc3)c3ccccc3)cc(N(c3ccccc3)c3cccc(N(c4ccccc4)c4cc(Oc5ccccc5)cc(N(c5ccccc5)c5cc(N(c6ccccc6)c6ccccc6)cc(N(c6ccccc6)c6ccccc6)c5)c4)c3)c2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4N(c4ccccc4)c4cc(N(c6ccccc6)c6ccccc6)cc(c43)N2c2ccccc2)N5c2ccccc2)cc1]

### 6.1 Synthesis of Intermediate 13-1

Compound 13-1 was synthesized utilizing 5-phenoxy-N1,N1,N3-triphenylbenzene-1,3-diamine instead of Intermediate 1-2 and Intermediate 1-3 instead of 1-bromo-3-iodobenzene in substantially the same manner as for the synthesis of Intermediate 1-3. (yield: 65%)

### 6.2 Synthesis of Compound 13

Compound 13 was synthesized utilizing Intermediate 13-1 instead of Intermediate 1-4 in substantially the same manner as for the synthesis of Compound 1. (yield: 3%)

¹H NMR and MS/FAB of the synthesized compounds are shown in Table 1. The synthesis method of compounds other than the compounds shown in Table 1 can also be easily recognized by those skilled in the art by referring to synthetic routes and raw materials above.

TABLE 1

| | | MS/FAB | |
|---|---|---|---|
| Compounds | ¹H NMR (δ) | Calc | Found |
| 1 | 10.1-9.95(1H,d), 8.52-8.48(2H,d), 8.21-8.15(1H,d) | 1364.05 | 1365.10 |
| | 7.67-7.60(15H,m), 7.58-7.41(18H,m), 7.40- | | |
| | 7.27(14H,m), 7.24-7.07(9H,m), 6.78-6.74(2H,m), 6.13- | | |
| | 6.08(2H,m) | | |
| 2 | 10.3-9.97(1H,d), 8.58-8.47(2H,d), 8.3-8.17(1H,d) 7.71- | 1516.24 | 1517.03 |
| | 7.51(15H,m), 7.48-7.35(16H,m), 7.34-7.26(16H,m), | | |
| | 7.22-7.07(17H,m), 6.81-6.74(2H,m), 6.64-6.57(2H,m) | | |
| 3 | 10.2-9.8(1H,d), 8.61-8.54(2H,m), 8.37-8.31(1H,d) | 1668.44 | 1669.31 |
| | 7.70-7.53(15H,m), 7.48-7.34(16H,m), 7.31- | | |
| | 7.23(19H,m), 7.22-7.01(22H,m), 6.83-6.77(2H,m), | | |
| | 6.71-6.66(2H,m) | | |
| 6 | 10.3-10.1(1 H,d), 8.7-8.65(2H,m), 8.41-8.38(1H,d) | 1196.84 | 1197.15 |
| | 7.80-7.61(10H,m), 7.57-7.37(16H,m), 7.36- | | |
| | 7.24(11H ,m), 7.22-6.97(10H, m), 6.85-6.77(2H, m), | | |
| | 6.73-6.66(2H,m) | | |
| 7 | 10.3-10.1 (1H,d), 8.71-8.64(2H, m), 8.42-8.38(1H ,d) | 1288.93 | 1289.24 |
| | 7.79-7.62(12H,m), 7.58-7.34(14H,m), 7.33- | | |
| | 7.24(15H,m), 7.22-6.98(10H,m), 6.85-6.77(2H,m), | | |
| | 6.73-6.66(2H,m) | | |
| 13 | 10.5-10.3(1H,d), 8.73-8.69(2H,m), 8.63-8.59(1H,d) | 1288.93 | 1289.21 |
| | 7.85-7.62(12H,m), 7.59-7.37(14H,m),7.33- | | |
| | 7.25(15H,m), 7.22-7.01(10H,m), 6.87-6.80(2H,m), | | |
| | 6.77-6.73(2H,m) | | |

### Manufacture of Organic Electroluminescence Device

The organic electroluminescence devices were manufactured utilizing Example and Comparative Example Compounds as materials of an emission layer.

### Example Compounds

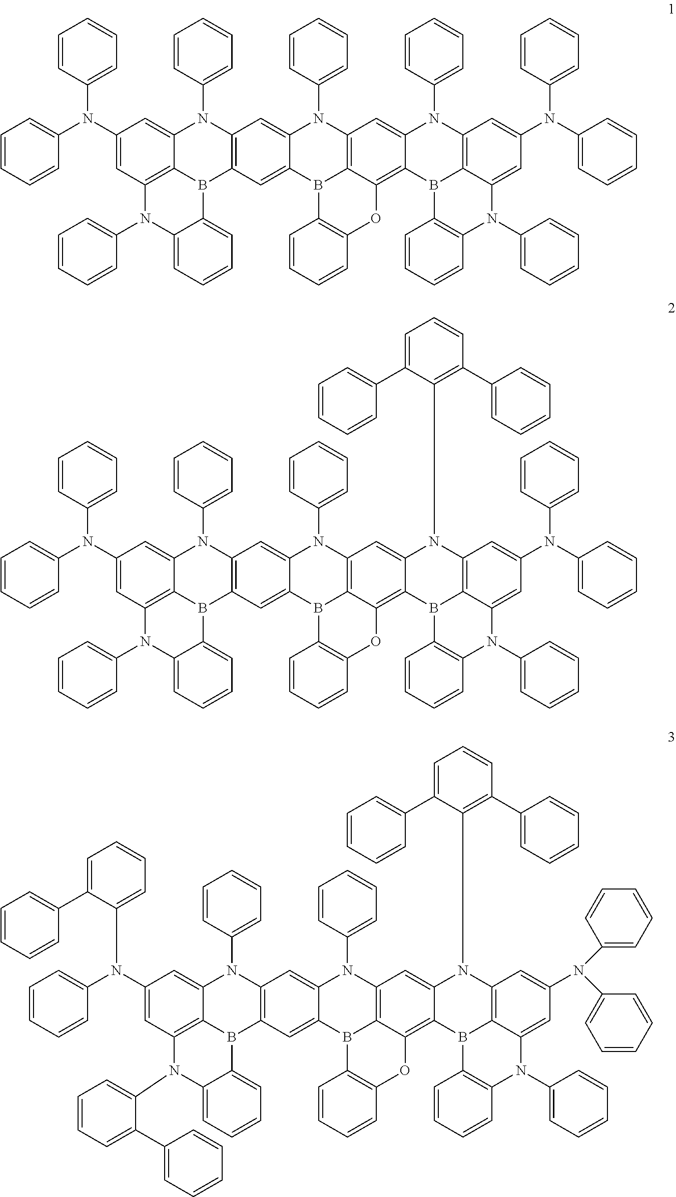

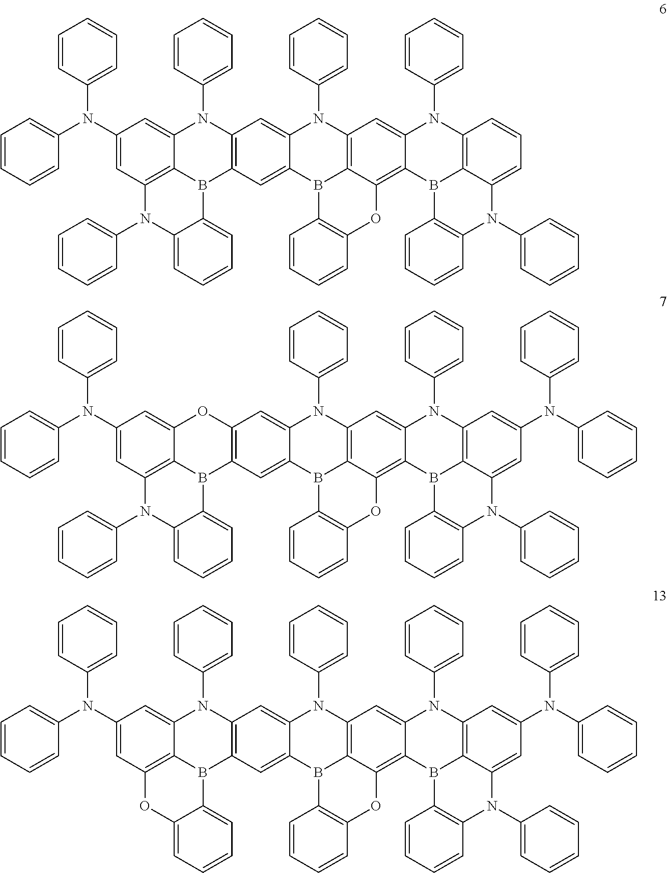

### Comparative Example Compounds

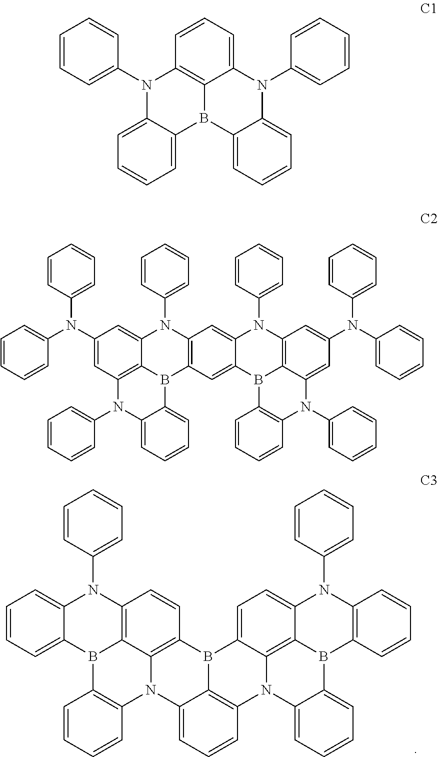

The organic electroluminescence devices of Examples and Comparative Examples were manufactured by the following method.

A 1200 Å-thickness ITO was patterned on a glass substrate to form a first electrode, cleansed by ultrasonic waves for about 5 minutes utilizing isopropyl alcohol and then pure water, respectively, and then irradiated with ultraviolet rays for about 30 minutes and exposed to ozone to clean. On the upper portion of the glass substrate on which ITO was formed, ax-NPD was deposited in vacuum to form a 300 Å-thick hole injection layer, and then HT3 was deposited in vacuum to form a 200 Å-thick hole transport layer. On the upper portion of the hole transport layer, CzSi, a hole transporting compound, was deposited in vacuum to a thickness of about 100 Å to form a light-emitting auxiliary layer.

Next, for forming an emission layer, an Example or Comparative Example polycyclic compound was co-deposited with mCBP in a weight ratio (e.g., amount) of about 1:99 to form a 200 Å-thick layer.

Then, on the upper portion of the emission layer, a layer with a thickness of about 200 Å was formed utilizing TSPO1 as an electron transport layer compound, and then TPBi as an electron injection layer compound was deposited to a thickness of about 300 Å. On the upper portion of the electron transport layer, LiF that is an alkaline metal halide was deposited to form a 10 Å-thick electron injection layer, and Al was deposited in vacuum to form a 3,000 Å-thick LiF/Al electrode (second electrode) to manufacture an organic electroluminescence device.

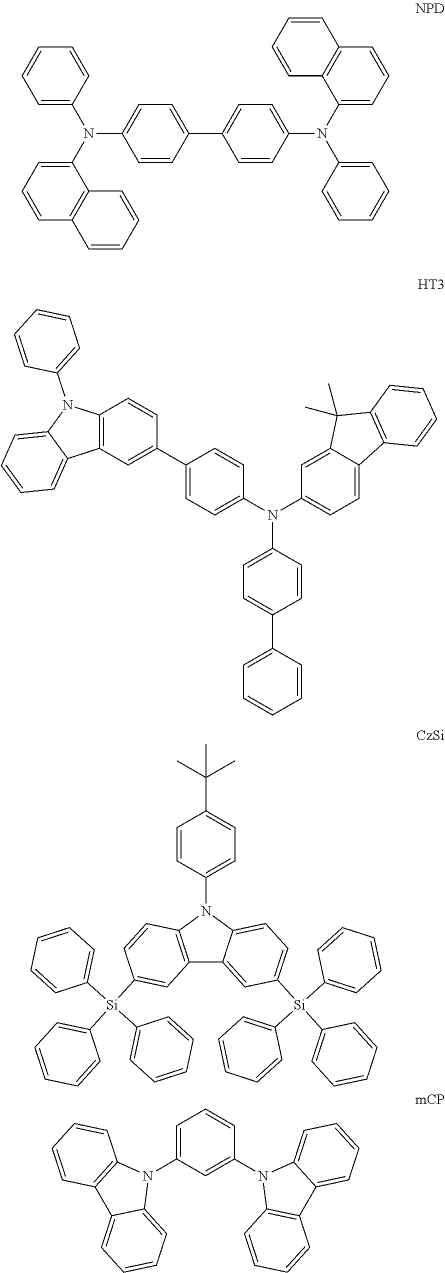

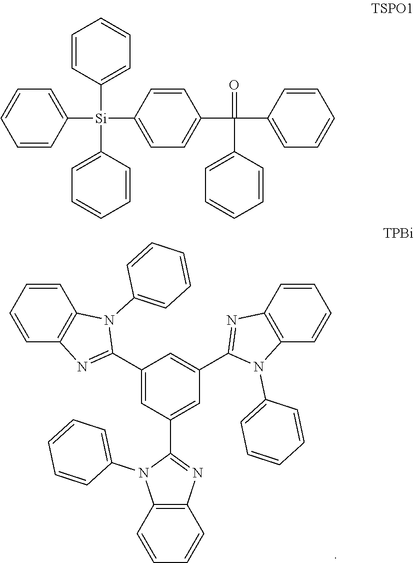

### Evaluation of Characteristics of Organic Electroluminescence Device

The evaluation results of the organic electroluminescence devices for Examples 1 to 6 and Comparative Examples 1 to 3 are shown in Table 2. The driving voltage, luminous efficiency and external quantum efficiency (EQE) of the manufactured organic electroluminescence devices are shown in Table 2 for comparison.

In the evaluation results of characteristics of Examples and Comparative Examples shown in Table 2, the voltage and current density were measured by utilizing a SourceMeter (Keithley Instrument, Inc., 2400 series), and luminous efficiency was measured by utilizing an external quantum efficiency measurement apparatus, C9920-2-12 manufactured by Hamamatsu Photonics, Inc. In the evaluation of the maximum external quantum efficiency, luminance/current density were measured by utilizing a luminance meter calibrated for wavelength sensitivity, and the maximum external quantum efficiency was calculated assuming an angular luminance distribution (Lambertian) in which ideal diffuse reflecting surface is contemplated. The driving voltage and luminous efficiency represent the current efficiency values for a current density of 10 mA/cm².

TABLE 2

| | | Driving | Luminous | | |
|---|---|---|---|---|---|
| | Dopant in | voltage | efficiency | Maximum external | Light-emitting |
| | emission layer | (V) | (Cd/A) | quantum efficiency (%) | color |
| Example 1 | Compound 1 | 4.7 | 25.1 | 26.3 | Blue |
| Example 2 | Compound 2 | 4.51 | 26.4 | 27.3 | Blue |
| Example 3 | Compound 3 | 4.54 | 24.8 | 25.9 | Blue |
| Example 4 | Compound 6 | 4.91 | 21.2 | 23.7 | Blue |
| Example 5 | Compound 7 | 4.60 | 22.8 | 23.5 | Blue |
| Example 6 | Compound 13 | 4.54 | 22.2 | 21.9 | Blue |
| Comparative | C1 | 5.7 | 15.6 | 16.1 | Blue |
| Examples 1 | | | | | |
| Comparative | C2 | 4.9 | 22.8 | 23.0 | Blue |
| Examples 2 | | | | | |
| Comparative | C3 | 5.5 | 17.1 | 18.4 | Bluish green |
| Examples 3 | | | | | |

Referring to Table 2 above, it may be seen that the organic electroluminescence devices of the Examples that utilize the polycyclic compound according to an embodiment of the present disclosure as a material for the emission layer exhibit low driving voltage values, and exhibit relatively high luminous efficiency and maximum external quantum efficiency, compared to the Comparative Examples.

The Example Compounds exhibit TADF characteristics by utilizing a multiple resonance phenomenon due to aromatic rings that form a condensed ring (e.g., because the fused aromatic ring system allows for multiple resonance structures), and may exhibit multiple resonance in a wide plate-like skeleton by particularly including 3 boron atoms and including a structure in which 7 aromatic rings are connected via 3 boron atoms and 6 heteroatoms, compared to Comparative Examples 1 and 2, and thus the organic electroluminescence devices of Examples may exhibit improved luminous efficiency than the organic electroluminescence device of Comparative Example.

It may be seen that Comparative Example Compound C3 included in Comparative Example 3 includes a plate-like skeleton and a condensed ring centered on 3 boron atoms, but 4 hetero atoms are included in the condensed ring, and multiple resonance effects by additional heteroatoms are reduced when compared with the Example Compounds. Also, Comparative Example Compound C3 may have a relatively reduced rigid nature in the π-conjugated structure (e.g., a more flexible and/or less planar structure), resulting in reduction of conjugation characteristics, and thereby increasing driving voltage and reducing luminous efficiency compared to Examples.

The polycyclic compound according to an embodiment has a high oscillator strength value and a small ΔE_{ST} value by including a structure in which 7 aromatic rings are connected via 3 boron atoms and 6 heteroatoms, and thereby may be utilized as a delayed fluorescence material. In some embodiments, the polycyclic compound according to an embodiment may be utilized as a dopant material for an emission layer of an organic electroluminescence device, thereby improving efficiency of a device.

The organic electroluminescence device according to an embodiment may include the polycyclic compound according to an embodiment, and may thereby exhibit improved luminous efficiency. In some embodiments, the organic electroluminescence device according to an embodiment may include the polycyclic compound of an embodiment, and thus high efficiency in a blue wavelength region may be achieved.

The organic electroluminescence device according to an embodiment may exhibit improved device characteristics with low driving voltage and high efficiency.

The polycyclic compound according to an embodiment may be included in an emission layer of an organic electroluminescence device to contribute to high efficiency of the organic electroluminescence device.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Although embodiments of the present disclosure have been described, persons having ordinary skill in the art will understand that the present disclosure can be implemented in other specific forms without altering the technical spirit or essential features of the present disclosure, as set forth by the following claims and equivalents thereof. Therefore, it should be understood that the embodiments described above are illustrative in all aspects and not limiting.

What is claimed is:

1. An organic electroluminescence device comprising:
a first electrode:
a hole transport region on the first electrode;
an emission layer on the hole transport region;
an electron transport region on the emission layer; and
a second electrode on the electron transport region, wherein:
the first electrode and the second electrode each independently comprise at least one selected from Ag, Mg, Cu, Al, Pt, Pd, Au, Ni, Nd, Ir, Cr, Li, Ca, LiF/Ca, LiF/Al, Mo, Ti, W, In, Sn, and Zn, a compound of two or more thereof, a mixture of two or more thereof, or an oxide thereof; and
the emission layer comprises a polycyclic compound represented by Formula 1: 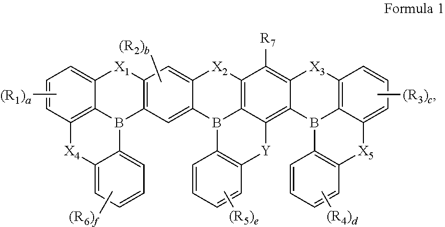
wherein, in Formula 1,
X₁ to X₅ are each independently O, NAr₁, S, or Se,
Y is O, S, or Se,
Ar₁ is a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
R₁ to R₇ are each independently a hydrogen atom, a deuterium atom, a halogen atom, a cyano group, a substituted or unsubstituted alkyl group having 1 to 30 carbon atoms, a substituted or unsubstituted amine group, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a and c are each independently an integer of 0 to 3,
b is an integer of 0 to 2, and
d to f are each independently an integer of 0 to 4.

2. The organic electroluminescence device of claim 1, wherein the emission layer is to emit delayed fluorescence.

3. The organic electroluminescence device of claim 1, wherein the emission layer is a delayed fluorescent emission layer comprising a host and a dopant, and
the dopant comprises the polycyclic compound represented by Formula 1.

4. The organic electroluminescence device of claim 1, wherein the emission layer is a thermally activated delayed fluorescent emission layer to emit blue light.

5. The organic electroluminescence device of claim 1, wherein the sum of a and c is an integer of 1 or more, and
at least one of R₁ and R₃ is a substituted amine group.

6. The organic electroluminescence device of claim 1, wherein the polycyclic compound represented by Formula 1 is represented by Formula 2-1 or Formula 2-2: 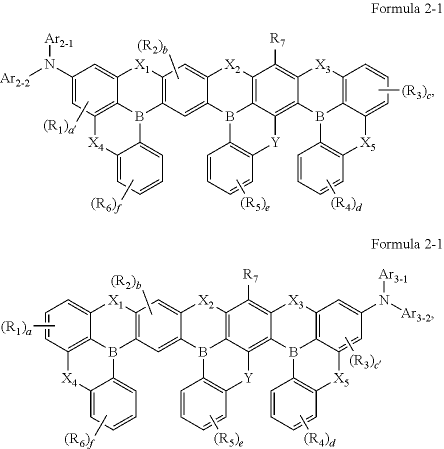
and
wherein, in Formula 2-1 and Formula 2-2,
Ar₂₋₁, Ar₂₋₂, Ar₃₋₁, and Ar₃₋₂ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a′ and c′ are each independently an integer of 0 to 2, and
X₁ to X₅, Y, R₁ to R₇, and a to f are each independently the same as defined in Formula 1.

7. The organic electroluminescence device of claim 1, wherein the polycyclic compound represented by Formula 1 is represented by Formula 3: 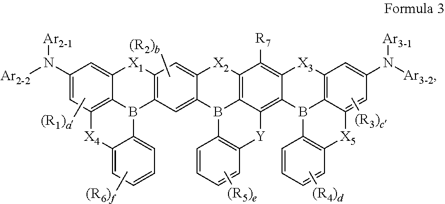
and
wherein, in Formula 3,
Ar₂₋₁, Ar₂₋₂, Ar₃₋₁, and Ar₃₋₂ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a′ and c′ are each independently an integer of 0 to 2, and
X₁ to X₅, Y, R₁ to R₇, b, and d to f are each independently the same as defined in Formula 1.

8. The organic electroluminescence device of claim 7, wherein Ar₂₋₁, Ar₂₋₂, Ar₃₋₁, and Ar₃₋₂ are each independently a substituted or unsubstituted ring-forming aryl group having 6 to 18 carbon atoms.

9. The organic electroluminescence device of claim 1, wherein the polycyclic compound represented by Formula 1 is represented by any one among Formula 4-1 to Formula 4-4: 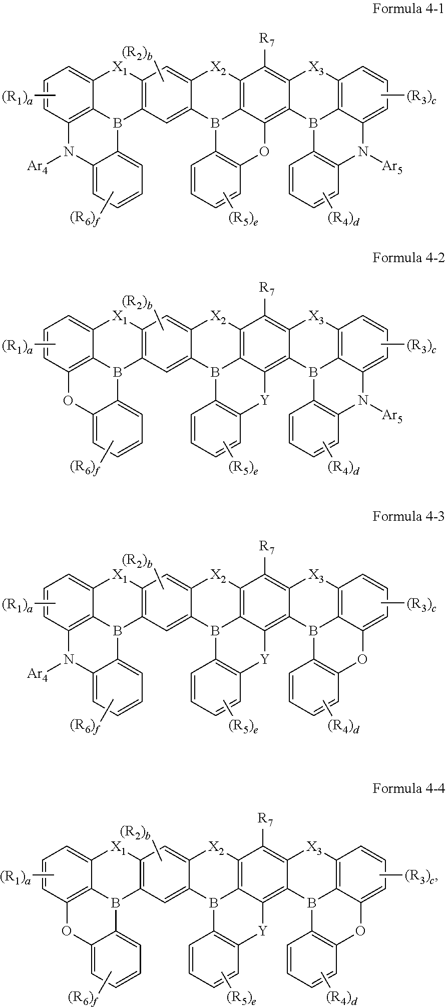
and
wherein, in Formula 4-1 to Formula 4-4,
Ar₄ and Ar₅ are each independently a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms, and
X₁ to X₃, Y, R₁ to R₇, and a to f are each independently the same as defined in Formula 1.

10. The organic electroluminescence device of claim 1, wherein the polycyclic compound represented by Formula 1 is represented by any one among Formula 5-1 to Formula 5-3: 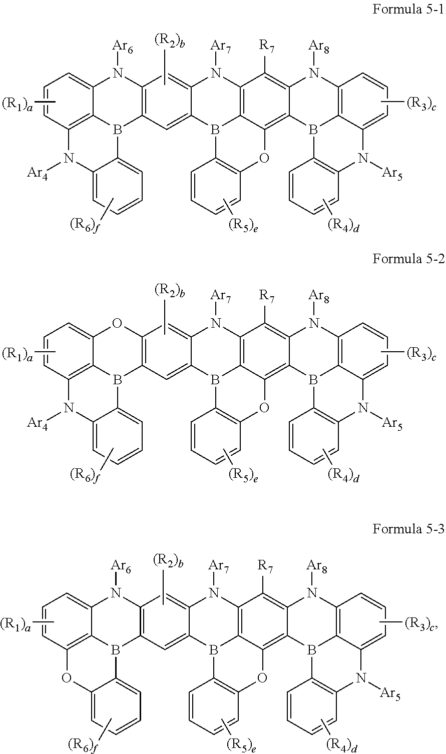
and
wherein, in Formula 5-1 to Formula 5-3,
Ar₄ to Ar₈ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, and
Y, R₁ to R₇, and a to f are each independently the same as defined in Formula 1.

11. The organic electroluminescence device of claim 10, wherein Ar₄ to Ar₈ are each independently represented by any one among Formula 6-1 to Formula 6-3: 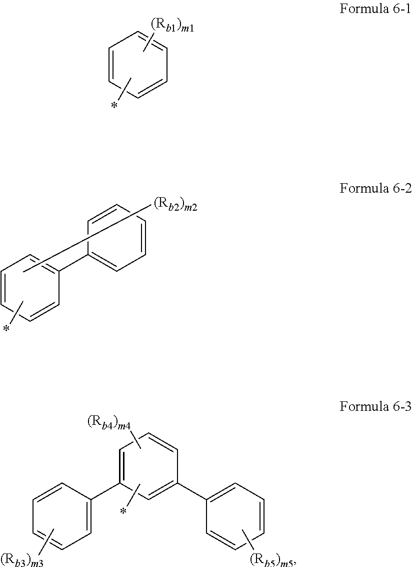
and
wherein, in Formula 6-1 to Formula 6-3,
R_{b1} to R_{b5} are a hydrogen atom, a deuterium atom, a halogen atom, a cyano group, a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
m1, m3, and m5 are each independently an integer of 0 to 5,
m2 is an integer of 0 to 9, and
m4 is an integer of 0 to 3.

12. The organic electroluminescence device of claim 1, wherein the polycyclic compound represented by Formula 1 is any one among the compounds represented in Compound Group 1:

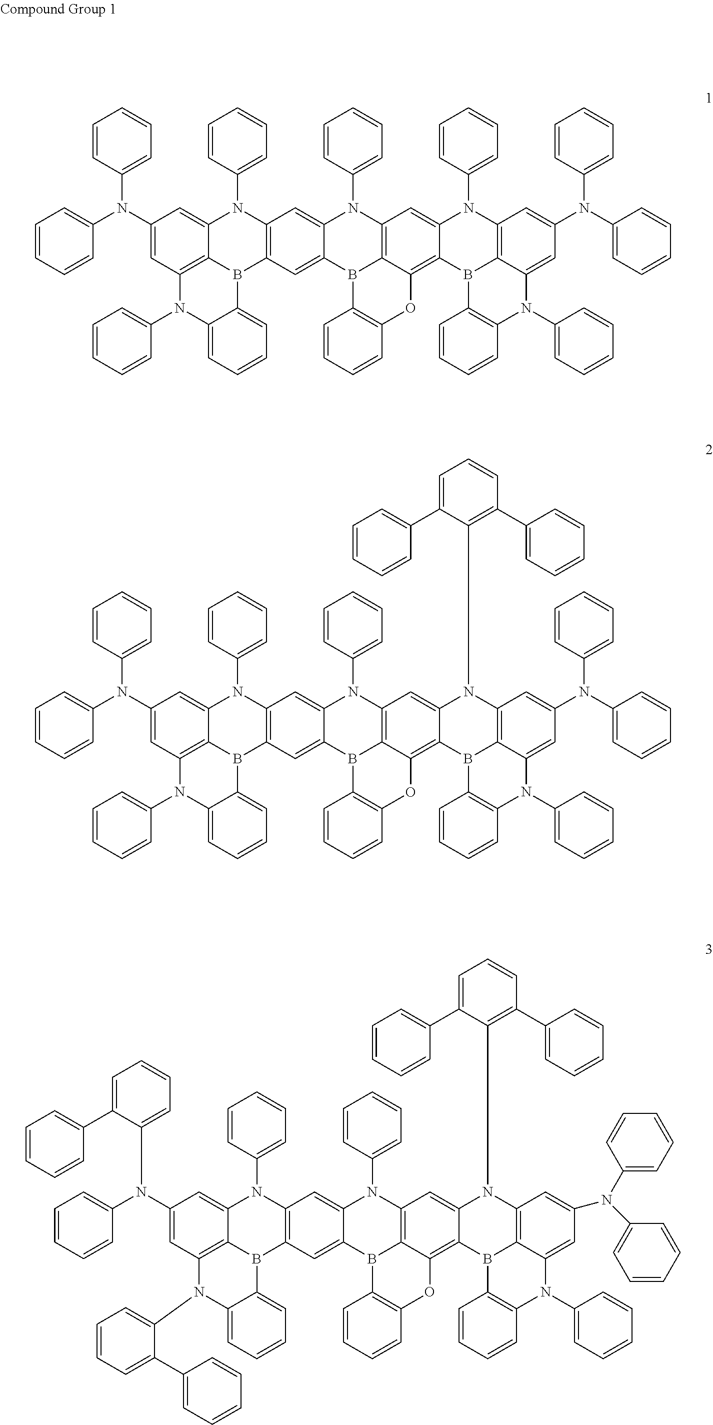

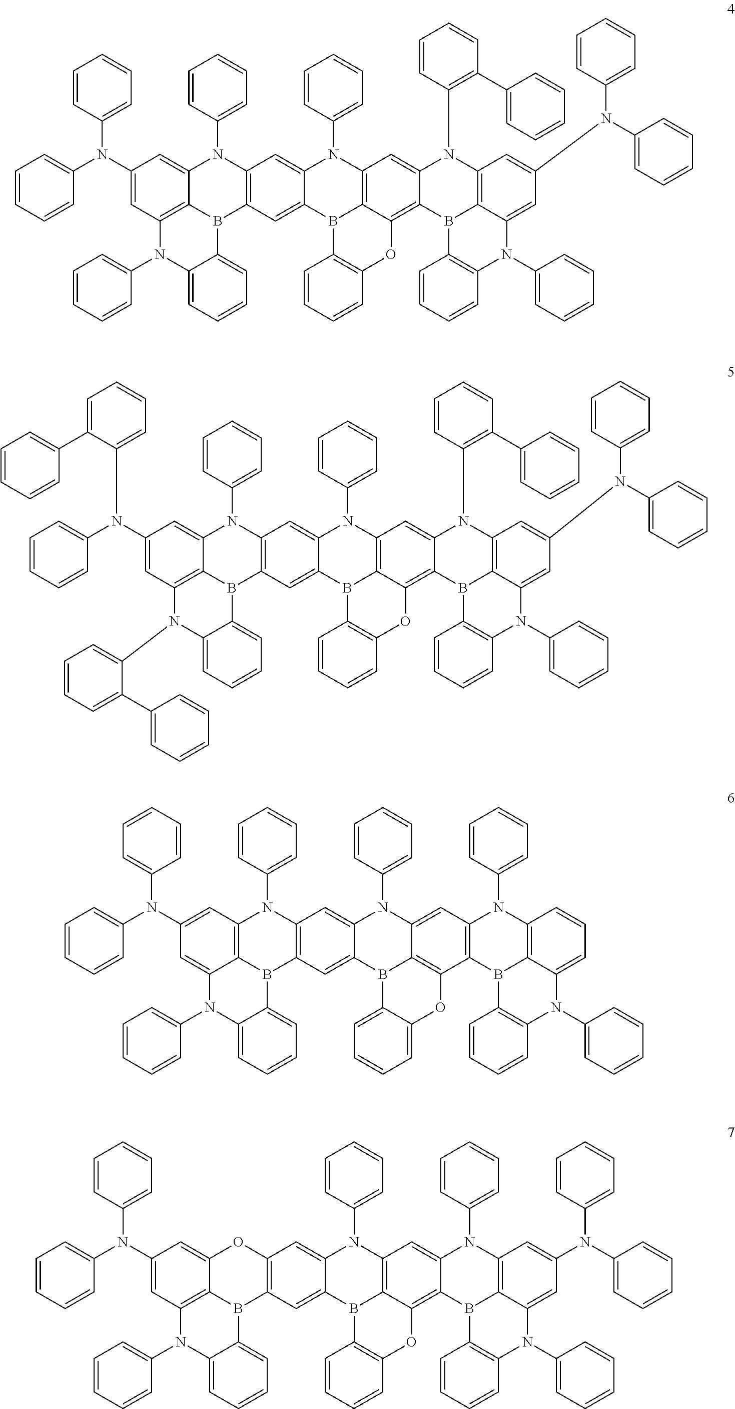

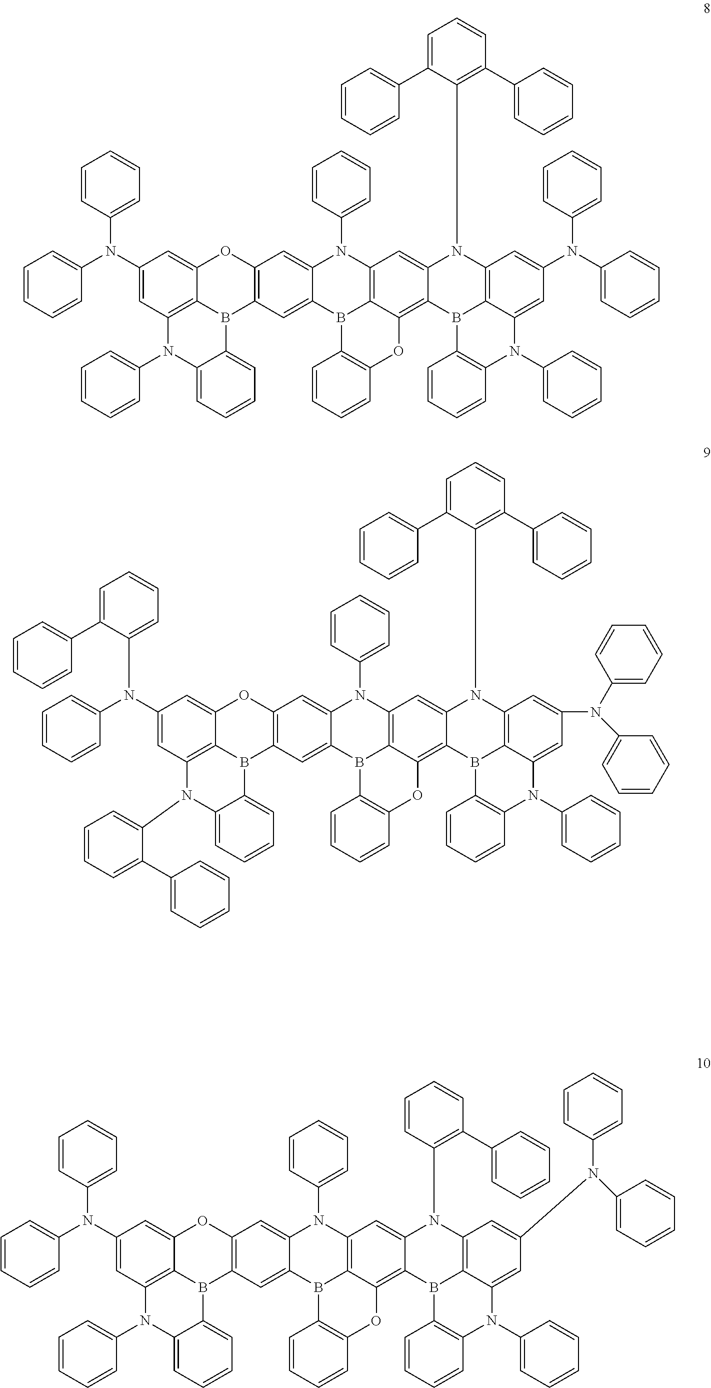

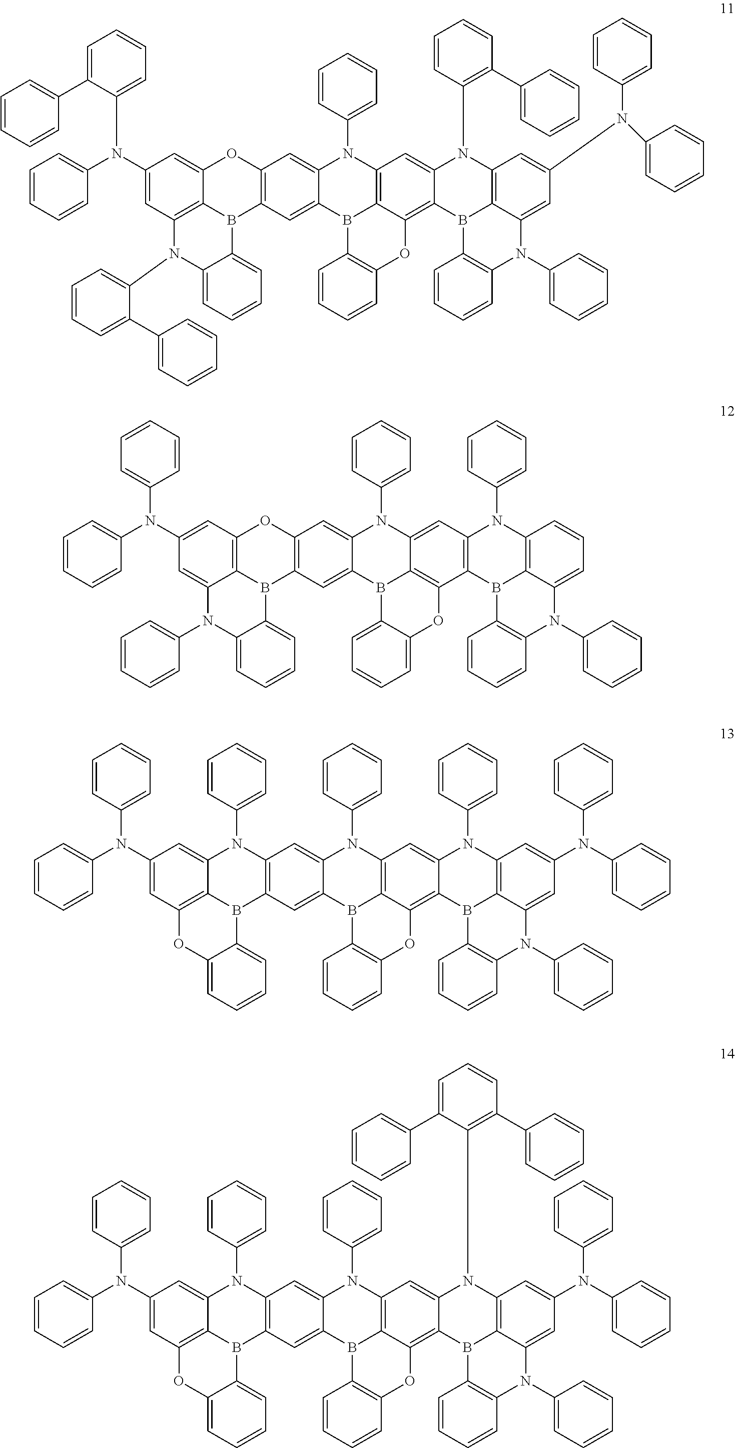

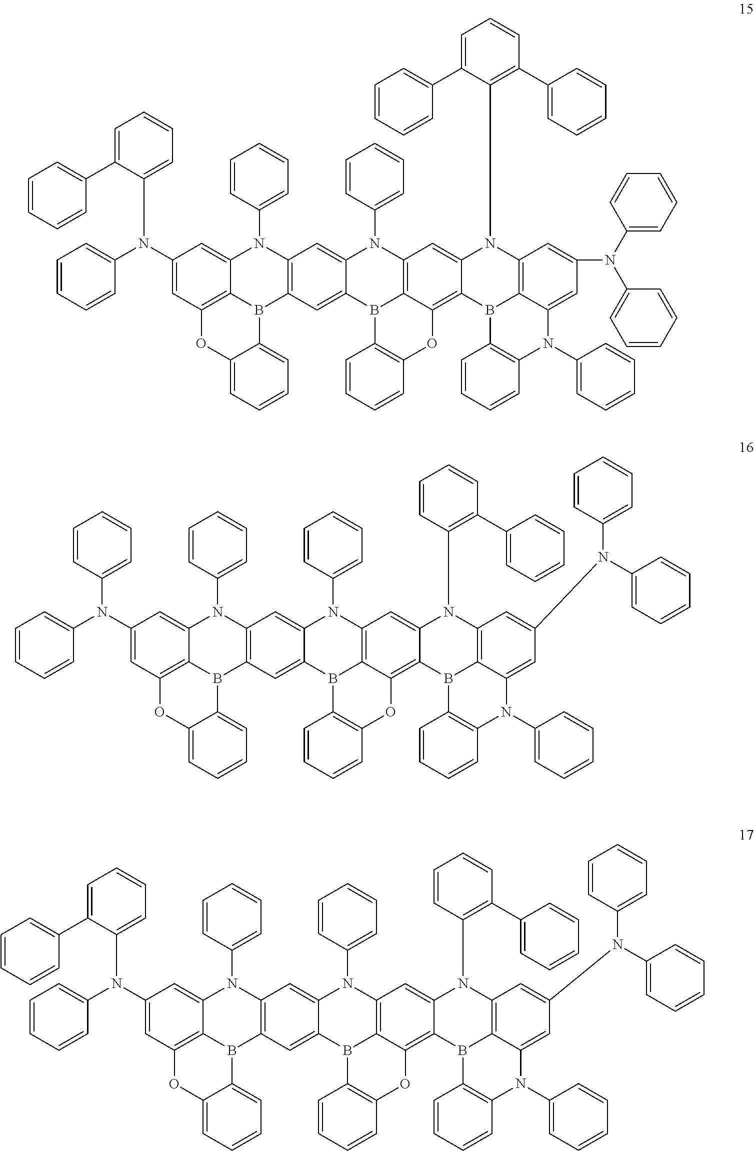

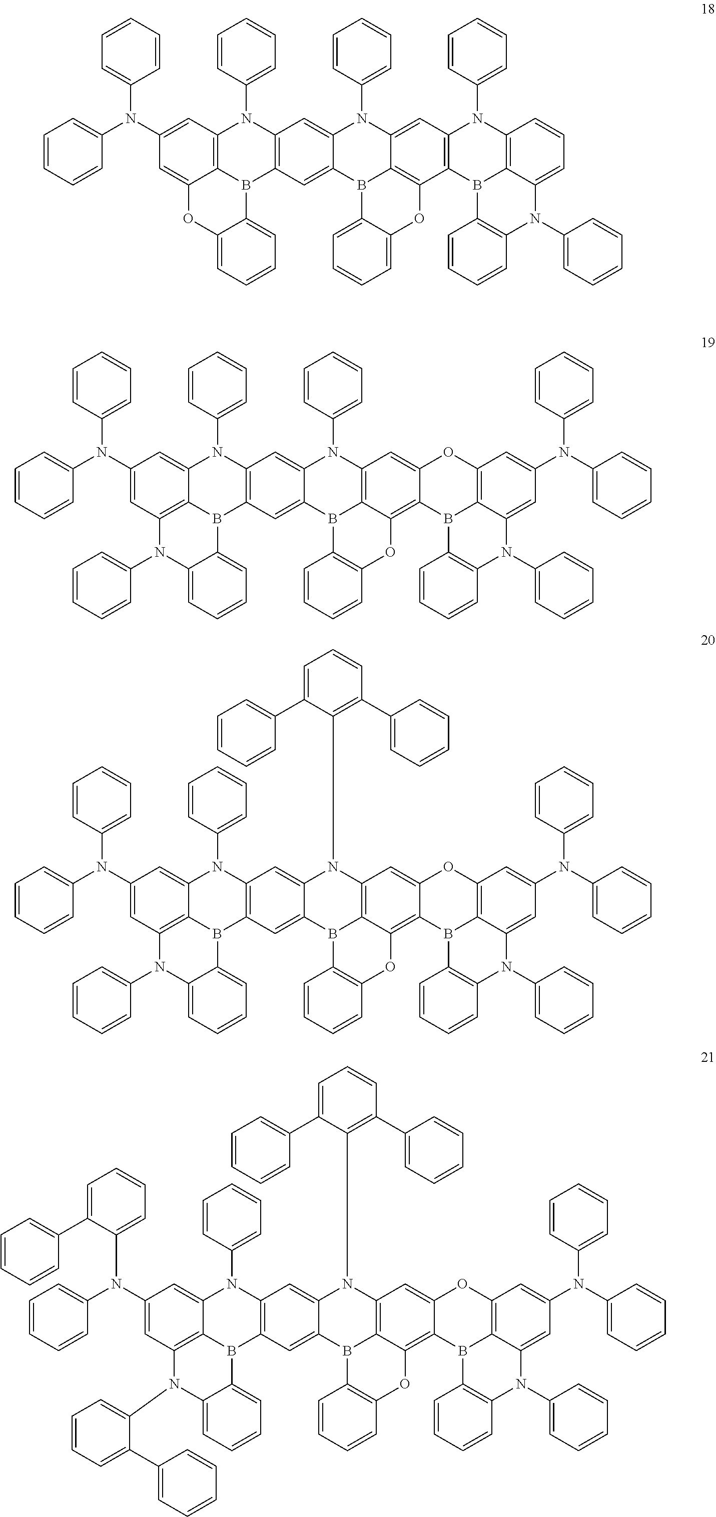

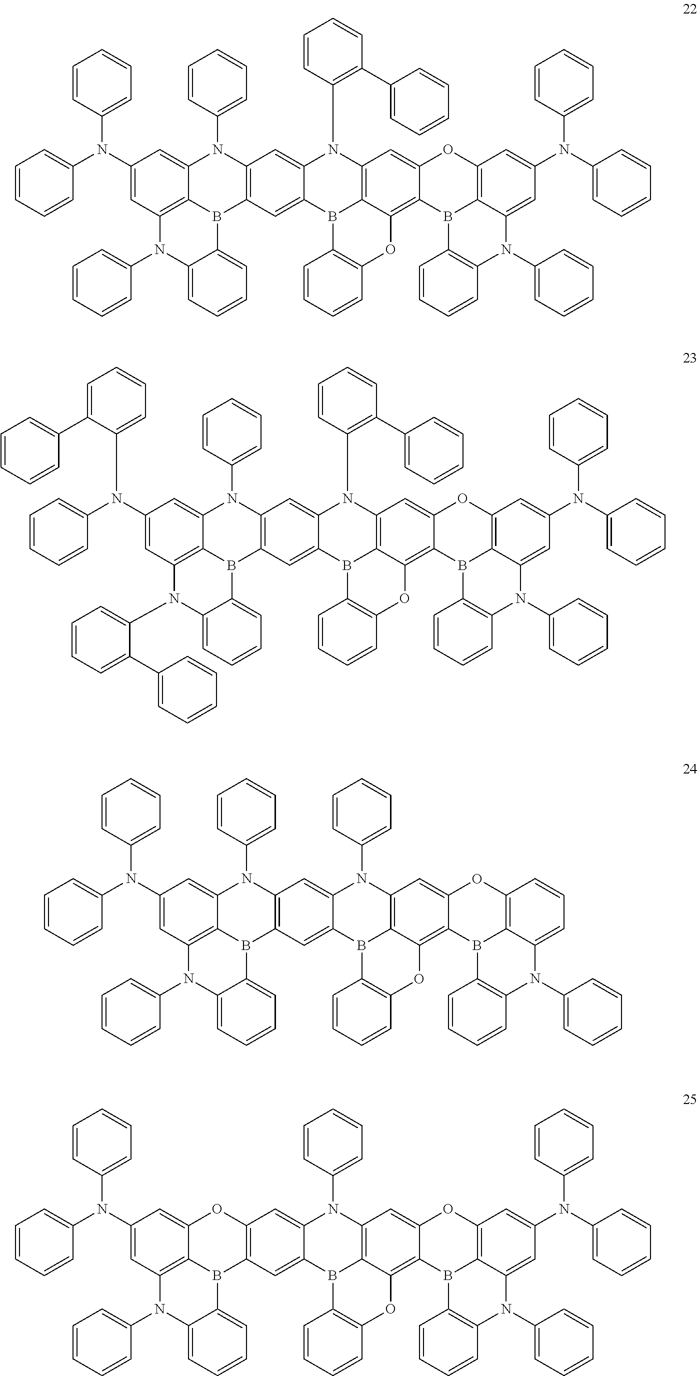

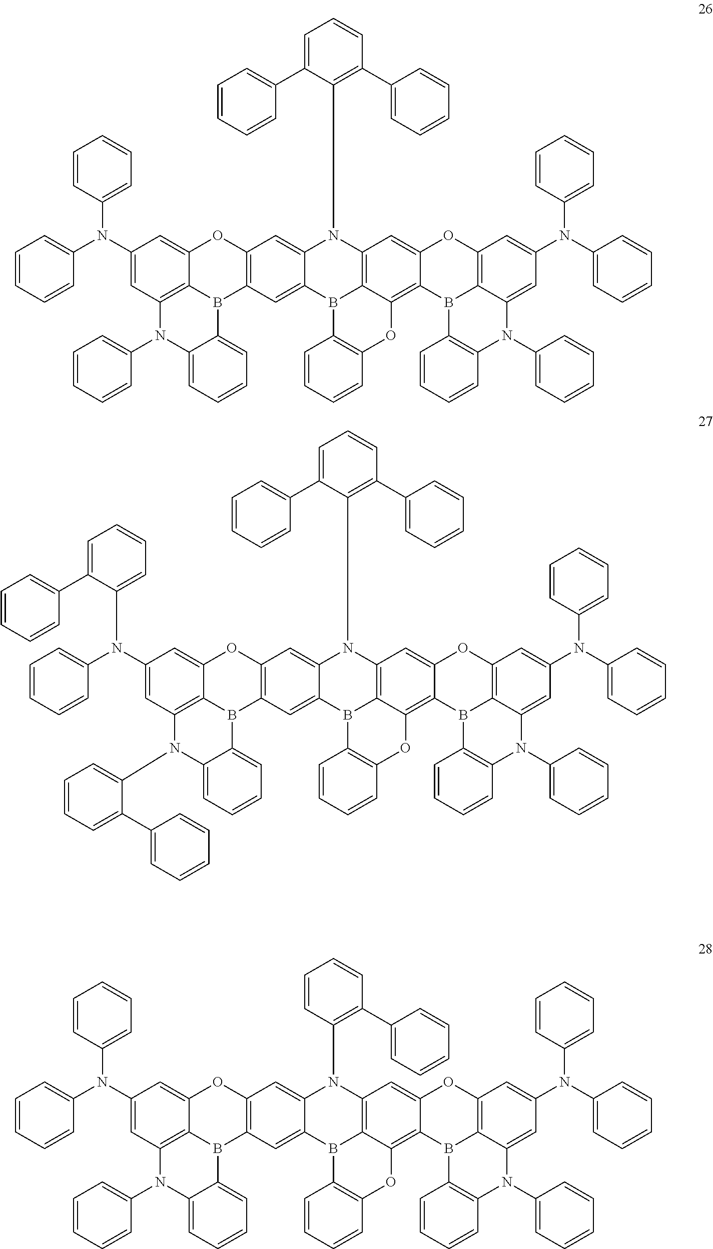

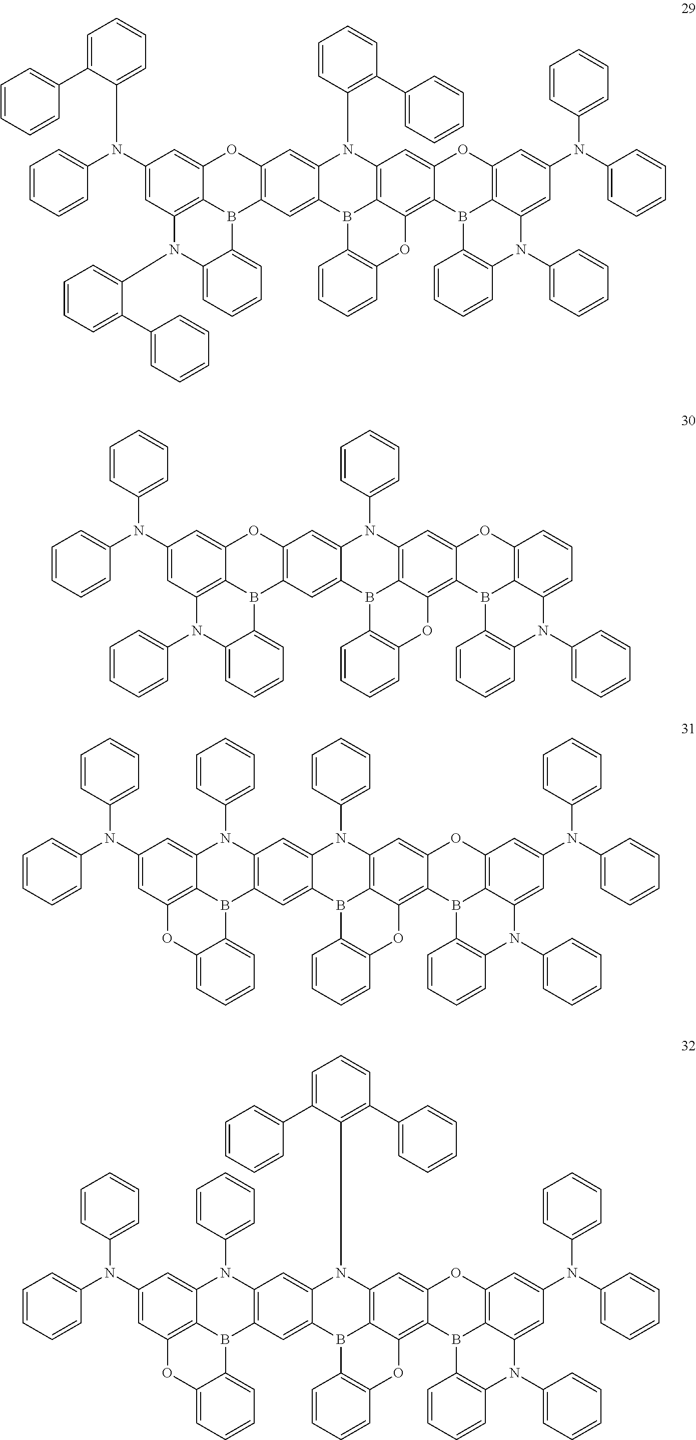

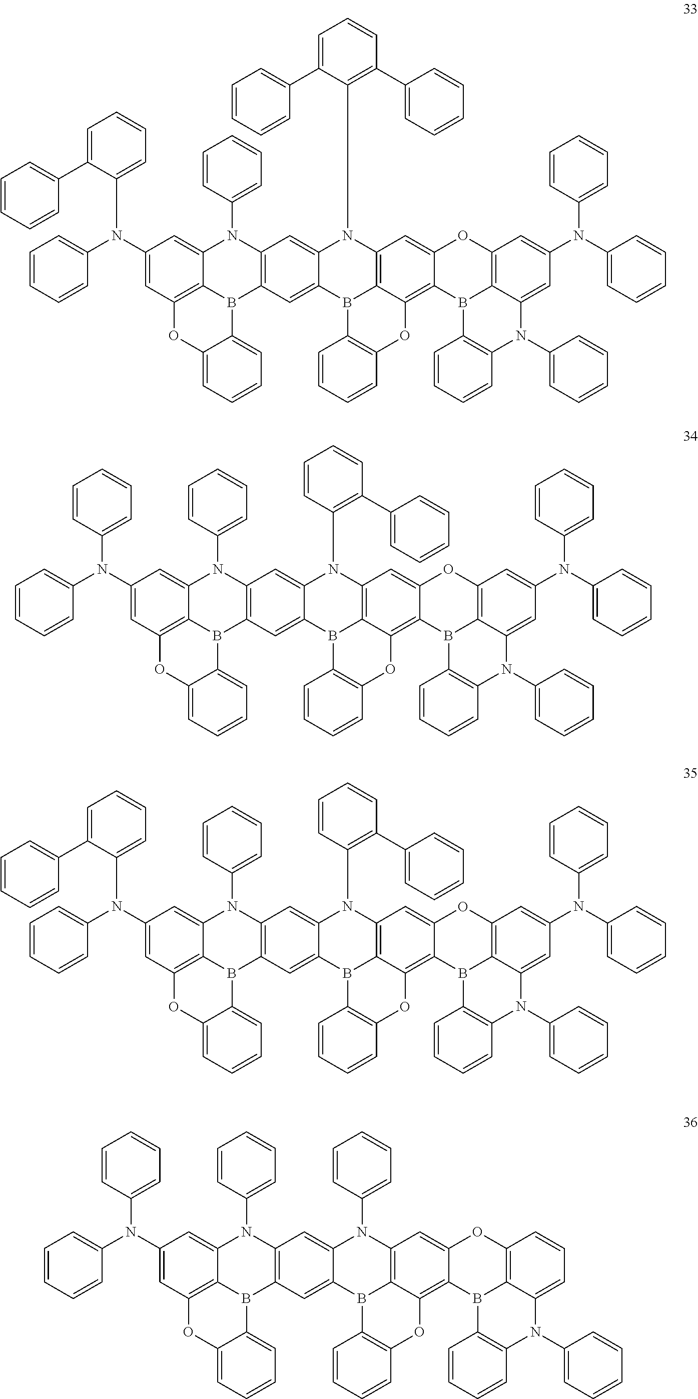

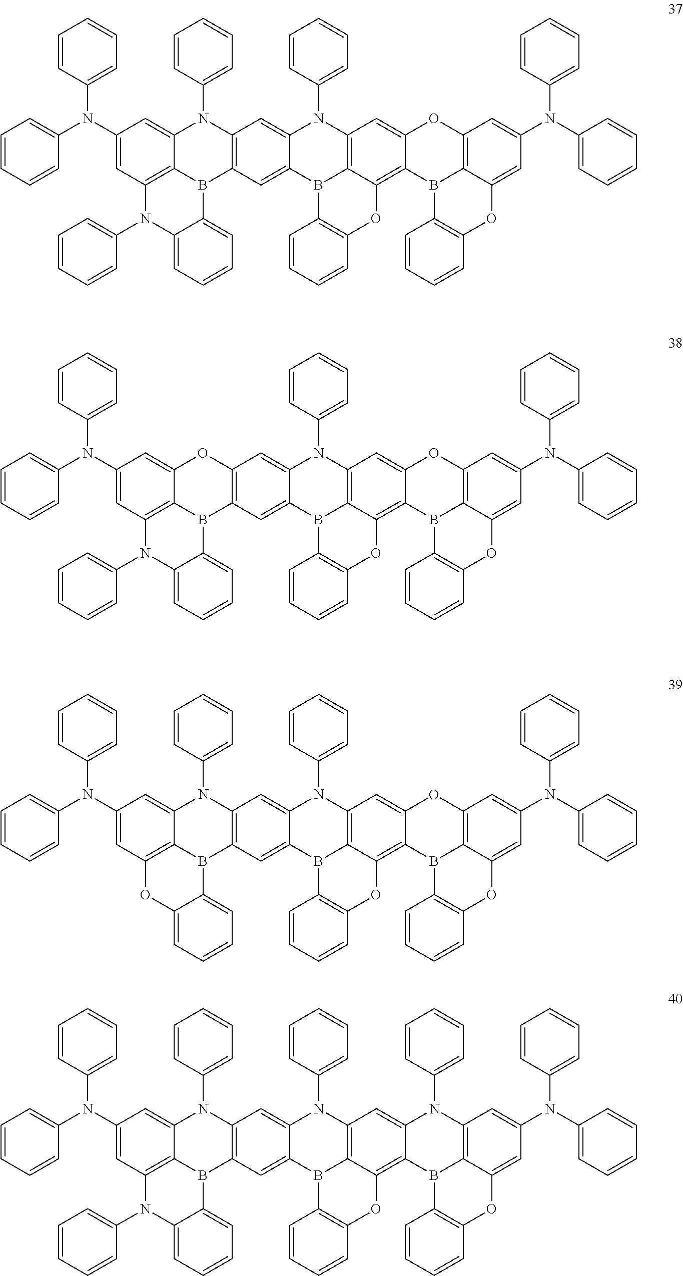

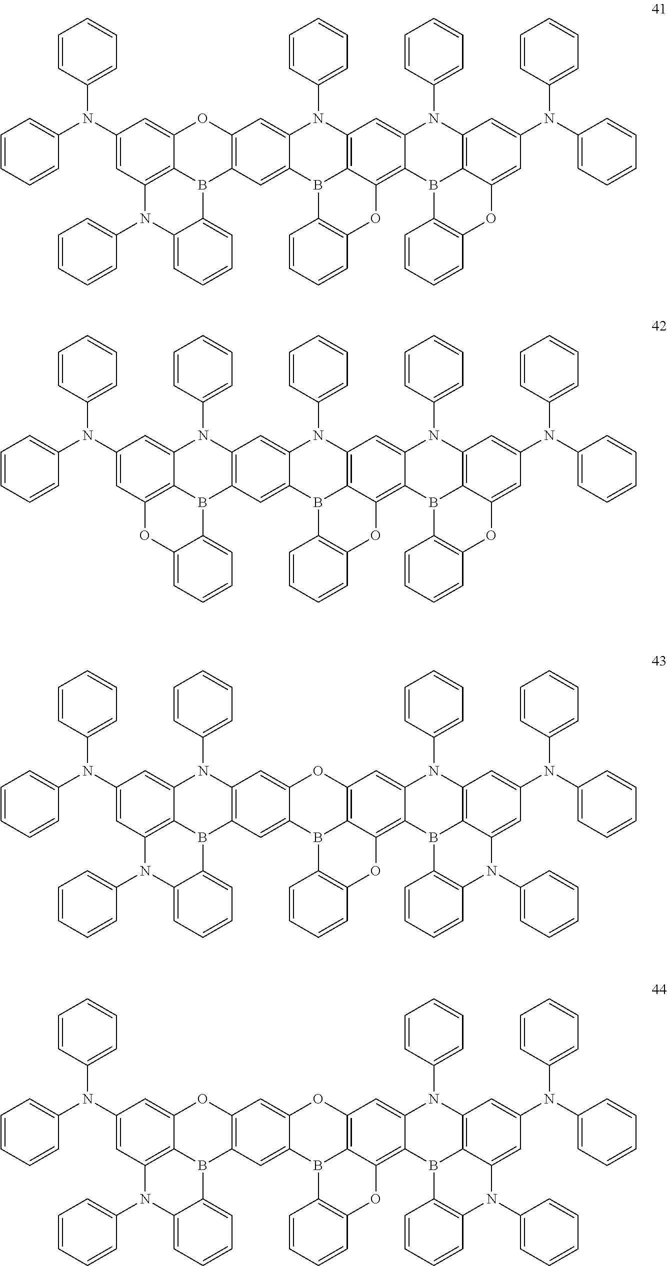

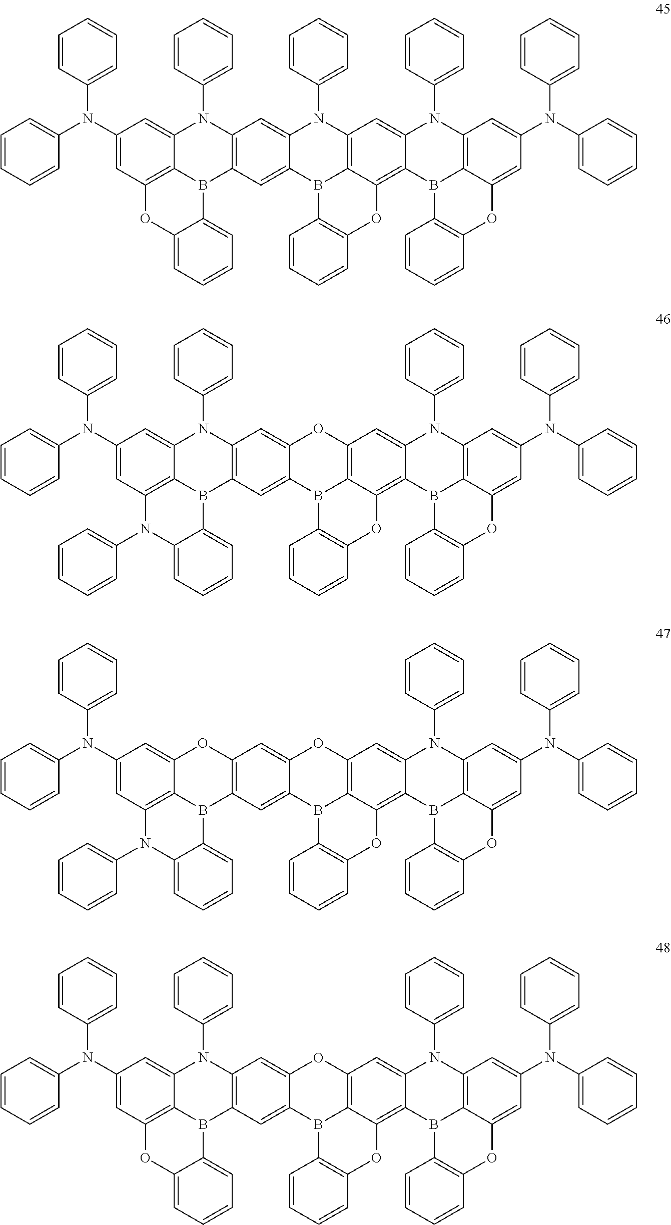

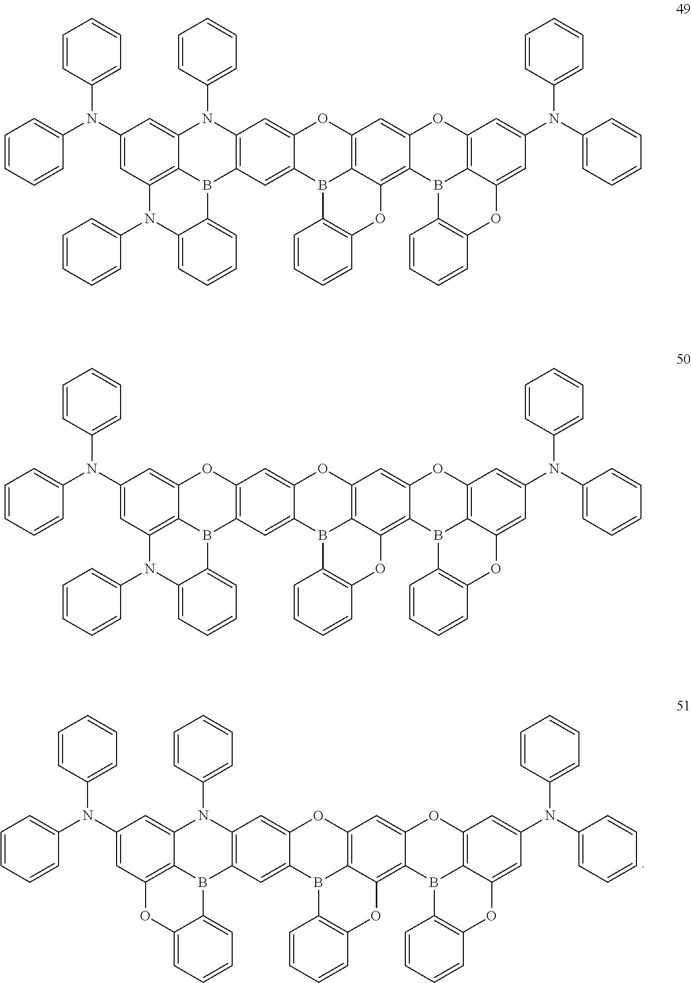 [SMILES: c1ccc(N(c2ccccc2)c2cc3c4c(c2)Oc2cc5c6c(c2B4c2ccccc2O3)Oc2ccccc2B6c2cc3c(cc2O5)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2O5)Oc2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2O5)N(c2ccccc2)c2cc(N(c4ccccc4)c4ccccc4)cc4c2B3c2ccccc2O4)cc1]

13. A polycyclic compound represented by Formula 1: 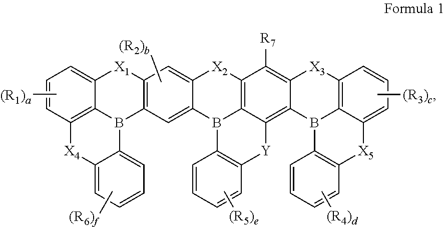
wherein, in Formula 1,
X₁ to X₅ are each independently O, NAr₁, S, or Se,
Y is O, S, or Se,
Ar₁ is a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
R₁ to R₇ are each independently a hydrogen atom, a deuterium atom, a halogen atom, a cyano group, a substituted or unsubstituted alkyl group having 1 to 30 carbon atoms, a substituted or unsubstituted amine group, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a and c are each independently an integer of 0 to 3,
b is an integer of 0 to 2, and
d to f are each independently an integer of 0 to 4.

14. The polycyclic compound of claim 13, wherein Formula 1 is represented by Formula 2-1 or Formula 2-2: 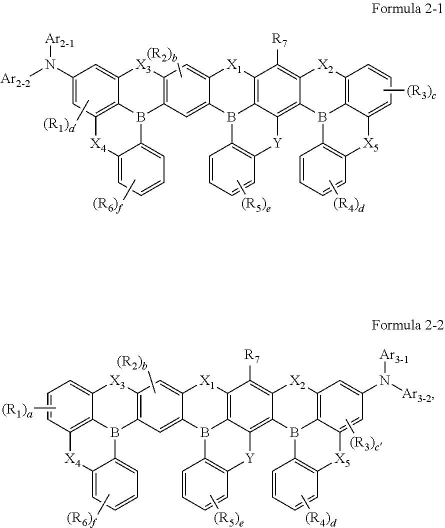
and
wherein, in Formula 2-1 and Formula 2-2,
Ar₂₋₁, Ar₂₋₂, Ar₃₋₁, and Ar₃₋₂ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a′ and c′ are each independently an integer of 0 to 2, and
X₁ to X₅, Y, R₁ to R₇, and a to f are each independently the same as defined in Formula 1.

15. The polycyclic compound of claim 13, wherein Formula 1 is represented by Formula 3: 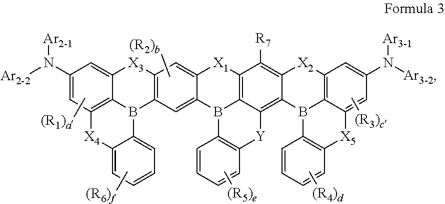
and
wherein, in Formula 3,
Ar₂₋₁, Ar₂₋₂, Ar₃₋₁, and Ar₃₋₂ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
a′ and c′ are each independently an integer of 0 to 2, and
X₁ to X₅, Y, R₁ to R₇, b, and d to f are each independently the same as defined in Formula 1.

16. The polycyclic compound of claim 15, wherein Ar₂₋₁, Ar₂₋₂, Ar₃₋₁, and Ar₃₋₂ are each independently a substituted or unsubstituted ring-forming aryl group having 6 to 18 carbon atoms.

17. The polycyclic compound of claim 13, wherein Formula 1 is represented by any one among Formula 4-1 to Formula 4-4: 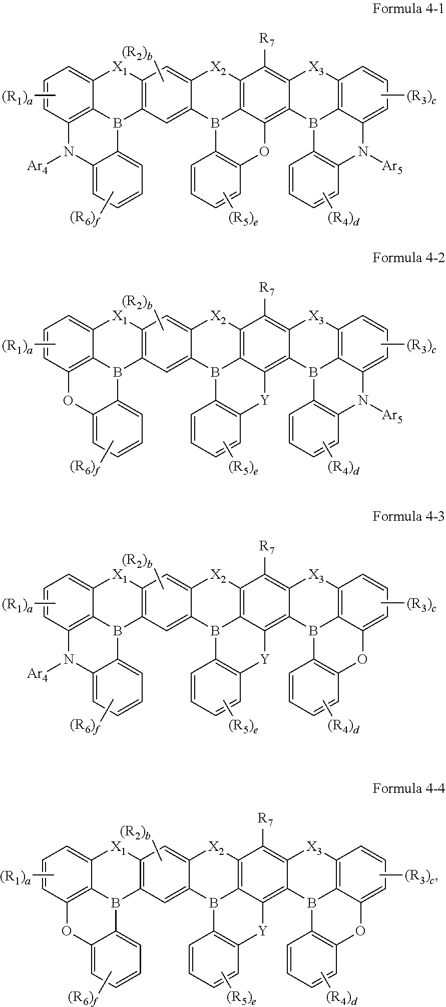
and
wherein, in Formula 4-1 to Formula 4-4,
Ar₄ and Ar₅ are each independently a substituted or unsubstituted alkyl group having 1 to 20 carbon atoms, a substituted or unsubstituted ring-forming aryl group having 6 to 30 carbon atoms, or a substituted or unsubstituted ring-forming heteroaryl group having 2 to 30 carbon atoms, and
X₁ to X₃, Y, R₁ to R₇, and a to f are each independently the same as defined in Formula 1.

18. The polycyclic compound of claim 13, wherein Formula 1 is represented by any one among Formula 5-1 to Formula 5-3: 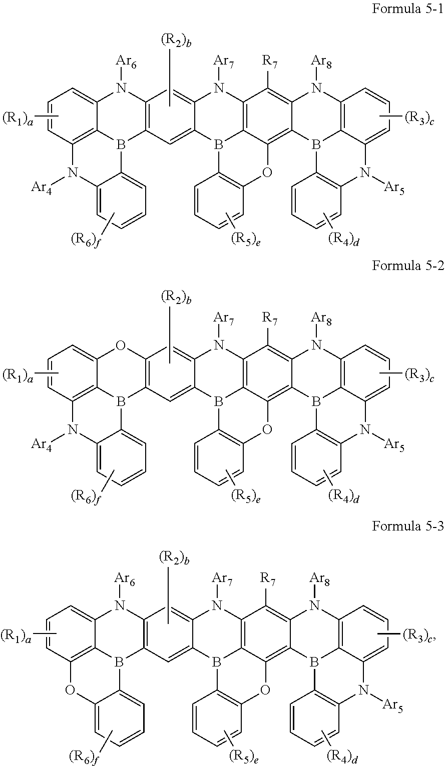
and
wherein, in Formula 5-1 to Formula 5-3,
Ar₄ to Ar₈ are each independently a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring, and
Y, R₁ to R₇, and a to f are each independently the same as defined in Formula 1.

19. The polycyclic compound of claim 18, wherein Ar₄ to Ar₈ are each independently represented by any one among Formula 6-1 to Formula 6-3: 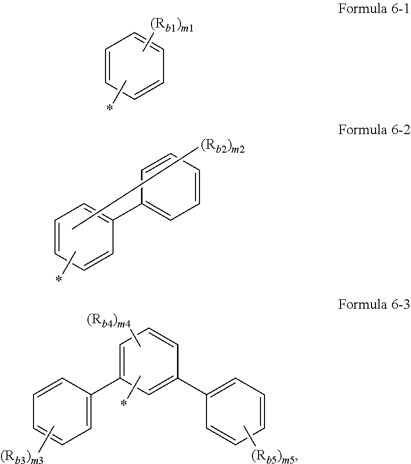
and
wherein, in Formula 6-1 to Formula 6-3,
R_{b1} to R_{b5} are a hydrogen atom, a deuterium atom, a halogen atom, a cyano group, a substituted or unsubstituted alkyl group having 1 to 20 carbon atoms, a substituted or unsubstituted ring-forming aryl group having 6 to 30 carbon atoms, a substituted or unsubstituted ring-forming heteroaryl group having 2 to 30 carbon atoms, or combined with an adjacent group to form a ring,
m1, m3, and m5 are each independently an integer of 0 to 5,
m2 is an integer of 0 to 9, and
m4 is an integer of 0 to 3.

20. The polycyclic compound of claim 13, wherein the polycyclic compound represented by Formula 1 is any one among the compounds represented in Compound Group 1: 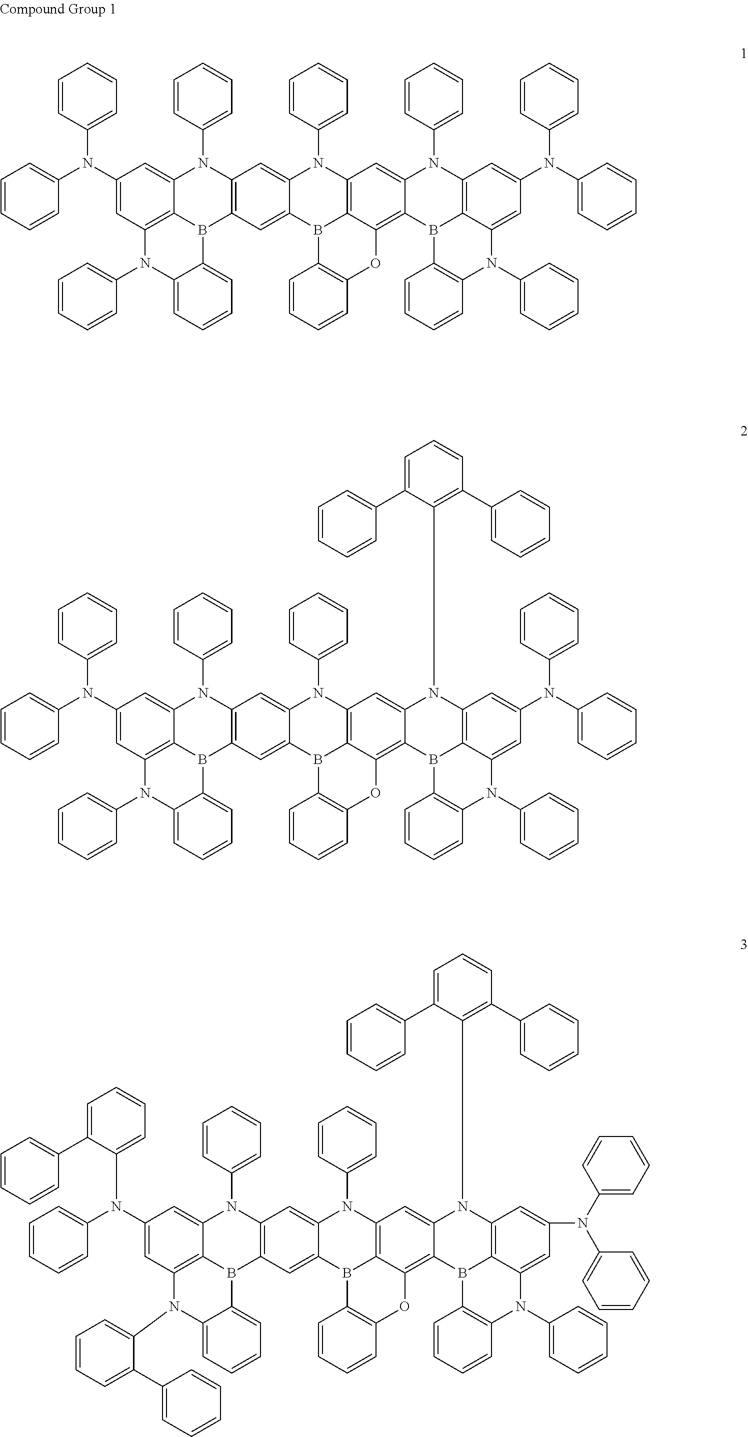 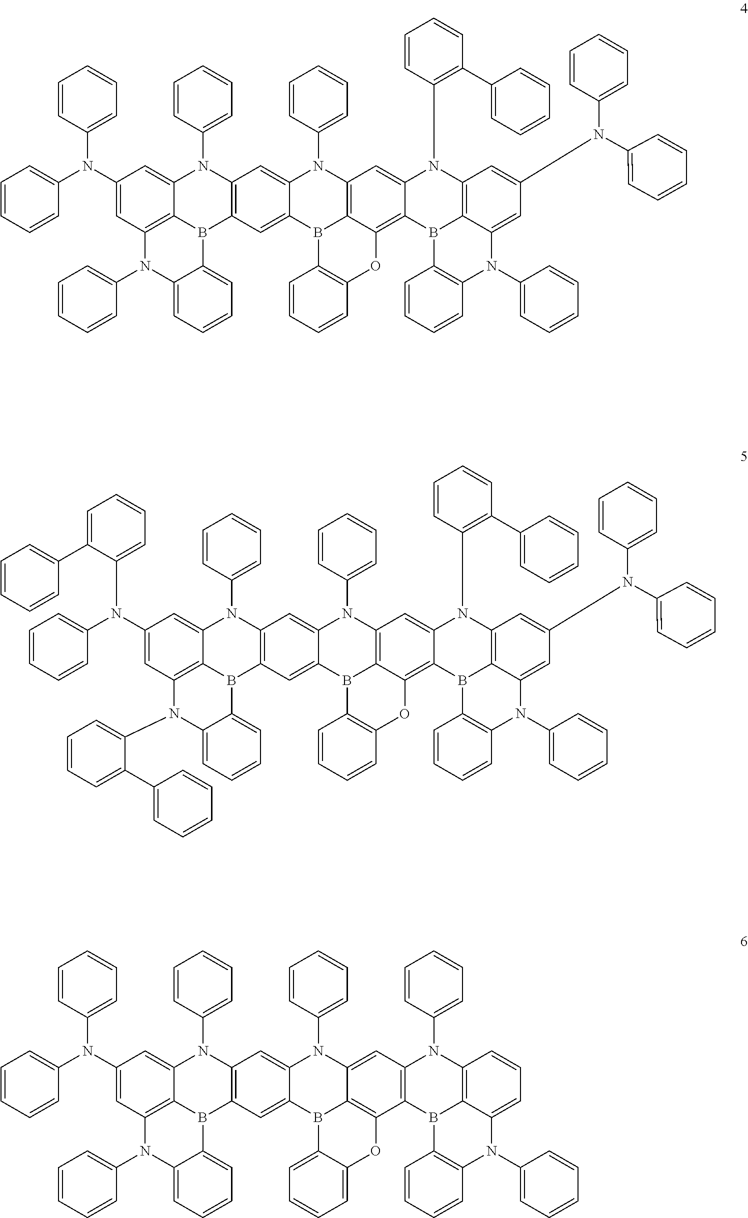 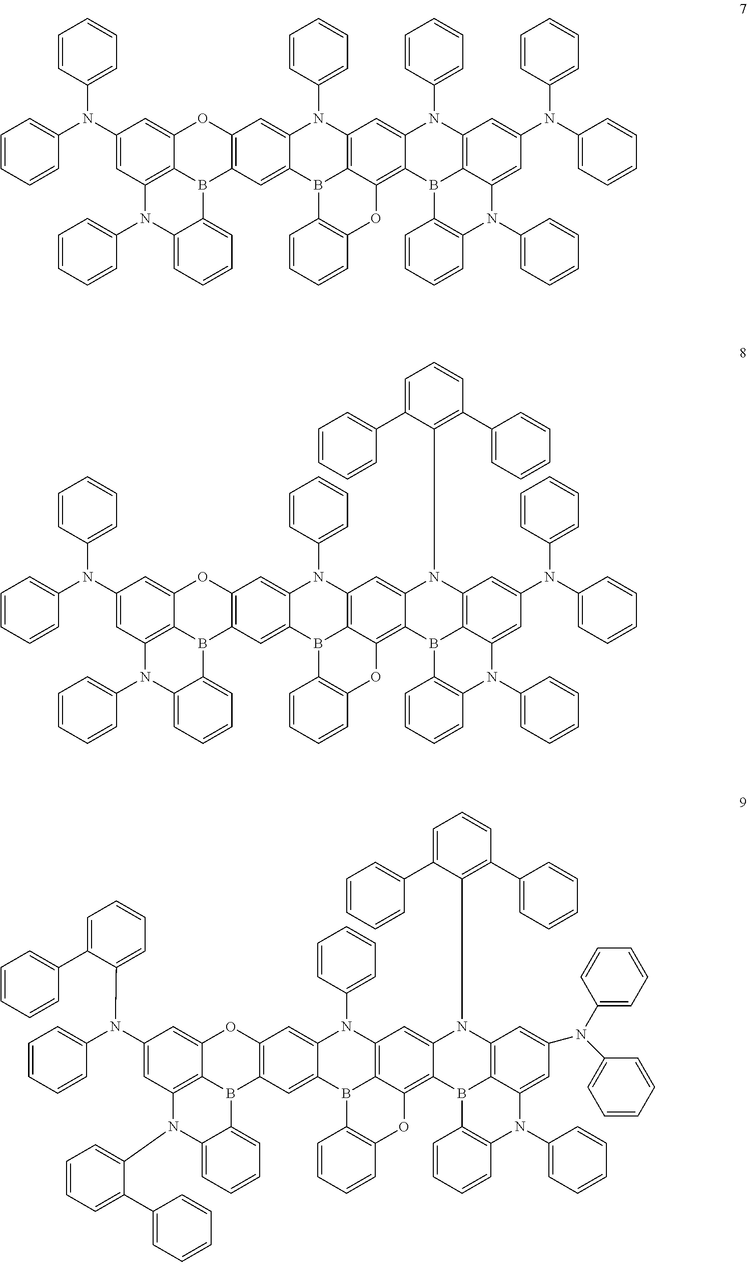 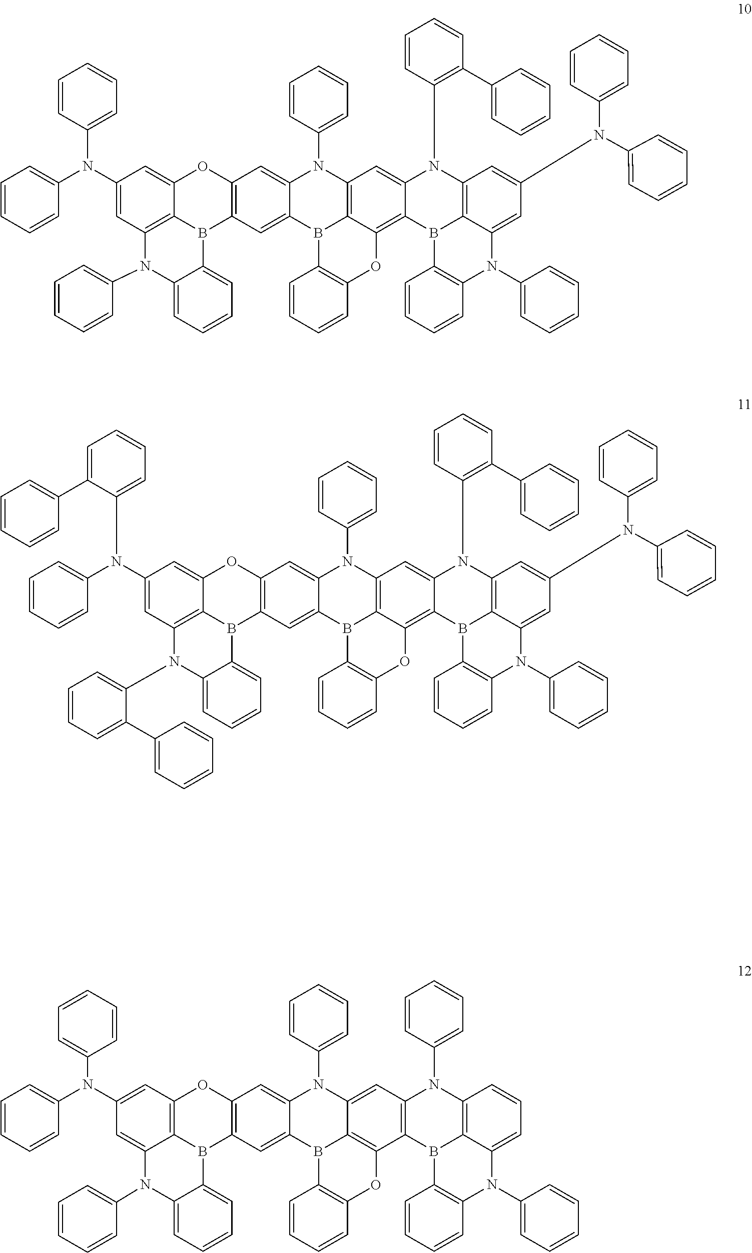 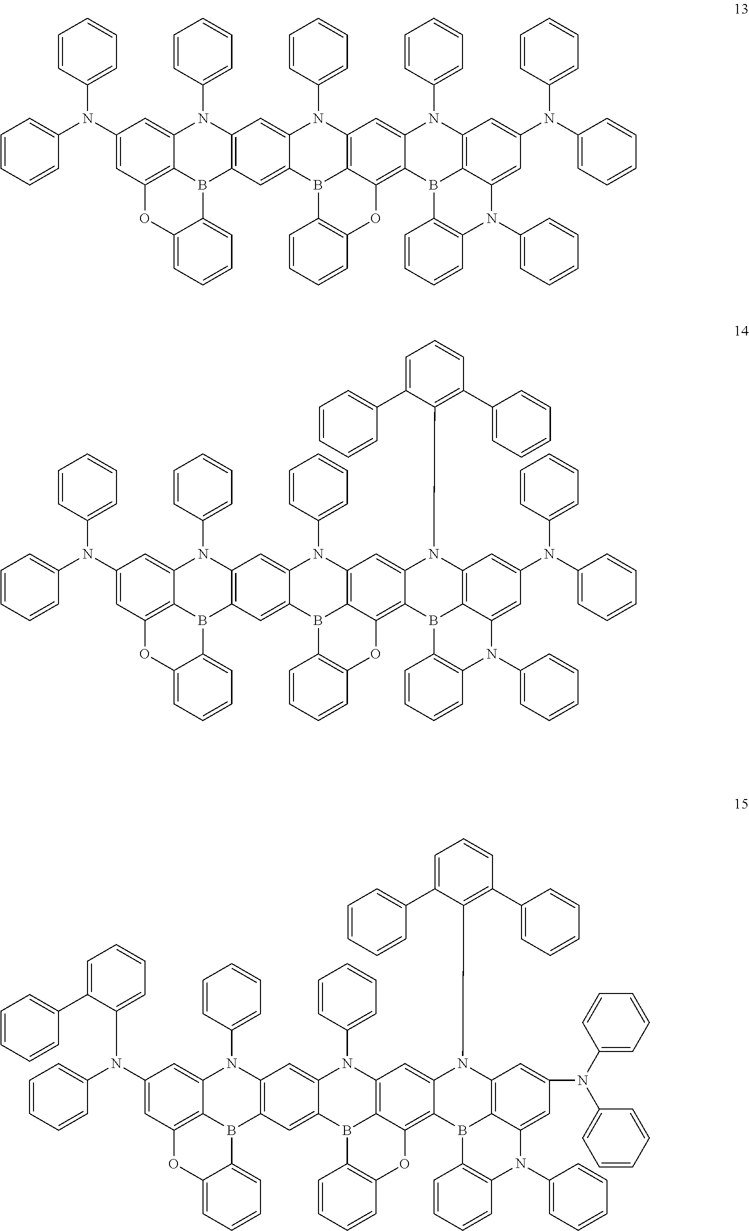 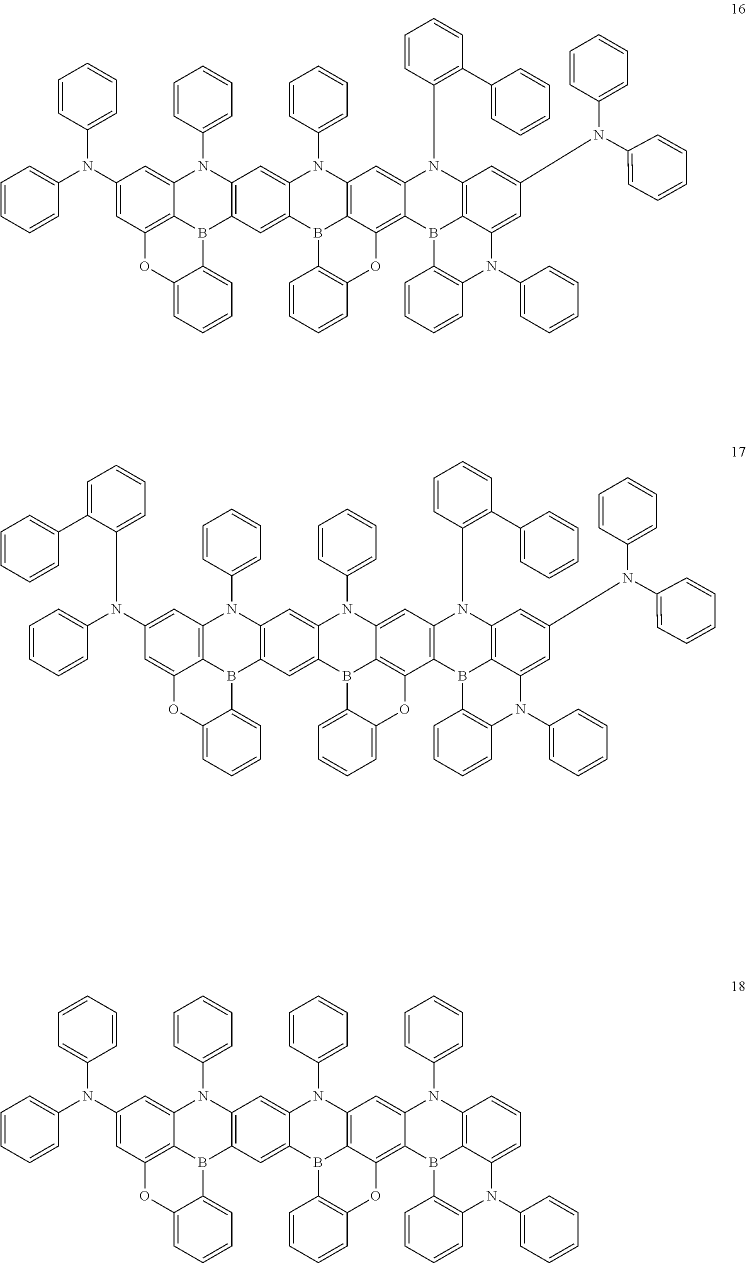 [SMILES: c1ccc(-c2ccccc2N2c3cc(N(c4ccccc4)c4ccccc4)cc4c3B(c3ccccc3N4c3ccccc3)c3c2cc2c4c3Oc3ccccc3B4c3cc4c(cc3N2c2ccccc2)N(c2ccccc2)c2cc(N(c3ccccc3)c3ccccc3)cc3c2B4c2ccccc2O3)cc1 ; c1ccc(-c2ccccc2N(c2ccccc2)c2cc3c4c(c2)N(c2ccccc2)c2cc5c(cc2B4c2ccccc2O3)B2c3ccccc3Oc3c2c(cc2c3B3c4ccccc4N(c4ccccc4)c4cc(N(c6ccccc6)c6ccccc6)cc(c43)N2c2ccccc2-c2ccccc2)N5c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4N(c4ccccc4)c4cccc(c43)N2c2ccccc2)N5c2ccccc2)cc1] 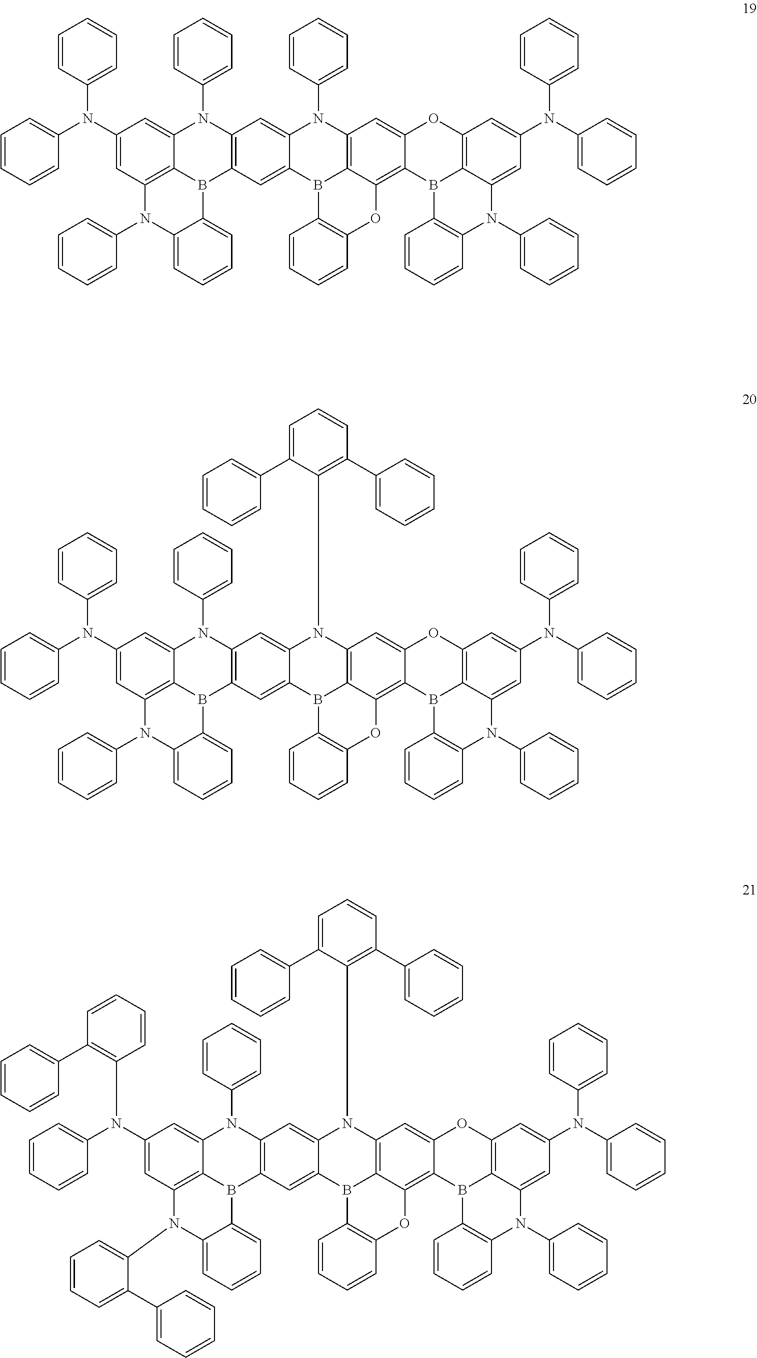 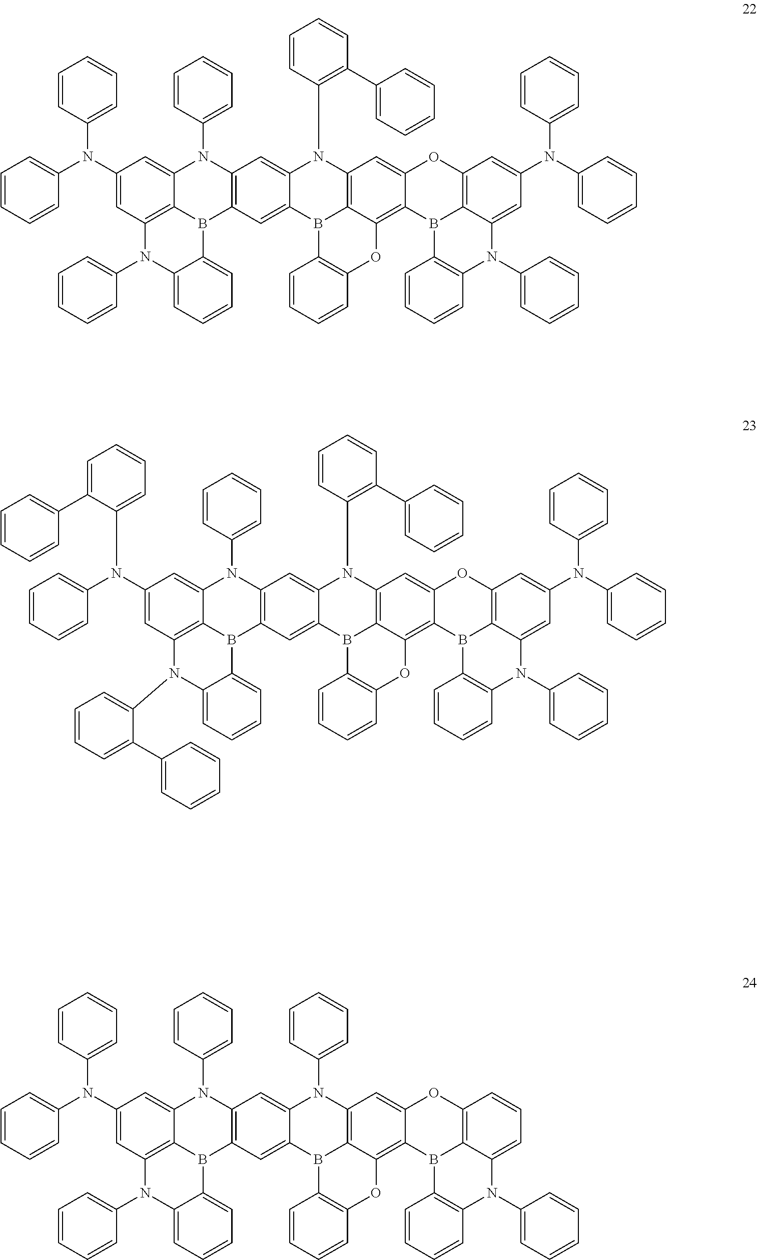 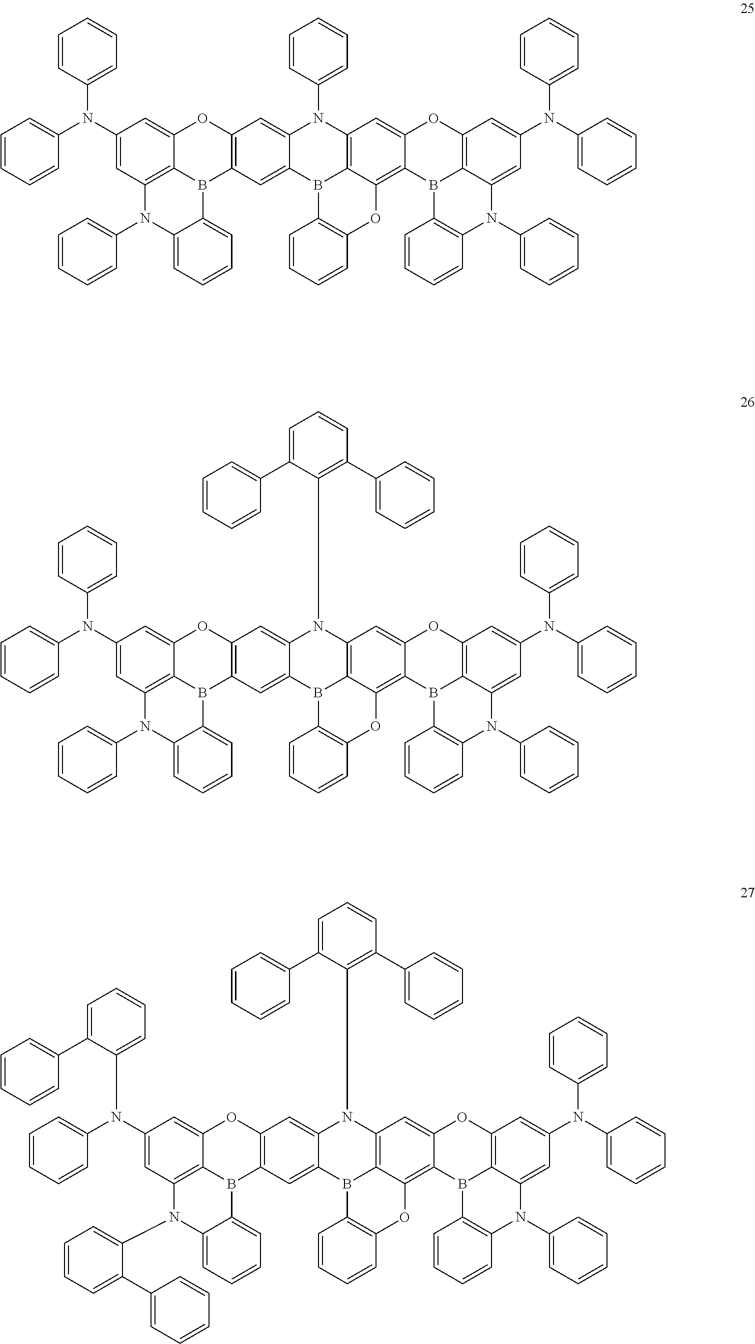 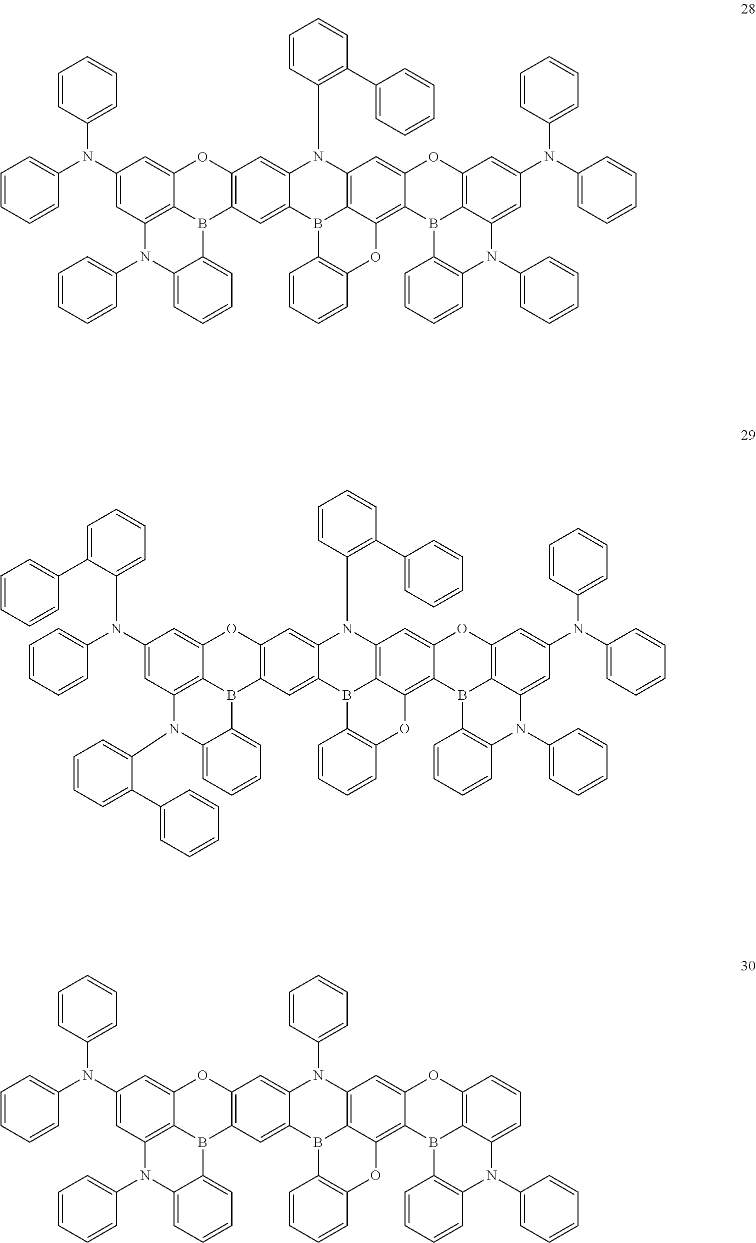 [SMILES: c1ccc(-c2ccccc2N2c3cc4c(cc3B3c5ccccc5Oc5c6c(cc2c53)Oc2cc(N(c3ccccc3)c3ccccc3)cc3c2B6c2ccccc2N3c2ccccc2)B2c3ccccc3N(c3ccccc3)c3cc(N(c5ccccc5)c5ccccc5)cc(c32)O4)cc1 ; c1ccc(-c2ccccc2N(c2ccccc2)c2cc3c4c(c2)N(c2ccccc2-c2ccccc2)c2ccccc2B4c2cc4c(cc2O3)N(c2ccccc2-c2ccccc2)c2cc3c(c5c2B4c2ccccc2O5)B2c4ccccc4N(c4ccccc4)c4cc(N(c5ccccc5)c5ccccc5)cc(c42)O3)cc1 ; c1ccc(N(c2ccccc2)c2cc3c4c(c2)N(c2ccccc2)c2ccccc2B4c2cc4c(cc2O3)N(c2ccccc2)c2cc3c(c5c2B4c2ccccc2O5)B2c4ccccc4N(c4ccccc4)c4cccc(c42)O3)cc1] 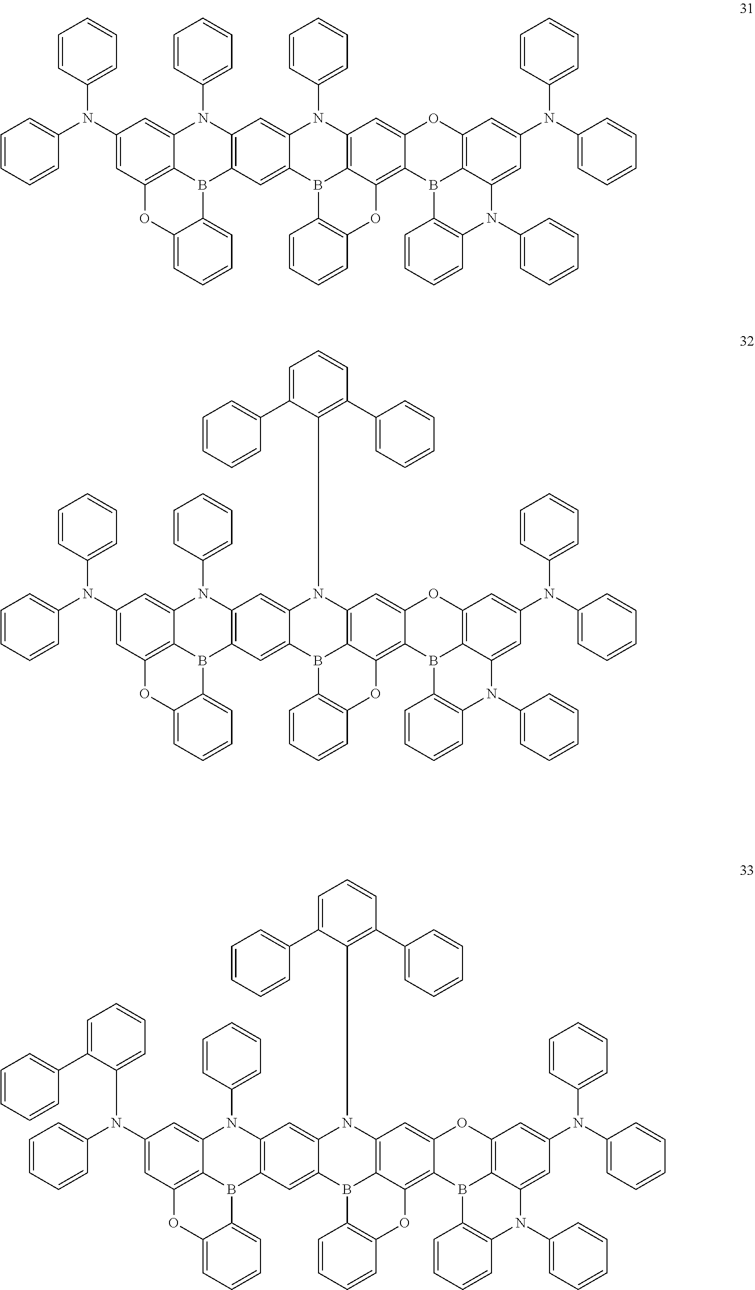 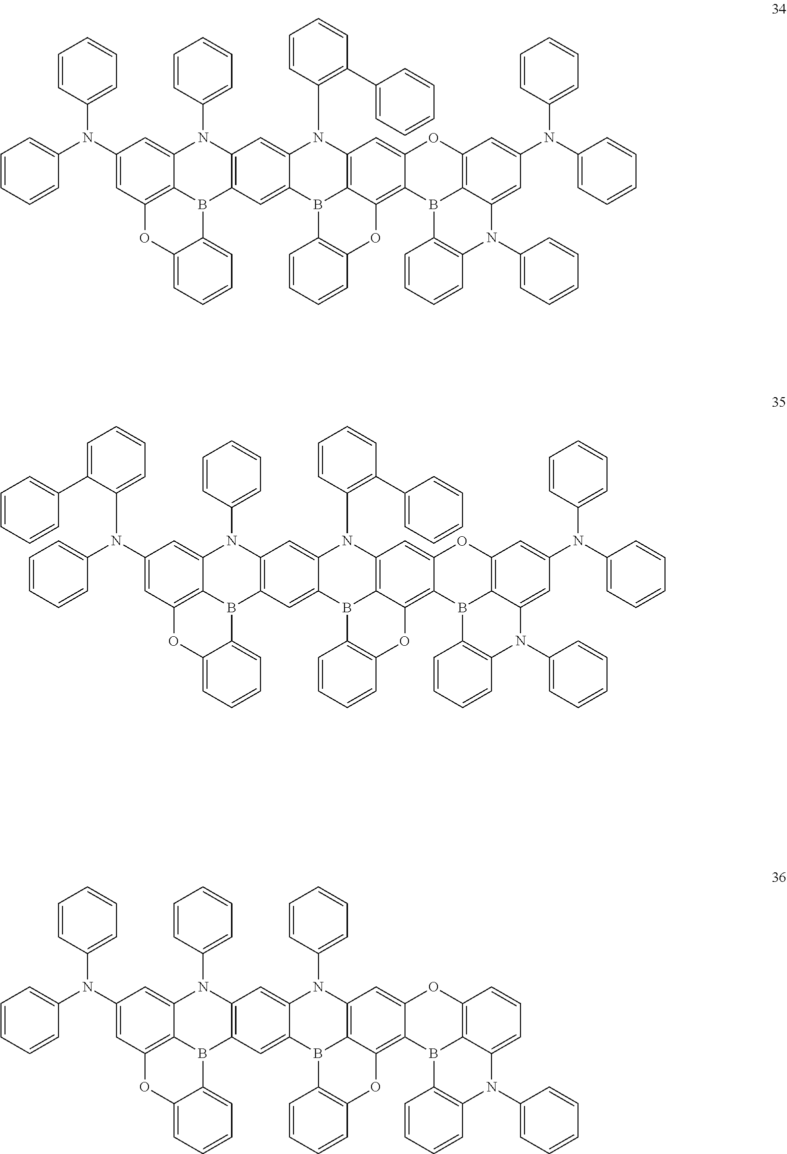 [SMILES: c1ccc(-c2ccccc2N2c3cc4c(cc3B3c5ccccc5Oc5c6c(cc2c53)Oc2cc(N(c3ccccc3)c3ccccc3)cc3c2B6c2ccccc2N3c2ccccc2)B2c3ccccc3Oc3cc(N(c5ccccc5)c5ccccc5)cc(c32)N4c2ccccc2)cc1 ; c1ccc(-c2ccccc2N(c2ccccc2)c2cc3c4c(c2)N(c2ccccc2)c2cc5c(cc2B4c2ccccc2O3)B2c3ccccc3Oc3c4c(cc(c32)N5c2ccccc2-c2ccccc2)Oc2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c4c(cc(c32)N5c2ccccc2)Oc2cccc3c2B4c2ccccc2N3c2ccccc2)cc1] 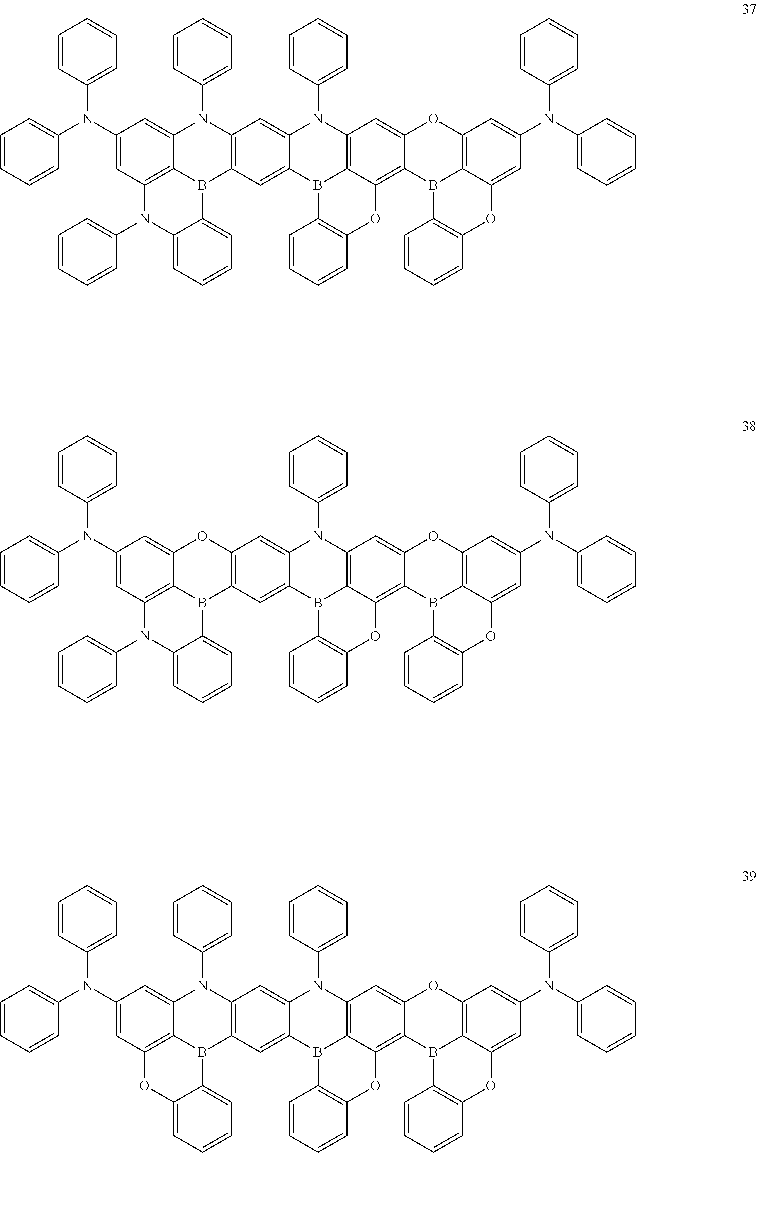 [SMILES: c1ccc(N(c2ccccc2)c2cc3c4c(c2)Oc2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2N5c2ccccc2)Oc2cc(N(c4ccccc4)c4ccccc4)cc4c2B3c2ccccc2N4c2ccccc2)cc1 ; c1ccc(N(c2ccccc2)c2cc3c4c(c2)Oc2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2O4)cc1] 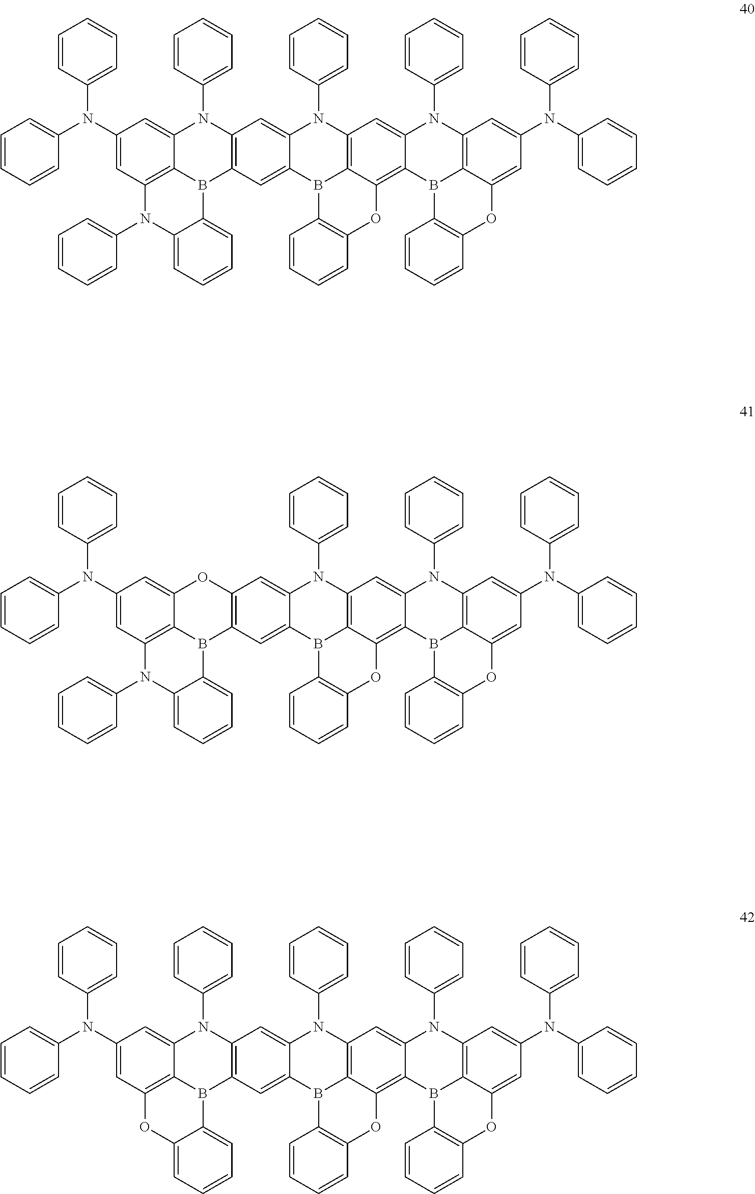 [SMILES: c1ccc(N(c2ccccc2)c2cc3c4c(c2)N(c2ccccc2)c2cc5c6c(c2B4c2ccccc2O3)Oc2ccccc2B6c2cc3c(cc2N5c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc3c(c5c2B4c2ccccc2O5)B2c4ccccc4Oc4cc(N(c5ccccc5)c5ccccc5)cc(c42)N3c2ccccc2)cc1 ; c1ccc(N(c2ccccc2)c2cc3c4c(c2)N(c2ccccc2)c2cc5c(cc2B4c2ccccc2O3)B2c3ccccc3Oc3c2c(cc2c3B3c4ccccc4Oc4cc(N(c6ccccc6)c6ccccc6)cc(c43)N2c2ccccc2)N5c2ccccc2)cc1] 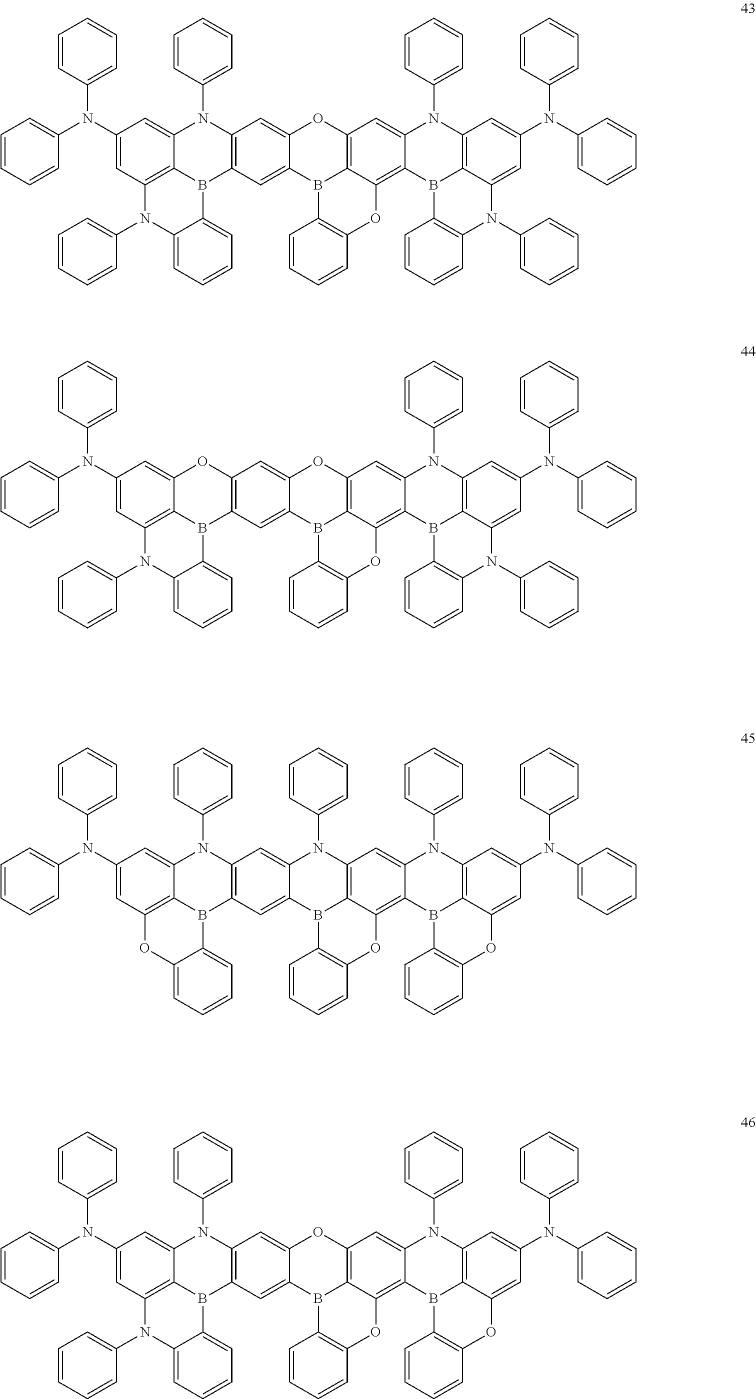 [chemical structure]
